(19) United States
(12) Patent Application Publication
(10) Pub. No.: US 2025/0176179 A1
(43) Pub. Date: May 29, 2025

(54) THREE-DIMENSIONAL MEMORY DEVICE WITH DUMMY SLIT REGIONS AND METHODS OF MAKING THE SAME

(71) Applicant: WESTERN DIGITAL TECHNOLOGIES, INC.,, SAN JOSE, CA (US)

(72) Inventors: Daichi SAITO, Yokkaichi (JP); Masaaki SHINOHARA, Yokkaichi (JP); Takayuki MAEKURA, Yokkaichi (JP); Tomohiro KUBO, Yokkaichi (JP); Masanori TERAHARA, Yokkaichi (JP); Satoshi YOSHIKAWA, Yokkaichi (JP); Hideaki HASEGAWA, Yokkaichi (JP)

(21) Appl. No.: 18/649,071

(22) Filed: Apr. 29, 2024

Related U.S. Application Data
(63) Continuation-in-part of application No. 18/523,129, filed on Nov. 29, 2023.

(51) Int. Cl. H10B 43/27; H10B 51/20

(52) U.S. Cl. CPC H10B 43/27; H10B 51/20

(57) ABSTRACT

A three-dimensional memory device includes active and peripheral alternating stacks of insulating layers and electrically conductive layers, memory opening fill structures vertically extending through the active alternating stacks, a set of layer contact via structures, each of the layer contact via structures contacting a respective electrically conductive layer in a respective contact region in a respective one of the active alternating stacks, and a set of dummy via fill structures, each of the dummy via fill structures contacting a respective electrically conductive layer in a respective dummy structure region in a respective one of the peripheral alternating stacks. A volume of the dummy via fill structures contacting layers in the peripheral alternating stack is greater than a volume of the layer contact via structures contacting layers in the active alternating stack. The dummy via fill structures may be slit shaped, while the layer contact via structures may be cylindrical.

### RELATED APPLICATIONS

This application is a continuation-in-part (CIP) application of U.S. application Ser. No. 18/523,129 filed on Nov. 29, 2023, the entire contents of which are incorporated herein by reference.

### FIELD

The present disclosure relates generally to the field of semiconductor devices, and particularly to a three-dimensional memory device with dummy slit regions and methods of making the same.

### BACKGROUND

A three-dimensional memory device including a three-dimensional vertical NAND strings having one bit per cell is disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a three-dimensional memory device, comprises active and peripheral alternating stacks of insulating layers and electrically conductive layers laterally extending along a first horizontal direction with a respective width along a second horizontal direction that is perpendicular to the first horizontal direction; lateral isolation trenches laterally extending along the first horizontal direction, wherein the alternating stacks are laterally spaced apart from each other along the second horizontal direction by the lateral isolation trenches; memory opening fill structures each containing a respective vertical stack of memory elements and a vertical semiconductor channel vertically extending through the active alternating stacks; a set of layer contact via structures, each of the layer contact via structures contacting a respective electrically conductive layer in a respective contact region in a respective one of the active alternating stacks; a set of dummy via fill structures, each of the dummy via fill structures contacting a respective electrically conductive layer in a respective dummy structure region in a respective one of the peripheral alternating stacks, wherein a second total volume of the respective set of the dummy via fill structures contacting the electrically conductive layers within the respective one of the peripheral alternating stacks is greater than a first total volume of the respective set of the layer contact via structures contacting the electrically conductive layers within the respective one of the active alternating stacks.

According to another aspect of the present disclosure, a method of forming a device structure is provided. The method comprises: forming a vertically alternating sequence of continuous insulating layers and continuous spacer material layers over a substrate; forming memory openings through the vertically alternating sequence; forming memory opening fill structures in the memory openings, wherein each of the memory opening fill structures comprises a respective vertical stack of memory elements; forming a patterned hardmask layer over the vertically alternating sequence and the memory opening fill structures, wherein the patterned hardmask layer comprises arrays of first-type openings in a center region of the vertically alternating sequence and an array of second-type openings in a peripheral region of the vertically alternating sequence; and forming arrays of contact via openings by vertically recessing first portions of the vertically alternating sequence that underlie the first-type openings and forming an array of dummy cavities by vertically recessing second portions of the vertically alternating sequence that underlie the second-type openings. Each array of the arrays of contact via openings has a first total cavity volume per unit area; and the array of dummy cavities has a second total cavity volume per unit area which is greater than the first total cavity volume per unit area.

According to an aspect of the present disclosure, a three-dimensional memory device comprises an alternating stack of insulating layers and electrically conductive layers; memory openings vertically extending through the alternating stack; memory opening fill structures located in the memory openings, wherein each of the memory opening fill structures comprises a respective vertical semiconductor channel and a vertical stack of memory elements; and an array of layer contact via structures. Each of the layer contact via structures contacts a respective one of the electrically conductive layers and vertically extends through a respective subset of layers within the alternating stack that overlies the respective one of the electrically conductive layers; and a shallower first subset of the layer contact via structures has a higher density per unit area than a deeper second subset of the layer contact via structures.

According to another aspect of the present disclosure, a method of forming a three-dimensional memory device comprises forming an alternating stack of insulating layers and spacer material layers, wherein the spacer material layers are formed are or are subsequently replaced with electrically conductive layers; forming memory openings through the alternating stack; forming memory opening fill structures in the memory openings, wherein each of the memory opening fill structures comprises a respective vertical semiconductor channel and a vertical stack of memory elements; and forming an array of layer contact via structures. Each of the layer contact via structures is formed on a respective one of the electrically conductive layers and vertically extends through a respective subset of layers within the alternating stack that overlies the respective one of the electrically conductive layers; and a shallower first subset of the layer contact via structures has a higher density per unit area than a deeper second subset of the layer contact via structures.

### BRIEF DESCRIPTION OF THE DRAWINGS

FIG. 1 is a schematic vertical cross-sectional view of a first exemplary structure after formation of an alternating stack of insulating layers and sacrificial material layers over a substrate according to a first embodiment of the present disclosure.

FIG. 2A is a top-down view of a region of the first exemplary structure after formation of memory openings and support openings according to an embodiment of the present disclosure.

FIG. 2B is a vertical cross-sectional view of the first exemplary structure along the vertical plane B-B′ of FIG. 2A.

FIG. 3A is a top-down view of a region of the first exemplary structure after formation of sacrificial opening fill structures according to an embodiment of the present disclosure.

FIG. 3B is a vertical cross-sectional view of the first exemplary structure along the vertical plane B-B′ of FIG. 3A.

FIG. 4A is a top-down view of a region of the first exemplary structure after replacement of sacrificial support opening fill structures with support pillar structures according to an embodiment of the present disclosure.

FIG. 4B is a vertical cross-sectional view of the first exemplary structure along the vertical plane B-B′ of FIG. 4A.

FIG. 5A is a top-down view of a region of the first exemplary structure after removal of sacrificial memory opening fill structures according to an embodiment of the present disclosure.

FIG. 5B is a vertical cross-sectional view of the first exemplary structure along the vertical plane B-B′ of FIG. 5A.

FIG. 6A is a top-down view of a region of the first exemplary structure after formation of memory opening fill structures according to an embodiment of the present disclosure.

FIG. 6B is a vertical cross-sectional view of the first exemplary structure along the vertical plane B-B′ of FIG. 6A.

FIG. 6C is a vertical cross-sectional view of a region around a memory opening fill structure in the first exemplary structure of FIGS. 6A and 6B.

FIG. 7A is a top-down view of a region of the first exemplary structure after formation of an insulating cap layer and a patterned hard mask layer according to an embodiment of the present disclosure.

FIG. 7B is a vertical cross-sectional view of the first exemplary structure along the vertical plane B-B′ of FIG. 7A.

FIGS. 8A-8F are sequential schematic vertical cross-sectional view of region of the first exemplary structure during formation of contact via openings according to an embodiment of the present disclosure.

FIG. 9A is a top-down view of a region of the first exemplary structure after formation of contact via openings and removal of the patterned hard mask layer according to an embodiment of the present disclosure.

FIG. 9B is a vertical cross-sectional view of the first exemplary structure along the vertical plane B-B′ of FIG. 9A.

FIG. 9C is a vertical cross-sectional view of the first exemplary structure along the vertical plane C-C′ of FIG. 9A.

FIGS. 10A-10C are top-down views of alternative configuration of the first exemplary structure after the processing steps of FIGS. 9A-9C according to an embodiment of the present disclosure.

FIG. 11A is a top-down view of a region of the first exemplary structure after formation of sacrificial via fill structures and removal of the patterned hard mask layer according to an embodiment of the present disclosure.

FIG. 11B is a vertical cross-sectional view of the first exemplary structure along the vertical plane B-B′ of FIG. 11A.

FIG. 11C is a vertical cross-sectional view of the first exemplary structure along the vertical plane C-C′ of FIG. 11A.

FIG. 12A is a top-down view of a region of the first exemplary structure after formation of a contact-level dielectric layer, lateral isolation trenches, and source regions according to an embodiment of the present disclosure.

FIG. 12B is a vertical cross-sectional view of the first exemplary structure along the vertical plane B-B′ of FIG. 12A.

FIG. 12C is a vertical cross-sectional view of the first exemplary structure along the vertical plane C-C′ of FIG. 12A.

FIG. 13A is a top-down view of a region of the first exemplary structure after formation of lateral recesses according to an embodiment of the present disclosure.

FIG. 13B is a vertical cross-sectional view of the first exemplary structure along the vertical plane B-B′ of FIG. 13A.

FIG. 13C is a vertical cross-sectional view of the first exemplary structure along the vertical plane C-C′ of FIG. 13A.

FIG. 14A is a top-down view of a region of the first exemplary structure after formation of electrically conductive layers according to an embodiment of the present disclosure.

FIG. 14B is a vertical cross-sectional view of the first exemplary structure along the vertical plane B-B′ of FIG. 14A.

FIG. 14C is a vertical cross-sectional view of the first exemplary structure along the vertical plane C-C′ of FIG. 14A.

FIG. 15A is a top-down view of a region of the first exemplary structure after formation of lateral isolation trench fill structures according to an embodiment of the present disclosure.

FIG. 15B is a vertical cross-sectional view of the first exemplary structure along the vertical plane B-B′ of FIG. 15A.

FIG. 15C is a vertical cross-sectional view of the first exemplary structure along the vertical plane C-C′ of FIG. 15A.

FIG. 16A is a top-down view of a region of the first exemplary structure after formation of connection via openings according to an embodiment of the present disclosure.

FIG. 16B is a vertical cross-sectional view of the first exemplary structure along the vertical plane B-B′ of FIG. 16A.

FIG. 16C is a vertical cross-sectional view of the first exemplary structure along the vertical plane C-C′ of FIG. 16A.

FIG. 17A is a top-down view of a region of the first exemplary structure after formation of contact via openings according to an embodiment of the present disclosure.

FIG. 17B is a vertical cross-sectional view of the first exemplary structure along the vertical plane B-B′ of FIG. 17A.

FIG. 17C is a vertical cross-sectional view of the first exemplary structure along the vertical plane C-C′ of FIG. 17A.

FIG. 18A is a top-down view of a region of the first exemplary structure after formation of layer contact via structures according to an embodiment of the present disclosure.

FIG. 18B is a vertical cross-sectional view of the first exemplary structure along the vertical plane B-B′ of FIG. 18A.

FIG. 18C is a vertical cross-sectional view of the first exemplary structure along the vertical plane C-C′ of FIG. 18A.

FIGS. 19A-19C are top-down views of alternative configuration of the first exemplary structure after the processing steps of FIGS. 18A-18C according to an embodiment of the present disclosure.

FIG. 20A is a horizontal cross-sectional view along horizontal plane A-A′ of FIG. 20B of a second exemplary structure at a processing step during formation of contact via openings and dummy cavities according to an embodiment of the present disclosure. A patterned hard mask layer is not shown for clarity.

FIG. 20B is a vertical cross-sectional view of the second exemplary structure along the vertical plane B-B′ of FIG. 20A.

FIG. 21A is a top-down view of the second exemplary structure after application of an i-th photoresist material layer according to an embodiment of the present disclosure.

FIG. 21B is a vertical cross-sectional view of the second exemplary structure along the vertical plane B-B′ of FIG. 21A.

FIG. 21C is a vertical cross-sectional view of the second exemplary structure along the vertical plane C-C′ of FIG. 21A.

FIG. 22 is a vertical cross-sectional view of the second exemplary structure after patterning of the i-th photoresist material layer according to an embodiment of the present disclosure.

FIG. 23A is a top-down view of the second exemplary structure after a last iteration of a selective via extension process and removal of a last patterned photoresist material layer according to an embodiment of the present disclosure. The patterned hard mask layer is not shown for clarity.

FIG. 23B is a vertical cross-sectional view of the second exemplary structure along the vertical plane B-B′ of FIG. 23A.

FIG. 24A is a top-down view of the second exemplary structure after formation of sacrificial via opening fill structures in the contact via openings and in the dummy cavities according to an embodiment of the present disclosure.

FIG. 24B is a vertical cross-sectional view of the second exemplary structure along the vertical plane B-B′ of FIG. 24A.

FIG. 25A is a top-down view of the second exemplary structure after formation of lateral isolation trenches, replacement of sacrificial material layers with electrically conductive layers, formation of lateral isolation trench fill structures, and replacement of the sacrificial via opening fill structures with layer contact via structures and dummy via fill structures according to an embodiment of the present disclosure.

FIG. 25B is a vertical cross-sectional view of the second exemplary structure along the vertical plane B-B′ of FIG. 25A.

### DETAILED DESCRIPTION

As discussed above, the embodiments of the present disclosure are directed to a three-dimensional memory device with dummy slit regions and methods of making the same, the various aspects of which are described below. The embodiments of the present disclosure can be used to form various structures including a multilevel memory structure, non-limiting examples of which include three-dimensional memory array devices comprising a plurality of NAND memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are used merely to identify similar elements, and different ordinals may be used across the specification and the claims of the instant disclosure. The same reference numerals refer to the same element or similar element. Unless otherwise indicated, elements having the same reference numerals are presumed to have the same composition. Unless otherwise indicated, a “contact” between elements refers to a direct contact between elements that provides an edge or a surface shared by the elements. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a “prototype” structure or an “in-process” structure refers to a transient structure that is subsequently modified in the shape or composition of at least one component therein. As used herein, a first electrical component is electrically connected to a second electrical component if there exists an electrically conductive path between the first electrical component and the second electrical component.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a “semiconducting material” refers to a material having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵S/cm. As used herein, an “insulator material” or a “dielectric material” refers to a material having electrical conductivity less than 1.0×10⁻⁶ S/cm. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to have electrical conductivity greater than 1.0×10⁵ S/cm. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁶ S/cm to 1.0×10⁵ S/cm. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material can be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that can be attached to a circuit board through a set of pins or solder balls. A semiconductor package may include a semiconductor chip (or a “chip”) or a plurality of semiconductor chips that are bonded thereamongst, for example, by flip-chip bonding or another chip-to-chip bonding. A package or a chip may include a single semiconductor die (or a “die”) or a plurality of semiconductor dies. A die is the smallest unit that can independently execute external commands or report status. Typically, a package or a chip with multiple dies is capable of simultaneously executing as many external commands as the total number of dies therein. Each die includes one or more planes. Identical concurrent operations can be executed in each plane within a same die, although there may be some restrictions. In case a die is a memory die, i.e., a die including memory elements, concurrent read operations, concurrent write operations, or concurrent erase operations can be performed in each plane within a same memory die. Each plane contains a number of memory blocks (or “blocks”), which are the smallest unit that can be erased by in a single erase operation. Each memory block contains a number of pages, which are the smallest units that can be selected for programming.

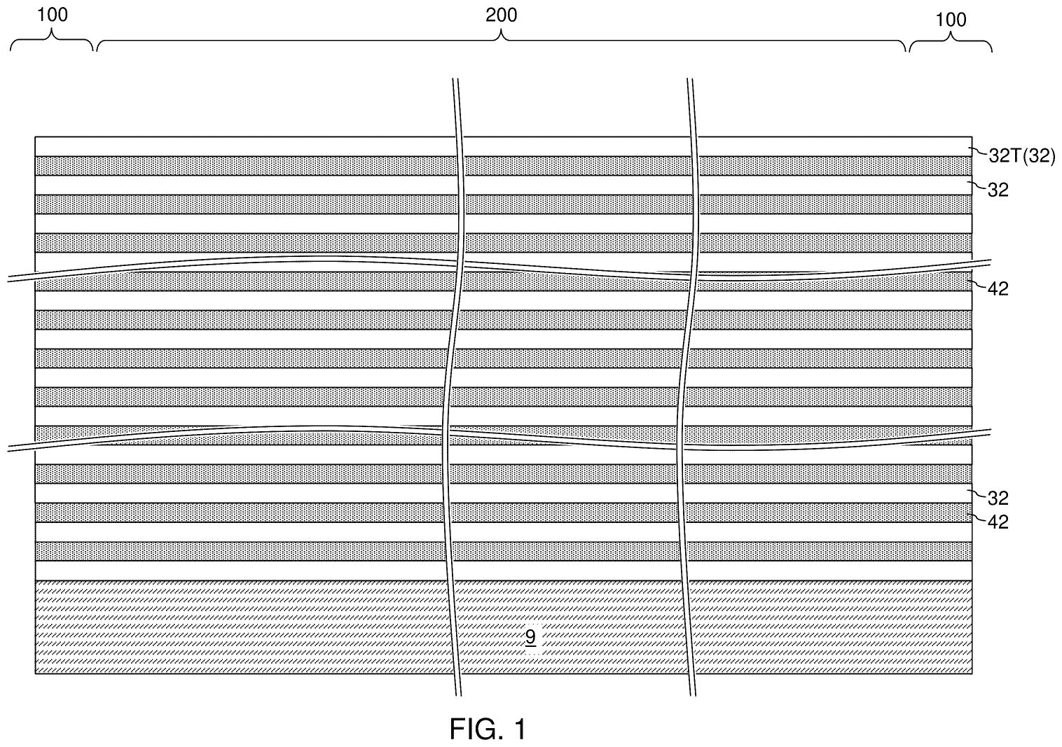

Referring to FIG. 1, a first exemplary structure according to an embodiment of the present disclosure is illustrated, which can be used, for example, to fabricate a device structure containing vertical NAND memory devices. The first exemplary structure includes a substrate including a semiconductor material layer at least at an upper portion thereof. The semiconductor material layer 9 includes at least one elemental semiconductor material (e.g., a doped well in a single crystal silicon wafer or a deposited silicon layer), at least one III-V compound semiconductor material, at least one II-VI compound semiconductor material, at least one organic semiconductor material, or other semiconductor materials known in the art. In one embodiment, the semiconductor material layer may comprise a semiconductor material having a doping of a first conductivity type.

An alternating stack (32, 46) of insulating layers 32 and spacer material layers can be formed over a semiconductor material layer 9. The spacer material layers are formed as, or are subsequently replaced with, electrically conductive layers. In case the spacer material layers are subsequently replaced with the electrically conductive layers, the spacer material layers may be formed as sacrificial material layers 42. In this case, a stack of an alternating plurality of insulating layers 32 and sacrificial material layers 42 can be formed over the semiconductor material layer 9. The stack of the alternating plurality is herein referred to as an alternating stack (32, 42).

In one embodiment, the alternating stack (32, 42) can include insulating layers 32 composed of the first material, and sacrificial material layers 42 composed of a second material different from that of insulating layers 32. The first material of the insulating layers 32 can be at least one insulating material. As such, each insulating layer 32 can be an insulating material layer. Insulating materials that can be used for the insulating layers 32 include, but are not limited to, silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the insulating layers 32 can be silicon oxide.

The second material of the sacrificial material layers 42 is a sacrificial material that can be removed selective to the first material of the insulating layers 32. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The sacrificial material layers 42 may comprise a dielectric material. In one embodiment, the sacrificial material layers 42 may comprise, and/or may consist essentially of, silicon nitride. The insulating layers 32 can be deposited, for example, by chemical vapor deposition (CVD). For example, if silicon oxide is used for the insulating layers 32, tetraethyl orthosilicate (TEOS) can be used as the precursor material for the CVD process. The sacrificial material layers 42 can be formed, for example, CVD or atomic layer deposition (ALD).

The thicknesses of the insulating layers 32 and the sacrificial material layers 42 can be in a range from 20 nm to 50 nm, although lesser and greater thicknesses can be used for each insulating layer 32 and for each sacrificial material layer 42. The number of repetitions of the pairs of an insulating layer 32 and a sacrificial material layer (e.g., a control gate electrode or a sacrificial material layer) 42 can be in a range from 2 to 1,024, and typically from 8 to 256, although a greater number of repetitions can also be used. The top and bottom gate electrodes in the stack may function as the select gate electrodes. In one embodiment, each sacrificial material layer 42 in the alternating stack (32, 42) can have a uniform thickness that is substantially invariant within each respective sacrificial material layer 42. The topmost one of the insulating layers 32 is herein referred to as a topmost insulating layer 32T.

The sacrificial material layers are replaced with electrically conductive layers in subsequent processing steps. The contact via structures that are subsequently formed to provide electrical contact to the electrically conductive layers are herein referred to as layer contact via structures, which may comprise word line contact via structures and/or select gate contact via structures, such as drain and/or source side select gate contact via structures. The first exemplary structure comprises a contact region 200 in which the layer contact via structures are to be subsequently formed, and at least one memory array region 100. The memory array region or regions 100 are laterally spaced from the contact region 200 and are employed to form three-dimensional memory arrays.

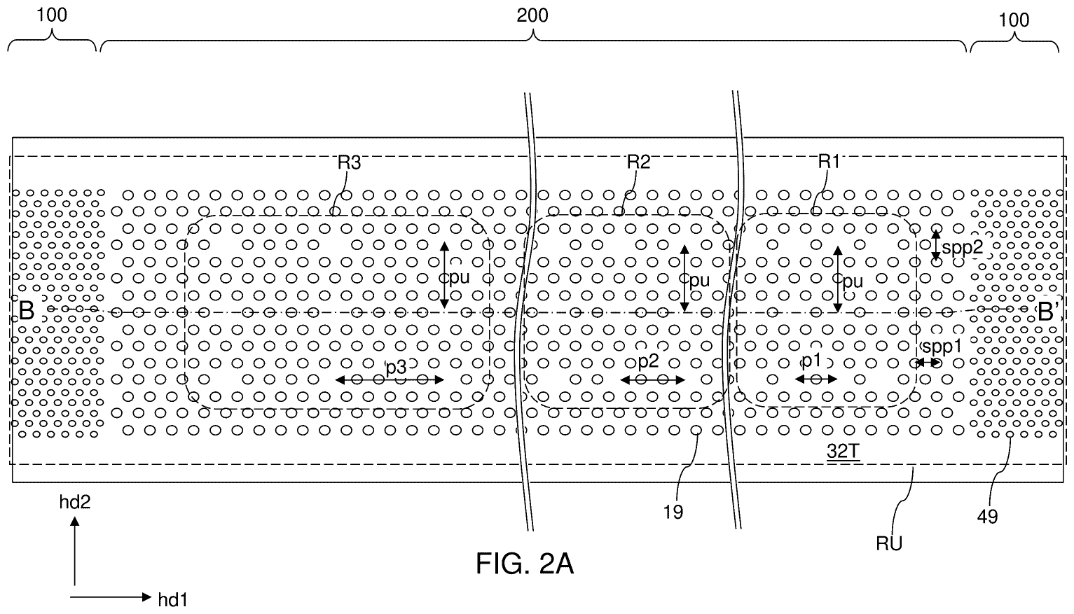

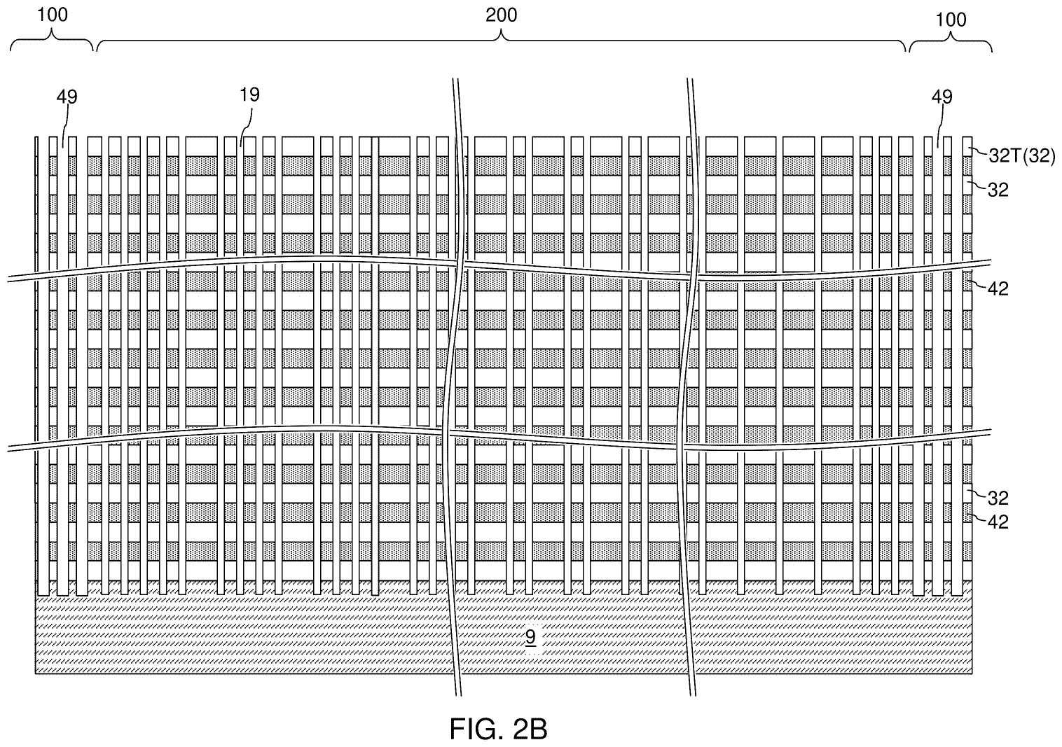

Referring to FIGS. 2A-2C, a lithographic material stack (not shown) including at least a photoresist layer can be formed over the alternating stack (32, 42), and can be lithographically patterned to form openings therein. The pattern in the lithographic material stack can be transferred through the alternating stack (32, 42) and through the alternating stack (32, 42) by at least one anisotropic etch that uses the patterned lithographic material stack as an etch mask. Portions of the alternating stack (32, 42) and underlying the openings in the patterned lithographic material stack are etched to form memory openings 49 in the memory array regions 100 and to form support openings 19 in the contact region 200. As used herein, a “memory opening” refers to an opening in which memory elements, such as a memory stack structure, is subsequently formed. As used herein, a “support opening” refers to an opening in which an electrically inactive structure that provides structural support is subsequently formed.

The memory openings 49 and the support openings extend through the entirety of the alternating stack (32, 42). The chemistry of the anisotropic etch process used to etch through the materials of the alternating stack (32, 42) can alternate to optimize etching of the first and second materials in the alternating stack (32, 42). The anisotropic etch can be, for example, a series of reactive ion etches. The sidewalls of the memory openings 49 and the support openings 19 can be substantially vertical, or can be tapered. The patterned lithographic material stack can be subsequently removed, for example, by ashing.

The memory openings 49 and the support openings 19 can extend from the top surface of the alternating stack (32, 42) to at least the horizontal plane including the topmost surface of the semiconductor material layer 9. In one embodiment, an overetch into the semiconductor material layer 9 may be optionally performed after the top surface of the semiconductor material layer 9 is physically exposed at a bottom of each memory opening 49 and at a bottom of each support opening 19. The overetch may be performed prior to, or after, removal of the lithographic material stack. In other words, the recessed surfaces of the semiconductor material layer 9 may be vertically offset from the un-recessed top surfaces of the semiconductor material layer 9 by a recess depth. The recess depth can be, for example, in a range from 1 nm to 50 nm, although lesser and greater recess depths can also be used. The overetch is optional, and may be omitted. The lithographic mask stack can be subsequently removed, for example, by ashing.

In one embodiment, the memory openings 49 may have a horizontal cross-sectional shape of a circle. In one embodiment, the support openings 19 may have a horizontal cross-sectional shape of a circle having the same or different diameter than the diameter of the memory openings 19.

In one embodiment, the memory openings 49 may be arranged in rows that laterally extend along a first horizontal direction hd1 (e.g., word line direction). The rows of memory openings 49 may be laterally spaced from each other along a second horizontal direction hd2 (e.g., bit line direction) that is perpendicular to the first horizontal direction hd1. In one embodiment, the pattern of the memory openings 49 and the support openings 19 may be formed as a periodic pattern that is repeated along the second horizontal direction hd2. In this case, a repetition unit (e.g., a memory block) RU may have a rectangular areas having a pair of lengthwise sidewalls that laterally extends along the first horizontal direction hd1. The repetition unit RU may be repeated along the second horizontal direction hd2 with a periodicity that equals the width of the rectangular area along the second horizontal direction hd2. Each repletion unit RU may have at least one two-dimensional array of memory openings 49 formed within a respective memory array region 100, and a respective two-dimensional array of support openings 19 formed within a contact region 200. In one embodiment, each repetition unit RU may comprise two two-dimensional arrays of memory openings 49 that are laterally spaced from each other along the first horizontal direction hd1 by the contact region 200.

In one embodiment, each two-dimensional array of memory openings 49 may comprise a periodic two-dimensional array of memory openings 49, such as a two-dimensional hexagonal array of memory openings 49. As used herein, a hexagonal array refers to any array in which the lattice sites are formed by a hexagon having three pairs of parallel edges. The hexagon may optionally be a regular hexagon (i.e., a hexagon having six edges of equal length). In one embodiment, each two-dimensional array of support openings 49 may comprise a periodic two-dimensional array of support openings 19, such as a two-dimensional hexagonal array of support openings 19. In this embodiment, variable density layer contact via structures to be formed during a subsequent step extend through the areas of some of the support openings 19 (i.e., through support pillar structures that will be formed in the respective memory openings 19).

In an alternative embodiment, the variable density layer contact via structures do not extend through areas of the support openings (i.e., do not extend through support pillar structures). In this alternative embodiment shown in FIG. 2A, the support openings 19 may be formed as a quasi-periodic two-dimensional array of support openings 19. As used herein, a “quasi-periodic” two-dimensional array of elements refers to a two-dimensional array of elements in which each element is located at a respective lattice site of a periodic two-dimensional array while a subset of lattice sites within the periodic two-dimensional array are “vacancy” lattice sites that do not contain any of the elements (i.e., do not contain a support opening 19). In other words, a two-dimensional quasi-periodic array of elements is derived from a two-dimensional periodic array of elements by omitting a subset of the elements from some of the “vacancy” lattice sites of the two-dimensional periodic array of elements. As used herein, a “lattice site” within a two-dimensional periodic array of elements refers to the primary lattice sites corresponding to locations at which the elements of the two-dimensional periodic array located or the vacancy sites.

The support openings 19 within the quasi-periodic two-dimensional array of support openings 19 can be located at the primary subset of lattice sites of a first periodic two-dimensional array having a first support-pillar periodicity spp1 along a first horizontal direction hd1 and having a second support-pillar periodicity spp2 along a second horizontal direction hd2 in a plan view. A plan view refers to a view along a vertical direction perpendicular to the top surface of the substrate 9, such as a see-through top-down view or a see-through bottom-up view. The support openings 19 are absent in a complementary (i.e., “vacancy”) subset of the lattice sites of the first periodic two-dimensional array, which is the complementary subset of the primary subset. In other words, the complementary subset does not have any intersection with the primary subset, and the union of the complementary subset and the primary subset forms a two-dimensional periodic array.

The complementary subset of the lattice sites defines locations (i.e., the “vacancy” sites) at which support openings 19 are not present relative to a hypothetical two-dimensional periodic array of support openings that includes each support opening 19 in the quasi-periodic two-dimensional array of support openings 19. Therefore, the lattice sites of the complementary subset are herein referred to as vacancy sites, i.e., sites at which the support openings 19 are omitted. According to an aspect of the present disclosure, the vacancy sites may be arranged as a plurality of periodic arrays having different periodicities. Each periodic array of vacancy sites may be located in a respective region, which may comprise, for example, a first region R1 including a first periodic array of vacancy sites, a second region R2 including a second periodic array of vacancy sites, and a third region R3 including a third periodic array of vacancy sites.

In one embodiment, the a first periodic array of vacancy sites may have a first periodic pitch p1 along a first periodicity direction (e.g., the first horizontal direction hd1) and a uniform pitch pu along a second periodicity direction (e.g., the second horizontal direction hd2) that is perpendicular to the first periodicity direction. The second periodic array of vacancy sites may have a second periodic pitch p2 along the first periodicity direction and the uniform pitch pu along the second periodicity direction. The third periodic array of vacancy sites may have a third periodic pitch p3 along the third periodicity direction and the uniform pitch pu along the second periodicity direction. The first periodicity direction may be parallel to the first horizontal direction hd1 or may be parallel to the second horizontal direction hd2. In the illustrative example of FIG. 2A, the first periodicity direction is parallel to the first horizontal direction hd1, and is perpendicular to the second horizontal direction hd2.

In one embodiment, each of the first periodic pitch p1, the second periodic pitch p2, and the third periodic pitch p3 may be commensurate of the first pitch of the support openings 19 along the first periodicity direction in the quasi-periodic two-dimensional array of support openings 19. In one embodiment, the first periodic pitch p1, the second periodic pitch p2, and the third periodic pitch p3 may be different from each other. In one embodiment, the first periodic pitch p1 may be less than the second periodic pitch p2, and the second periodic pitch p2 may be less than the third periodic pitch p3. In the illustrative example of FIGS. 2A and 2B, the ratio of the first periodic pitch p1 to the first pitch spp1 of the support openings 19 along the first periodicity direction is 2; the ratio of the second periodic pitch p2 to the first pitch spp1 is 3, and the ratio of the third periodic pitch p3 to the first pitch spp1 is 5. While the periodic pitches are illustrated as integral multiples of the first pitch spp1, non-integral ratios may be used.

In one embodiment, the first uniform pitch pu may be commensurate of the second pitch of the support openings 19 along the second periodicity direction. In the illustrative example of FIGS. 2A and 2B, the ratio of the uniform pitch pu to the second pitch spp2 of the support openings 19 along the second periodicity direction within the hypothetical two-dimensional periodic array of support openings is 2. However, other integral or non-integral ratios may be used.

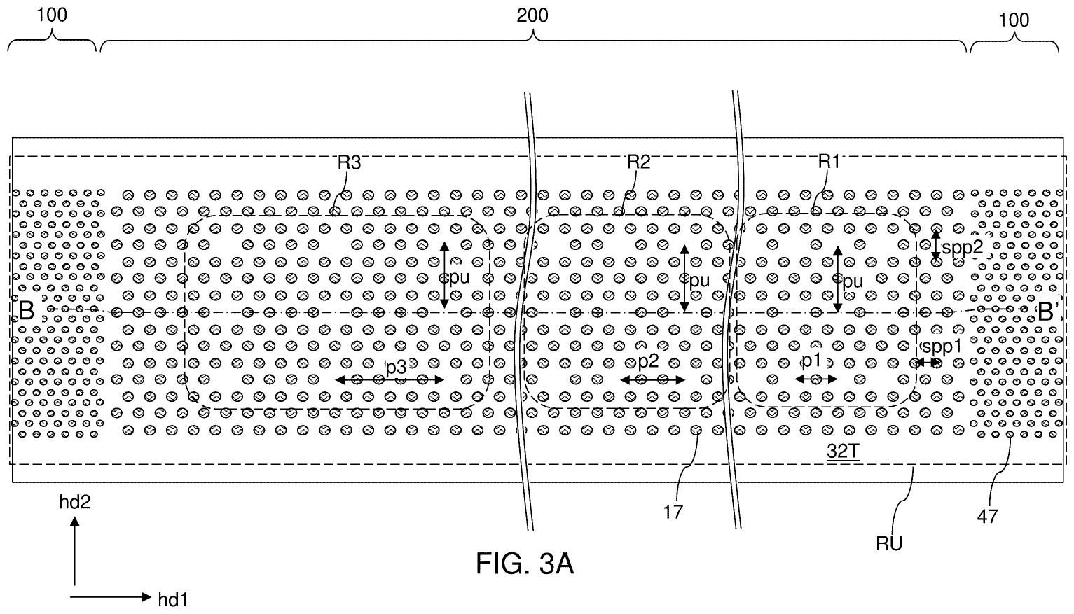

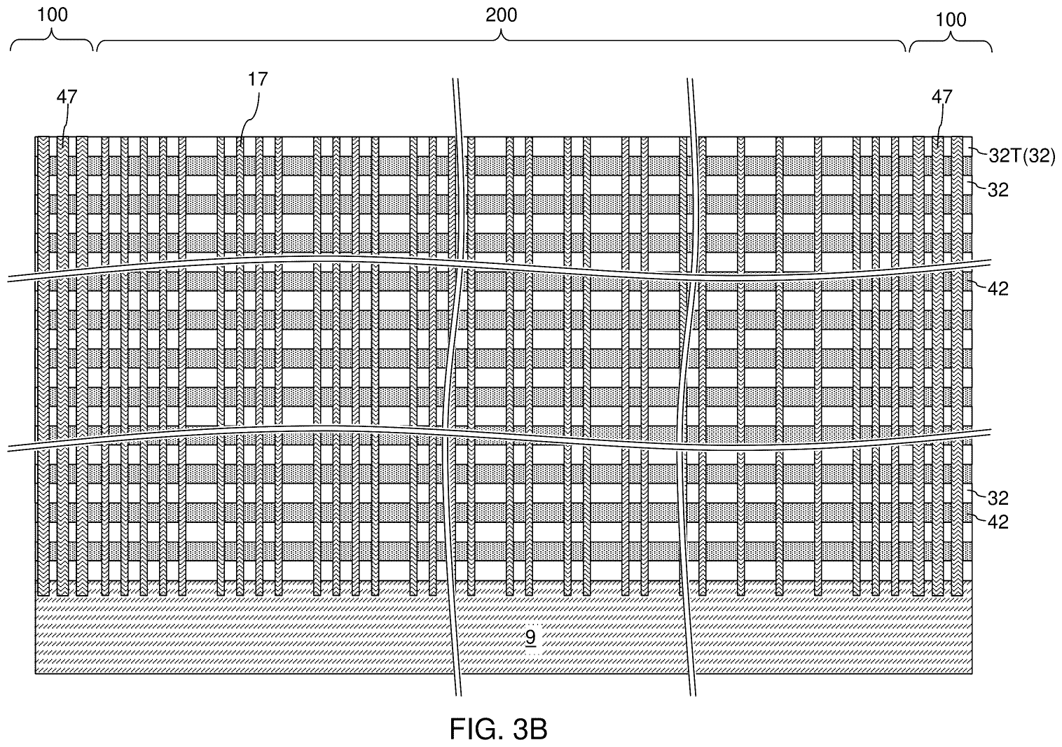

Referring to FIGS. 3A and 3B, a sacrificial fill material such as amorphous carbon, diamond-like carbon, a polymer material, or organosilicate glass can be deposited in the memory openings 49 and the support openings 19. Excess portions of the sacrificial fill material can be removed from above the horizontal plane including the topmost insulating layer 32T by performing a planarization process, which may comprise a chemical mechanical polishing (CMP) process and/or a recess etch process. Each remaining portion of the sacrificial fill material filling a memory opening 49 constitutes a sacrificial memory opening fill structure 47. Each remaining portion of the sacrificial fill material filling a support opening 19 constitutes a sacrificial support opening fill structure.

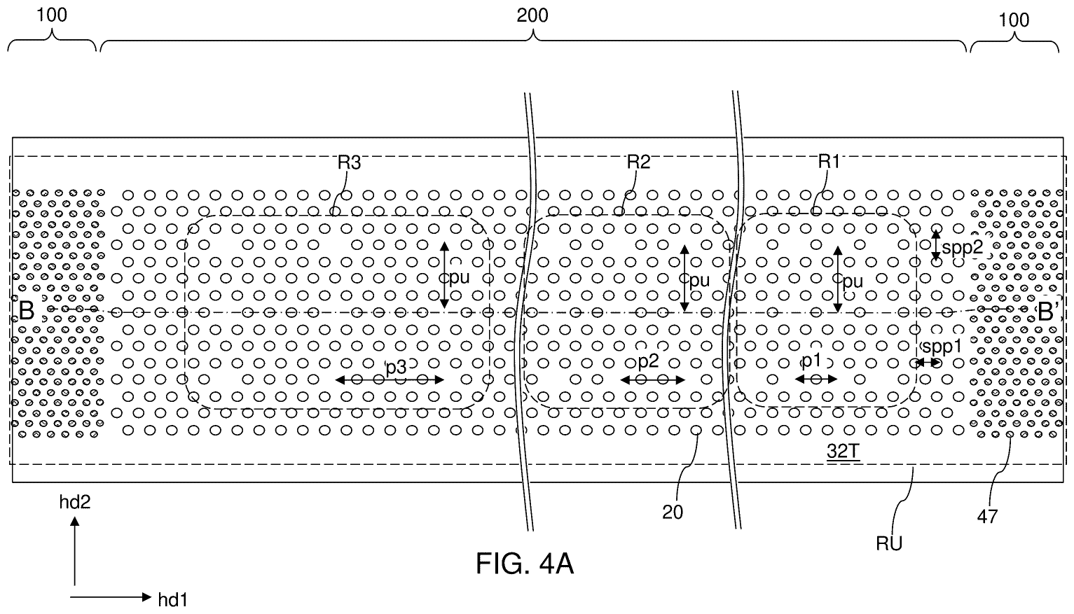

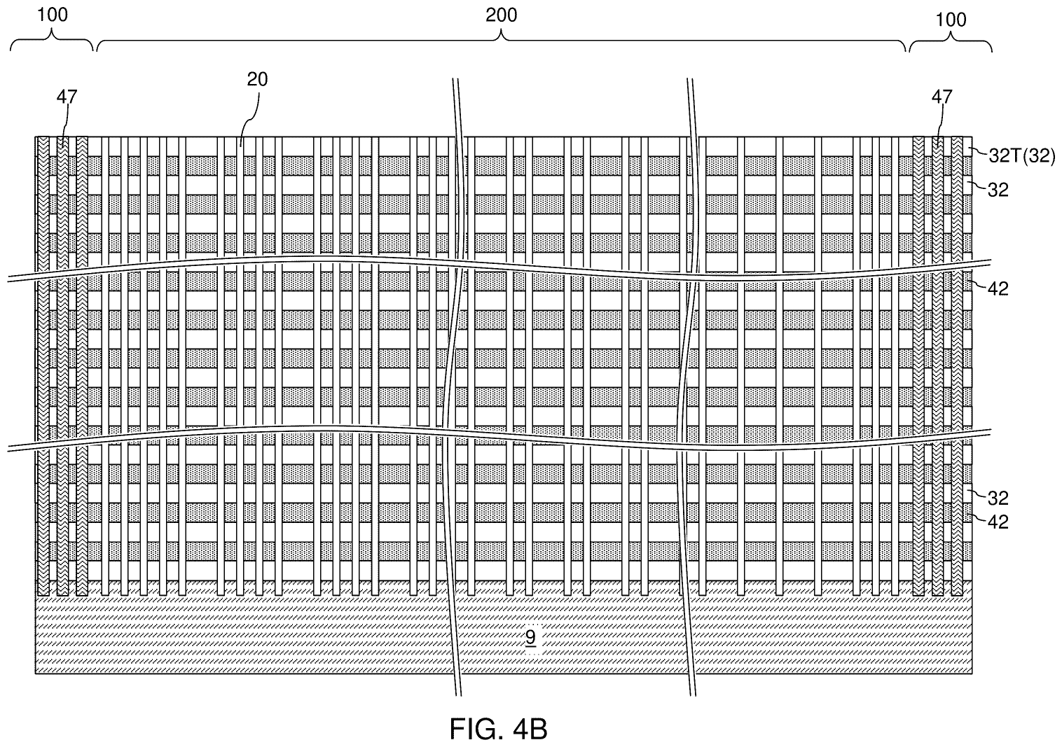

Referring to FIGS. 4A and 4B, a sacrificial cover liner (not shown) can be deposited over the alternating stack (32, 42). The sacrificial cover layer may comprise a dielectric material. A photoresist layer (not shown) can be applied over the sacrificial cover liner, and can be lithographically patterned to cover the memory array regions 100 without covering the contact region 200. A selective removal process can be performed to remove the sacrificial support opening fill structures selective to the materials of the alternating stack (32, 42) and the semiconductor material layer 9. The selective removal process may comprise an ashing process or a selective wet etch process. Voids are formed in the volumes of support openings 19. The photoresist layer may be removed during removal of the sacrificial support opening fill structures or after removal of the sacrificial support opening fill structures.

A dielectric fill material, such as silicon oxide, can be deposited in the voids of the support openings 19. Excess portions of the dielectric fill material can be removed from above the horizontal plane including the top surface of the topmost insulating layers 32T by performing a planarization process, which may comprise a chemical mechanical polishing process and/or a recess etch process. The sacrificial cover liner may be collaterally removed during the planarization process. Each remaining portion of the dielectric fill material that fills a respective one of the support openings 19 constitutes a support pillar structure 20.

A quasi-periodic two-dimensional array of support pillar structures 20 vertically extends through the alternating stack (32, 46) in the contact region 200. The support pillar structures 20 in the quasi-periodic two-dimensional array are located at a primary subset of lattice sites of a first periodic two-dimensional array having a first support-pillar periodicity along a first horizontal direction hd1 and having a second support-pillar periodicity along a second horizontal direction hd2 in a plan view. The first support pillar periodicity may be the same as a center-to-center distance between a neighboring pair of support pillar structures 20 along the first horizontal direction hd1. The second support pillar periodicity may be the same as a center-to-center distance between a neighboring pair of support pillar structures 20 along the second horizontal direction hd2. A subset of the vacancy lattice sites of the first periodic two-dimensional array at which the support pillar structures 20 are not present can be located at a complementary subset of the lattice sites of the first periodic two-dimensional array, which can be the complementary subset of the primary subset. In other words, the union of the primary subset and the complementary subset constitutes the first periodic two-dimensional array.

The complementary subset of the vacancy lattice sites of the first periodic two-dimensional array may comprise a first subset of the complementary subset located in the first region R1, a second subset of the complementary subset located in the second region R2, and a third subset of the complementary subset located in the third region R3. The lattice sites of the first subset of the complementary subset may have the first periodic pitch p1 along a first periodicity direction (which may be the first horizontal direction hd1) and may have the uniform pitch pu along a second periodicity direction (which may be the second horizontal direction hd2). The lattice sites of the second subset of the complementary subset may have the second periodic pitch p2 along the first periodicity direction and may have the uniform pitch pu along the second periodicity direction. The lattice sites of the third subset of the complementary subset may have the third periodic pitch p3 along the first periodicity direction and may have the uniform pitch pu along the second periodicity direction. In one embodiment, each of the first periodic pitch p1, the second periodic pitch p2, and the third periodic pitch p3 may be multiples (e.g., integer multiples) of the first support-pillar periodicity spp1 along the first horizontal direction hd1, and the uniform pitch pu may be a multiple (e.g., integer multiple) of the second support-pillar periodicity spp2 along the second horizontal direction hd2. The value of the integer multiples may be, for example, one or more, such as 1, 2, 3, 4, 5, 6, 7, 8, 9, 10, etc.

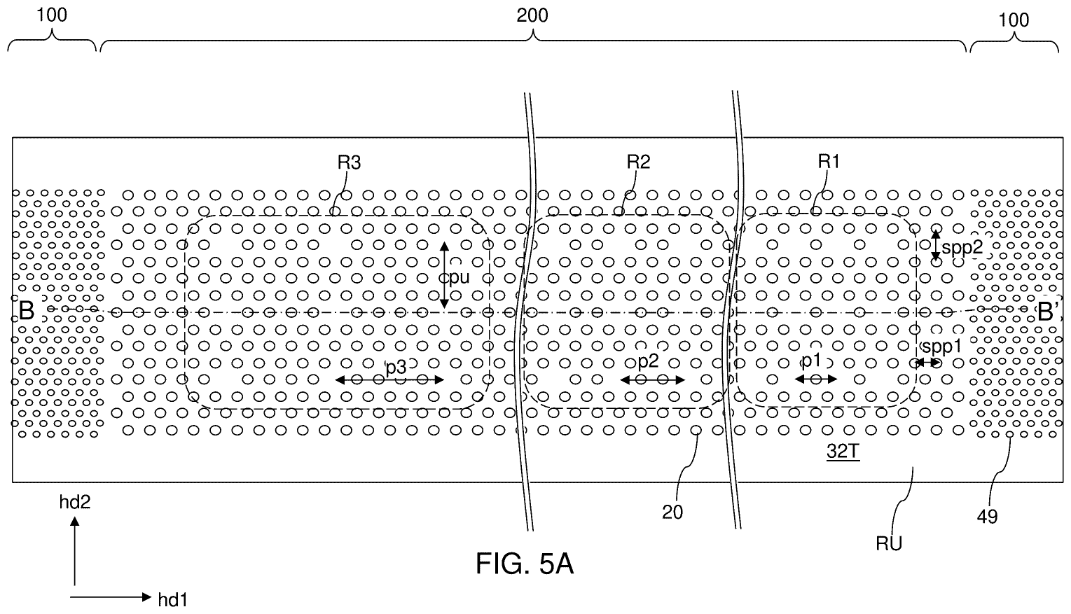

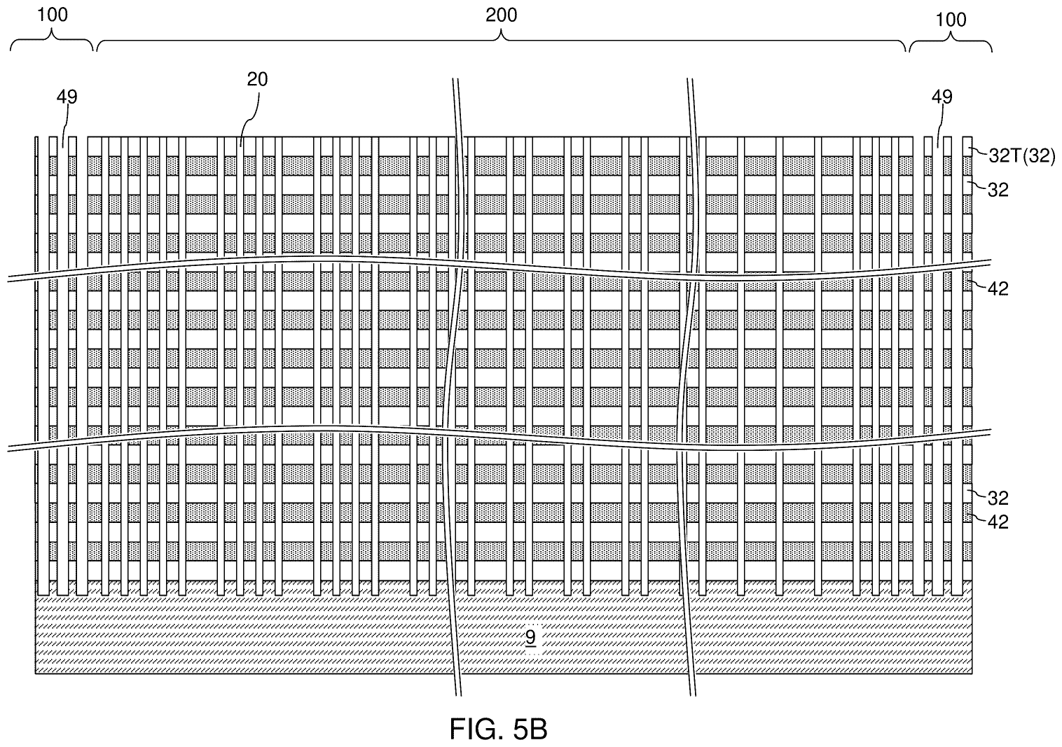

Referring to FIGS. 5A and 5B, the sacrificial memory opening fill structures 47 can be removed selective to the materials of the alternating stack (32, 42) and the semiconductor material layer 9 by performing a selective removal process, which may comprise an ashing process or a selective etch process (which may comprise a dry etch process or a wet etch process). Voids are formed in the volumes of the memory openings 49.

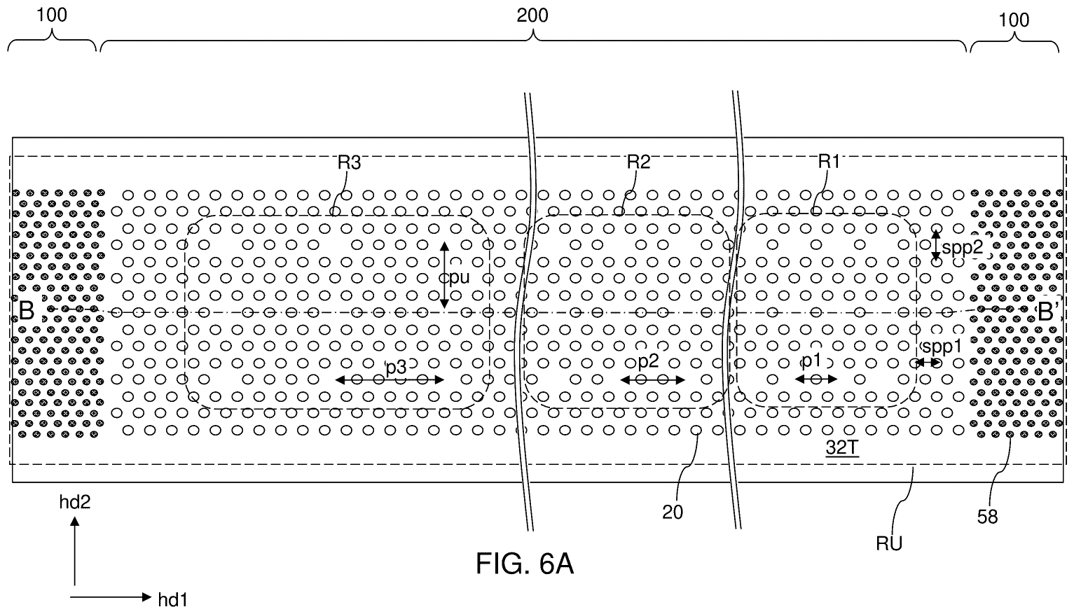

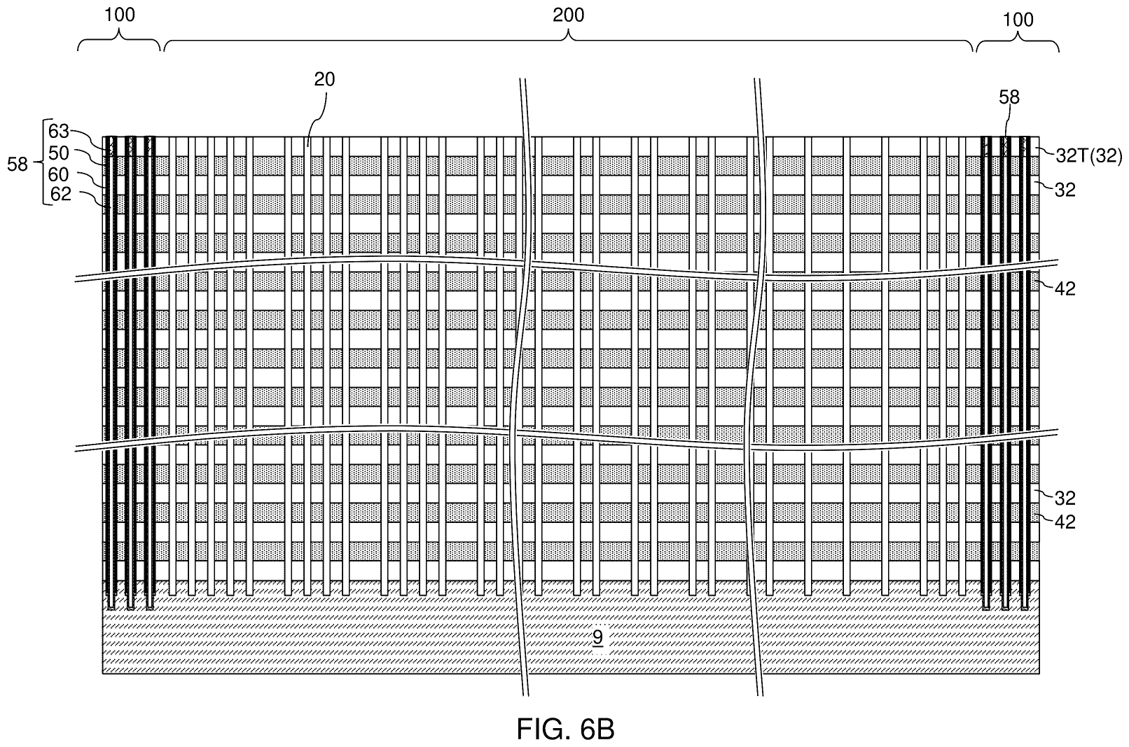

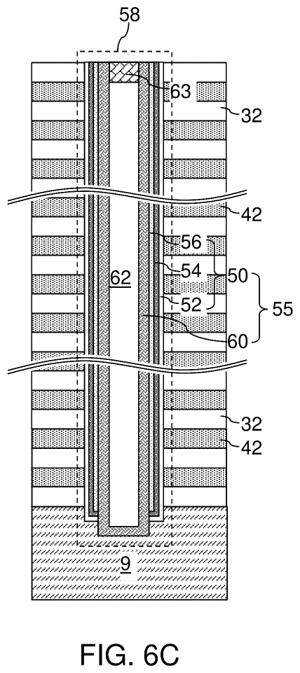

Referring to FIGS. 6A-6C, a memory opening fill structure 58 can be formed within each memory opening 49. For example, a memory film 50 can be formed in a peripheral region of each memory opening 49 by performing at least one conformal deposition process. In one embodiment shown in FIG. 6C, the memory film 50 may include a layer stack of a blocking dielectric layer 52, a memory material layer 54 (which may comprise a charge storage layer, such as a silicon nitride layer, or any alternative type of memory material layer, such as a ferroelectric material layer), and an optional dielectric liner 56 (such as a tunneling dielectric layer). Generally, the memory film 50 comprises a vertical stack of memory elements, which may be located at levels of the sacrificial material layers 42. For example, portions of a charge material layer located at the levels of the sacrificial material layers constitute charge storage material portions, which are memory elements. An optional anisotropic etch process may be performed to remove horizontally-extending portions of the memory film 50, for example, at the bottom of each memory opening 49 and from above the alternating stack (32, 42). A vertical semiconductor channel 60 and a dielectric core 62 can be formed in an inner region of each memory opening 49. The vertical semiconductor channels 60 may comprise a polysilicon or an amorphous silicon layer have a doping of a first conductivity type. A drain region 63 having a doping of a second conductivity type may be formed at an upper end of each vertical semiconductor channel 60. The combination of the memory film 50 and the vertical semiconductor channel 60 within each memory opening 49 constitutes a memory stack structure 55. The set of all material portions filling a memory opening 49 constitutes a memory opening fill structure 58. Each of the memory opening fill structures 58 comprises a respective vertical stack of memory elements.

In another alternative embodiment, the steps described above with respect to FIGS. 3A, 3B, 4A and 4B are omitted. In this alternative embodiment, dummy memory opening fill structures are formed in the support openings 19 at the same time as the memory opening fill structures 58 are formed in the memory openings. The dummy memory opening fill structures function as the support pillar structures 20, and are electrically inactive. In other words, they are not electrically connected to bit lines to be formed during a subsequent step.

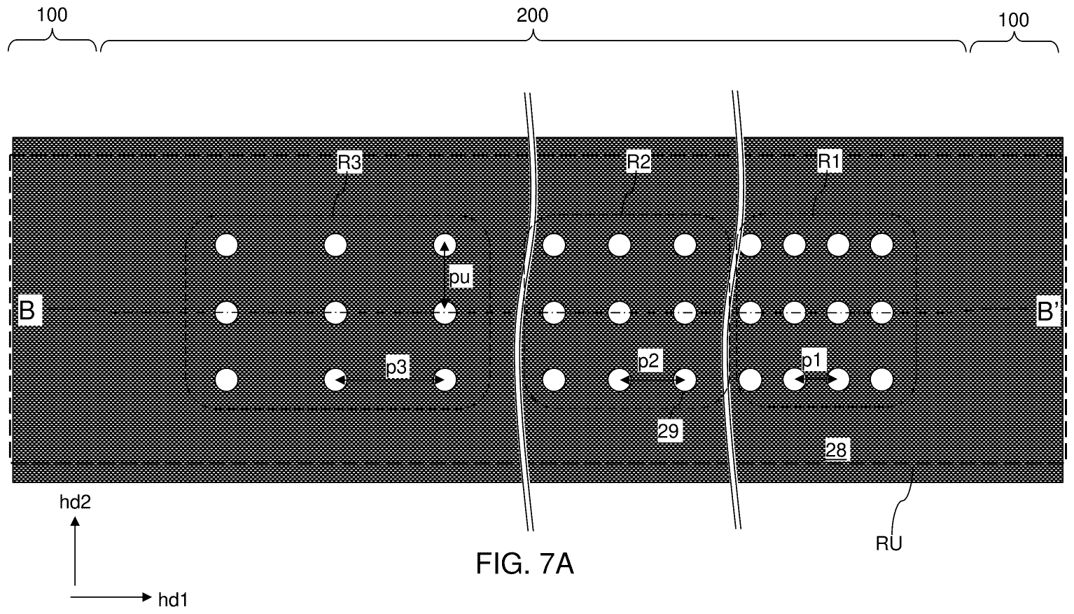

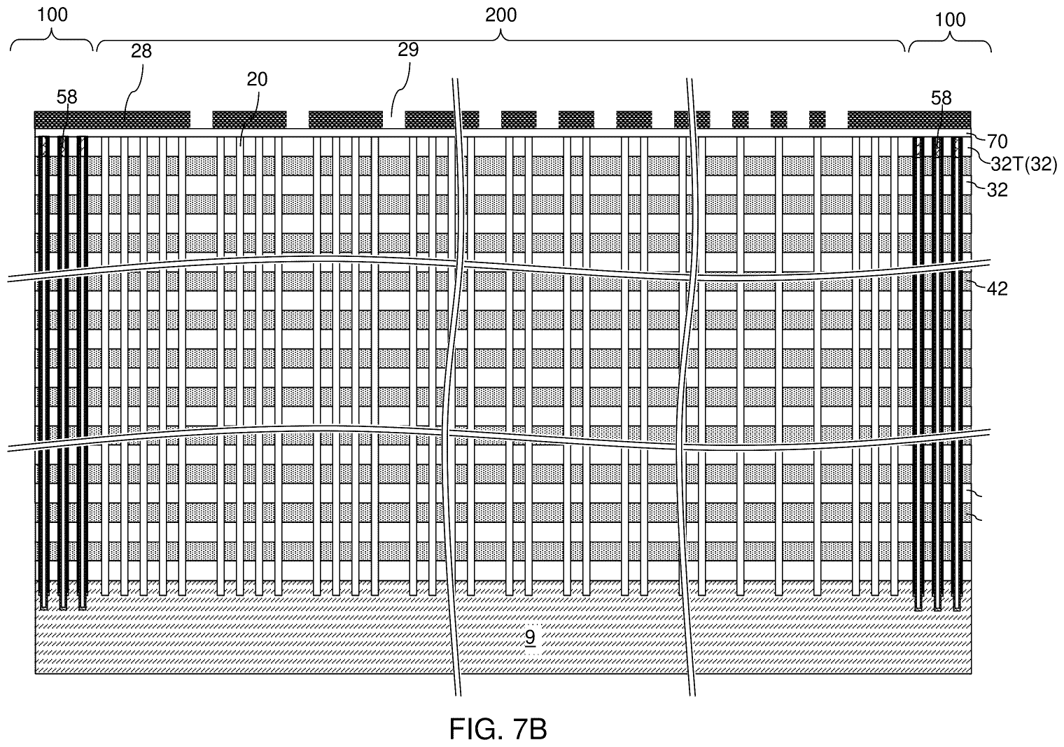

Referring to FIGS. 7A and 7B, an insulating cap layer 70 and a patterned hard mask layer 28 can be formed over the alternating stack (32, 42). The insulating cap layer 70 comprises an insulating material, such as silicon oxide. The thickness of the insulating cap layer 70 may be in a range from 10 nm to 300 nm, such as from 20 nm to 150 nm, although lesser and greater thicknesses may also be employed. The patterned hard mask layer 28 comprises a hard mask material that can function as an etch mask material during subsequent anisotropic etch processes to be employed to etch materials of the insulating layers 32 and the sacrificial material layers 42. For example, the hard mask material of the patterned hard mask layer 28 may comprise a metallic material such as TiN, TaN, WN, MON, Ti, Ta, W, Mo, or a combination thereof.

The patterned hard mask layer 28 may be formed by depositing a blanket hard mask layer (i.e., an unpatterned hard mask layer), and by patterning the blanket hard mask layer. For example, a photoresist layer (not shown) can be deposited over the blanket hard mask layer, and can be lithographically patterned to form openings at locations of the complementary subset of the lattice sites of the first periodic two-dimensional array described above.

An anisotropic etch process can be performed to transfer the pattern of the openings in the photoresist layer through the blanket hard mask layer, thereby converting the blanket hard mask layer into the patterned hard mask layer 28. The patterned hard mask layer 28 may comprise arrays of openings 29 therethrough.

In one embodiment, the first exemplary structure comprises a first region R1 including a first two-dimensional array of a first subset of the openings 29 having the first periodic pitch p1 along the first horizontal periodicity direction, a second region R2 including a second two-dimensional array of a second subset of the openings 29 having the second periodic pitch p2 along the first horizontal periodicity direction, and a third region R3 including a third two-dimensional array of a third subset of the openings 29 having the third periodic pitch p3. In one embodiment, the second periodic pitch p2 is greater than the first periodic pitch p1, and the third periodic pitch p3 is greater than the second periodic pitch p2. In one embodiment, the ratio of the second periodic pitch p2 to the first periodic pitch p1 is in a range from 1.2 to 2, and the ratio of the third periodic pitch p3 to the second periodic pitch p2 is in a range from 1.2 to 2. In an alternative embodiment, all openings 29 have the same pitch throughout the contact region 200.

In one embodiment, the first horizontal periodicity direction is the first horizontal direction hd1. In one embodiment, the first two-dimensional array comprises a first two-dimensional periodic array having a uniform pitch pu along the second horizontal periodicity direction that is different from the first horizontal periodicity direction, and the second two-dimensional array comprises a second two-dimensional periodic array having the uniform pitch pu along the second horizontal periodicity direction. In one embodiment, the quasi-periodic two-dimensional array of support pillar structures 20 vertically extends through the alternating stack (32, 42). The support pillar structures 20 in the quasi-periodic two-dimensional array are located at a primary subset of lattice sites of a first periodic two-dimensional array having the first support-pillar periodicity along the first horizontal direction hd1 and having the second support-pillar periodicity along the second horizontal direction hd2 in a plan view. The openings 29 in the patterned hard mask layer 28 may be located at a complementary subset of the vacancy lattice sites of the first periodic two-dimensional array.

In one embodiment, the second region R2 is laterally spaced from the first region R1 along the first horizontal direction hd1, and the third region R3 is laterally spaced from the second region R2 along the first horizontal direction hd1. In one embodiment, the first horizontal direction hd1 is parallel to the first horizontal periodicity direction, and the second horizontal direction hd2 is perpendicular to the first horizontal periodicity direction.

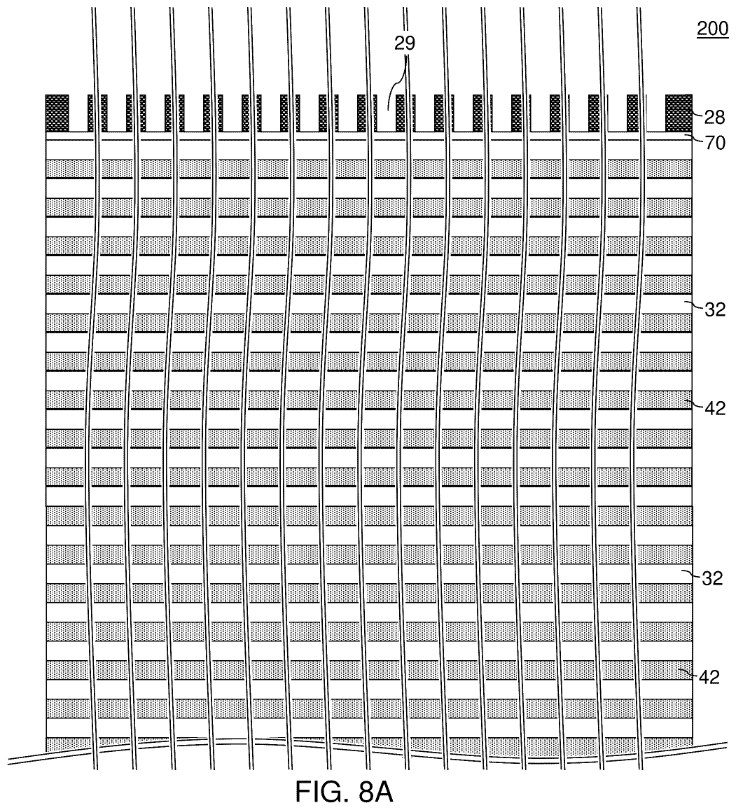

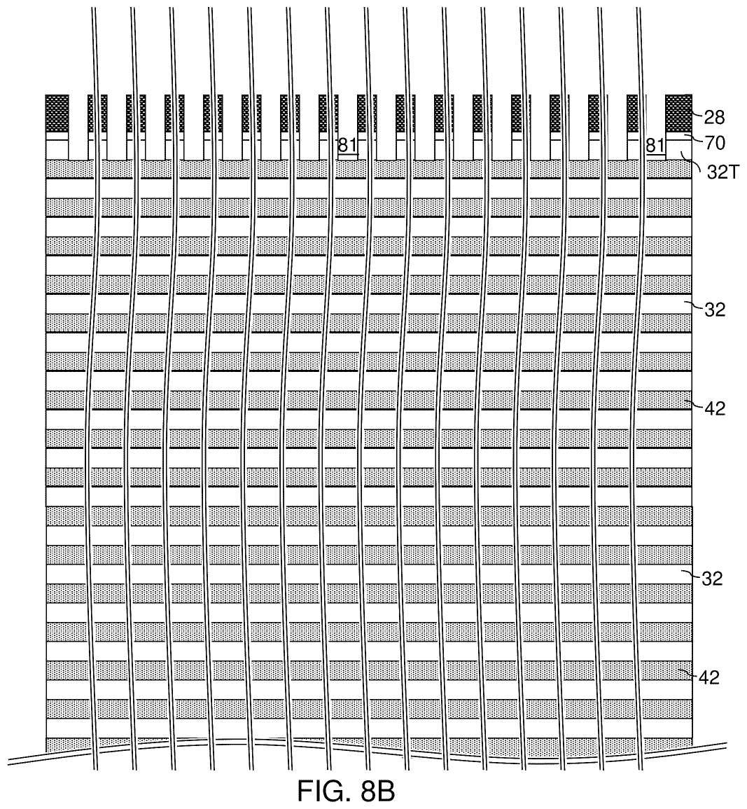

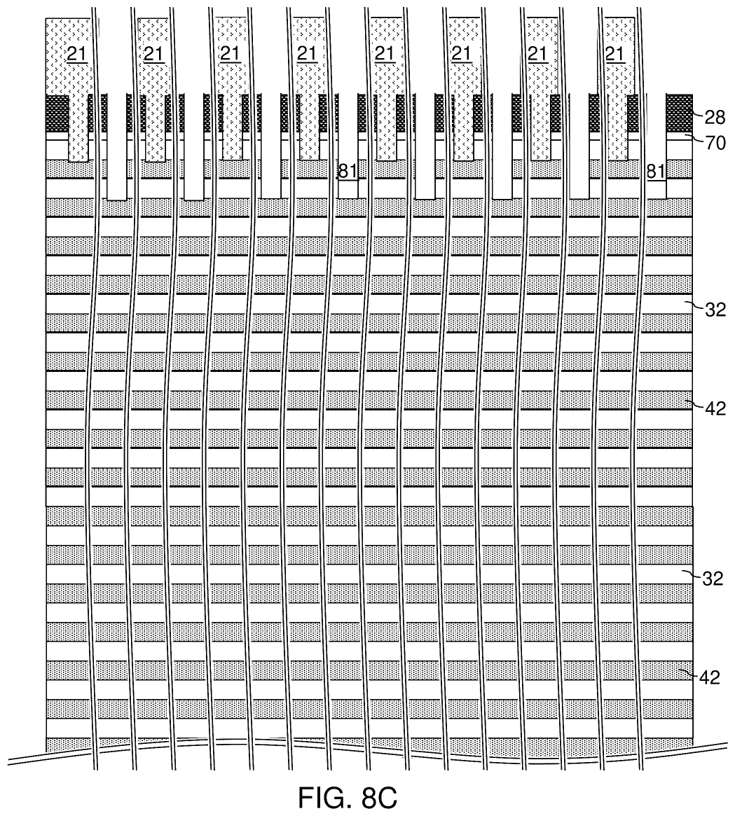

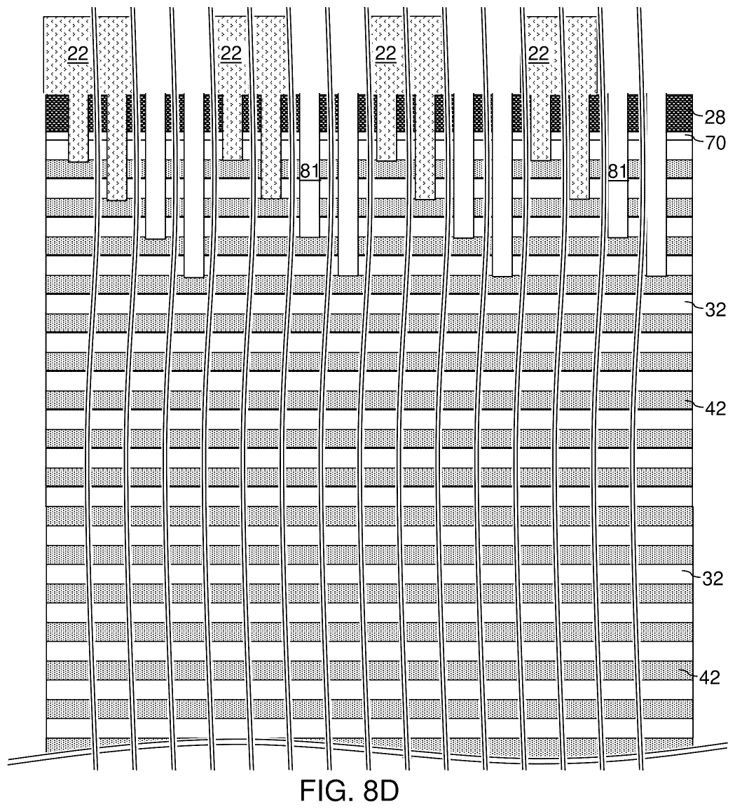

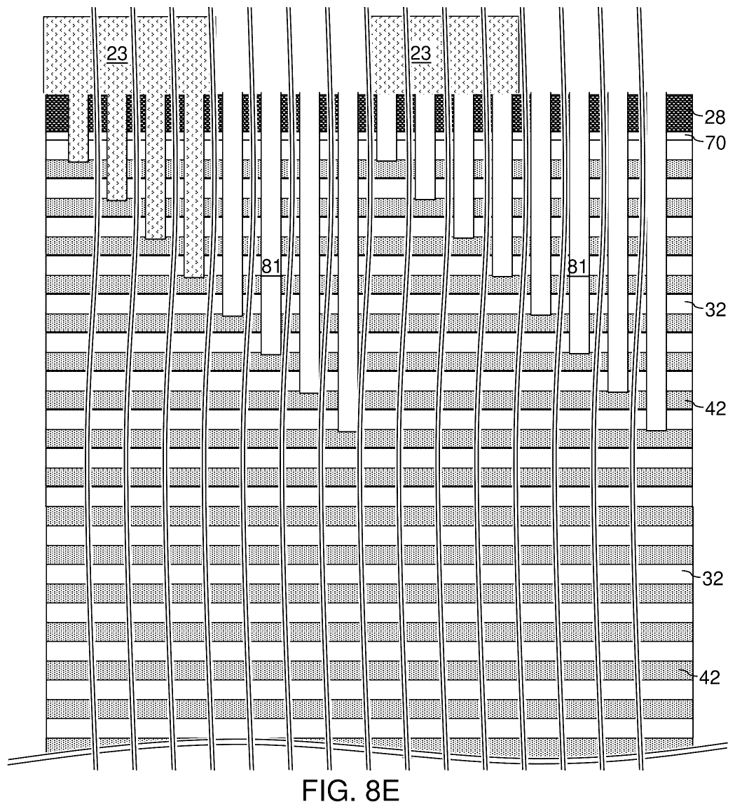

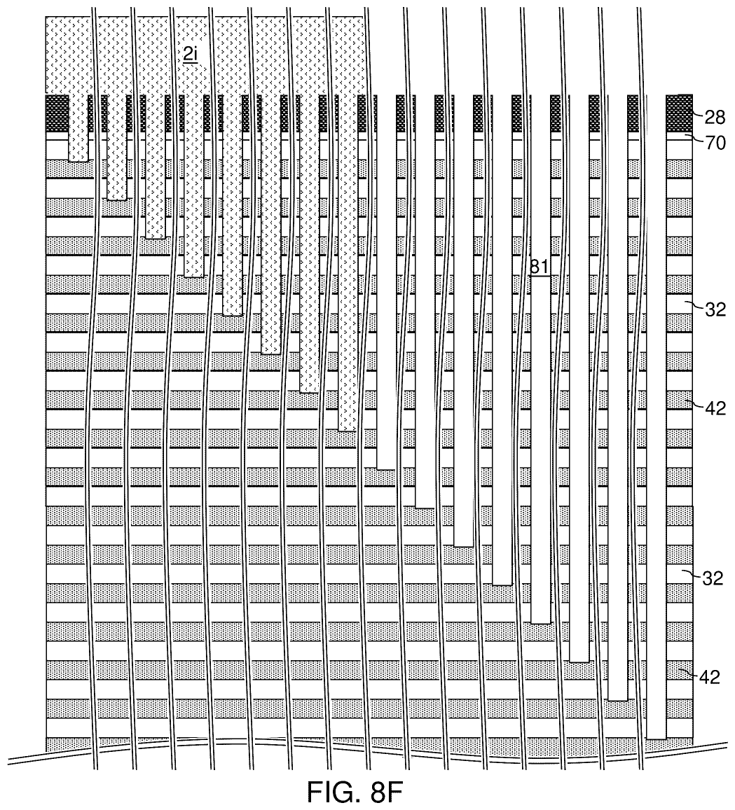

FIGS. 8A-8F are sequential schematic vertical cross-sectional view of region of the first exemplary structure during formation of contact via openings 81 according to an embodiment of the present disclosure.

Referring to FIG. 8A, a portion of the contact region 200 in the first exemplary structure of FIGS. 7A and 7B is illustrated.

Referring to FIG. 8B, an anisotropic etch process (which is also referred to as an initial anisotropic etch process) can be performed to etch through the topmost first-tier insulating layer 32T underneath the openings in the patterned hard mask layer 28. Via cavities can be formed through the topmost insulating layer 32T. The via cavities are herein referred to as contact via openings 81.

Referring to FIG. 8C, a first photoresist layer 21 can be applied over the patterned hard mask layer 28, and can be lithographically patterned to form openings in areas of a first primary subset of the contact via openings 81 without covering areas of a first complementary subset of the contact via openings 81. About one half of all of the contact via openings 81 can be covered the first photoresist layer 21. The first complementary subset of the contact via openings 81 can be vertically extended through the alternating stack by a first vertical extension distance, which can be the same as the sum of a thickness of an insulating layers 32 and a sacrificial material layer 42. The first photoresist layer 21 can be subsequently removed, for example, by ashing.

Referring to FIG. 8D, a second photoresist layer 22 can be applied over the patterned hard mask layer 28, and can be lithographically patterned to form openings in areas of a second primary subset of the contact via openings 81 without covering areas of a second complementary subset of the contact via openings 81. About one half of all of the contact via openings 81 can be covered the second photoresist layer 22. In one embodiment, the pattern of the second photoresist layer 22 can be selected such that four types of openings 29 in the patterned hard mask layer 28 are provided depending on whether an opening 29 is covered by first photoresist layer 21 at the processing steps of FIG. 8C and depending on whether the opening 29 is covered by the second photoresist layer 22 at the processing steps of FIG. 8D. The second complementary subset of the contact via openings 81 can be vertically extended through the alternating stack by a second vertical extension distance, which can be twice the sum of a thickness of an insulating layers 32 and a sacrificial material layer 42. The second photoresist layer 22 can be subsequently removed, for example, by ashing.

Referring to FIG. 8E, a third photoresist layer 23 can be applied over the patterned hard mask layer 28, and can be lithographically patterned to form openings in areas of a third primary subset of the contact via openings 81 without covering areas of a third complementary subset of the contact via openings 81. About one half of all of the contact via openings 81 can be covered the third photoresist layer 23. In one embodiment, the pattern of the third photoresist layer 23 can be selected such that up to eight types of openings 29 in the patterned hard mask layer 28 are provided depending on whether an opening 29 is covered by first photoresist layer 21 at the processing steps of FIG. 8C, depending on whether the opening 29 is covered by the second photoresist layer 22 at the processing steps of FIG. 8D, and depending on whether the openings 29 is covered by the third photoresist layer 23 at the processing steps of FIG. 8E. The third complementary subset of the contact via openings 81 can be vertically extended through the alternating stack by a third vertical extension distance, which may be four times the sum of a thickness of an insulating layers 32 and a sacrificial material layer 42. The third photoresist layer 23 can be subsequently removed, for example, by ashing.

Referring to FIG. 8F, the processing steps described with reference to FIGS. 8C-8E may be repeated with suitable modifications in the pattern of a photoresist layer and the anisotropic etch depth. Generally, for each integer i in a range from 1 to N, in which N is an integer in a range from 3 to 10 and i is a positive integer not greater than N, an i-th photoresist layer 2i can be applied over the patterned hard mask layer 28, and can be lithographically patterned to form openings in areas of an i-th primary subset of the contact via openings 81 without covering areas of an i-th complementary subset of the contact via openings 81. About one half of all of the contact via openings 81 can be covered the i-th photoresist layer 2i. In one embodiment, the pattern of the i-th photoresist layer 2i can be selected such that up to 2i types of openings 29 in the patterned hard mask layer 28 are provided depending on whether an opening 29 is covered by each photoresist layer including the first photoresist layer and up to the i-th photoresist layer 2i. The i-th complementary subset of the contact via openings 81 can be vertically extended through the alternating stack by an i-th vertical extension distance, which can be an integer multiple of the sum of a thickness of an insulating layers 32 and a sacrificial material layer 42. The integer multiple may be a number that may be equal to, or may be less than, 2(i-1). The i-th photoresist layer 2i can be subsequently removed, for example, by ashing.

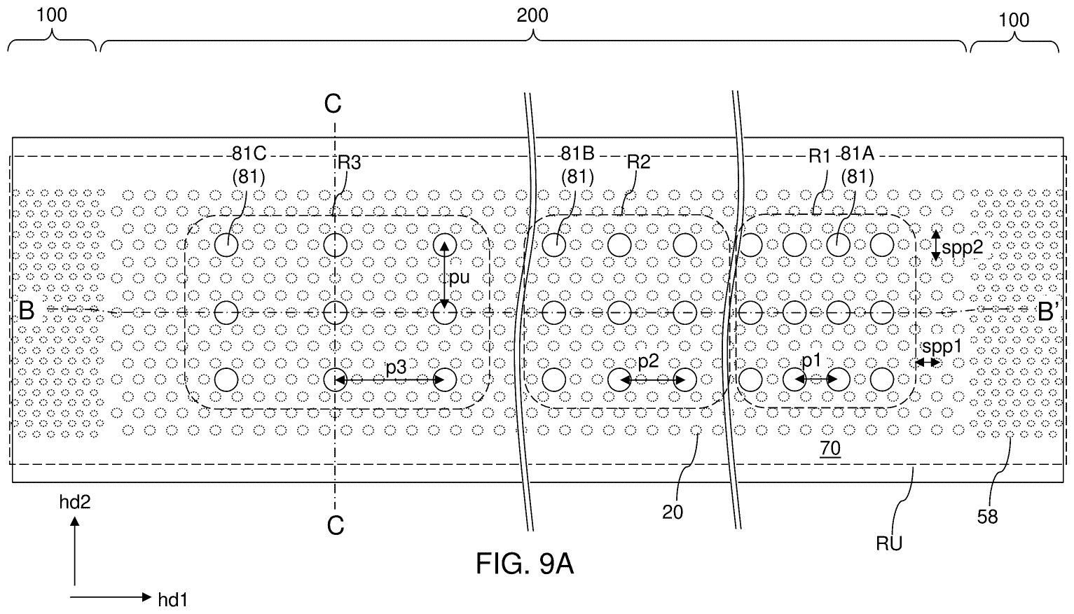

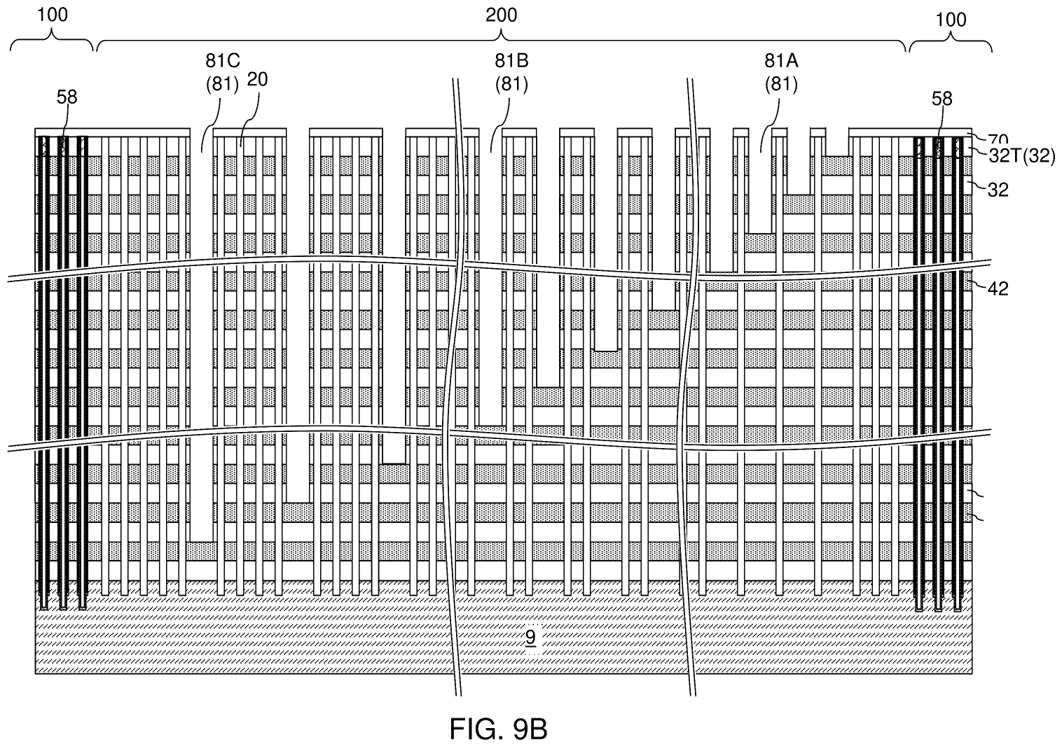

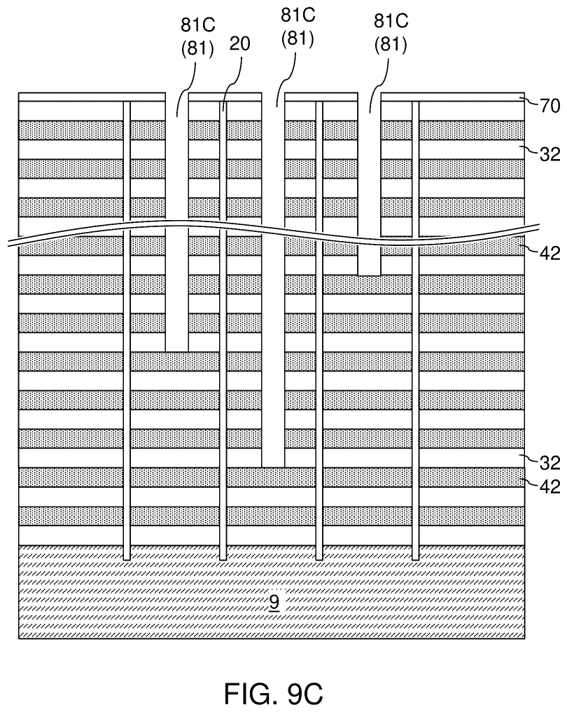

Referring to FIGS. 9A-9C, the first exemplary structure is illustrated after performing the N-th anisotropic etch process. The contact via openings 81 may have up to 2N different depths. The patterned hard mask layer 28 can be subsequently removed, for example, by performing a selective etch process that etches the material of the patterned hard mask layer 28 selective to the materials of the insulating layers 32 and the sacrificial material layers 42.

Generally, the pattern of the photoresist layers (21, 22, 23, etc.) can be selected such that a first subset of the contact via openings 81 formed within the first region R1 has a first average depth, a second subset of the contact via openings 81 formed within the second region R2 has a second average depth greater than the first average depth, and a third subset of the contact via openings 81 formed within the third region R3 has a third average depth greater than the second average depth, as shown in FIG. 9B. The first subset of the contact via openings 81 is herein referred to as first contact via openings 81A, the second subset of the contact via openings 81 is herein referred to as second contact via openings 81B, and the third subset of the contact via openings 81 is herein referred to as third contact via openings 81C. In one embodiment, the maximum depth of the first contact via openings 81A may be less than the minimum depth of the second contact via openings 81B, and the maximum depth of the second contact via openings 81B may be less than the minimum depth of the third contact via openings 81C. In one embodiments, the first contact via openings 81A have a shallower average depth than the second contact via openings 81B, and the second contact via openings 81B may be have a shallower average depth average depth than the third contact via openings 81C. The shallower first contact via openings 81A in the first region R1 have a smaller pitch (i.e., a higher density per unit area) than the deeper second contact openings 81B in the second region R2. The shallower second contact via openings 81B in the second region R1 have a smaller pitch (i.e., a higher density per unit area) than the deeper third contact openings 81C in the third region R3.

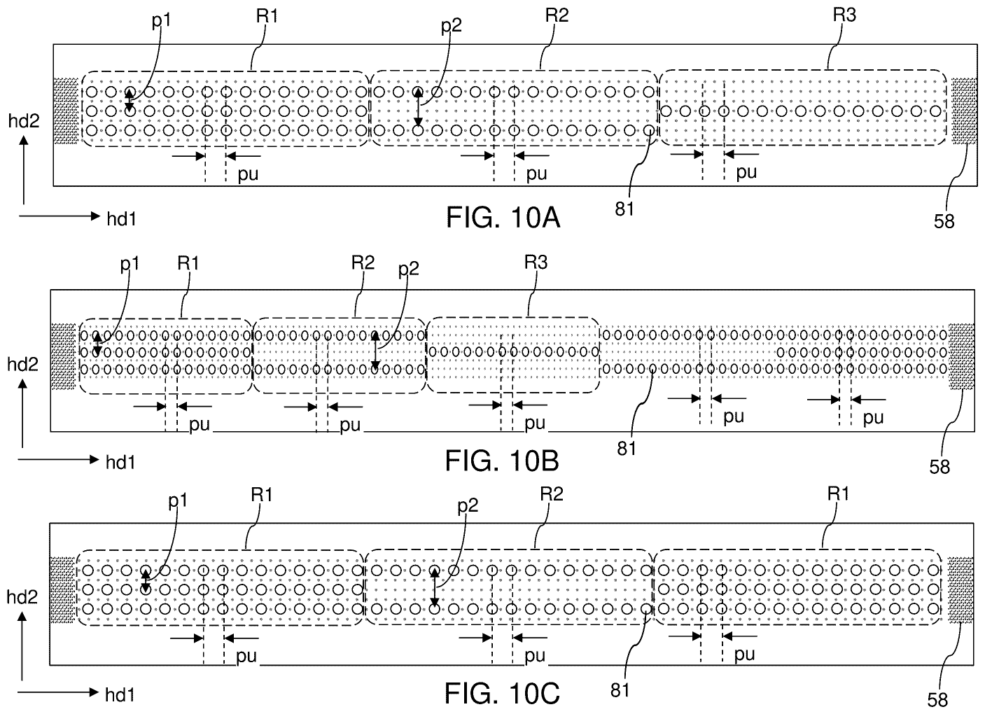

FIGS. 10A-10C are top-down views of alternative configuration of the first exemplary structure after the processing steps of FIGS. 9A-9C according to an alternative embodiment of the present disclosure. In the alternative configurations of the first exemplary structure, the first horizontal periodicity direction along which a first subset of the contact via openings 81 has a first periodic pitch p1, a second subset of the contact via openings 81 has a second periodic pitch p2, and a third subset of the contact via openings 81 has a third periodic pitch p3 can be the second horizontal direction hd2. Further, the second horizontal periodicity direction along which the first subset of the contact via openings 81, the second subset of the contact via openings 81, and the third subset of the contact via openings 81 have the uniform pitch pu may be the first horizontal direction hd1.

In other words, in this alternative embodiment, there may be more rows of shallower first contact via openings 81A extending along the first horizontal direction hd1 in the first region R1 than of the deeper second contact via openings 81B in the second region R2. There also may be more rows of shallower second contact via openings 81B in the second region R2 than of the deeper third contact via openings 81C in the third region R3. Therefore, in this alternative embodiment, the shallower contact via openings also have a higher density per unit area than the deeper contact via openings.

Referring collectively to FIGS. 9A-9C and 10A-10C, an array of contact via openings 81 can be formed such that each of the contact via openings 81 is formed on a respective one of the sacrificial material layers 42 and vertically extends through a respective subset of layers within the alternating stack (32, 42) that overlies the respective one of the sacrificial material layers 42. In one embodiment, the first exemplary structure comprises a first region R1 including a first two-dimensional array of a first subset of the contact via openings 81 that has a first average height and a first periodic pitch p1 along a first horizontal periodicity direction; a second region R2 including a second two-dimensional array of a second subset of the contact via openings 81 having a second average height and a second periodic pitch p2 along the first horizontal periodicity direction; and optionally a third region R3 including a third two-dimensional array of a third subset of the contact via openings 81 having a third average height and a third periodic pitch p3 along the first horizontal periodicity direction. The second average height is greater than the first average height; and the third average height is greater than the second average height. The second periodic pitch p2 is greater than the first periodic pitch p1, and the third periodic pitch p3 is greater than the second periodic pitch p2. Therefore, the shallower contact via openings have a higher density per unit area than the deeper contact via openings.

In one embodiment, a cavity-volume to region-area ratio of a total volume of the contact via openings 81 within a selected region (R1, R2, R3) to the total area of the selected region (R1, R2, R3) is about the same (i.e., within 30% of each other, such as within 20% of each other, such as within 0 to 10% of each other). In other words, the cavity-volume to region area ratios across the first region R1, the second region R2, and the third region R3 may be about the same. Thus, each value of the cavity-volume to region-area ratios for the first region R1, the second region R2, and the third region R3 may be between 0.7 and 1.3 times (e.g., between 0.8 and 1.2 times, such as between 0.9 and 1.1 times) the average of the cavity-volume to region area ratios of the first region R1, the second region R2, and the third region R3.

According to an embodiment of the present disclosure, the relative uniformity of the cavity-volume to region-area ratios for the various regions in the contact region 200 (such as the first region R1, the second region R2, and the third region R3) provides the benefit of reducing a photoresist sucking effect during the processing steps described with reference to FIGS. 8C-8F, i.e., the processing steps employed to form the contact via openings 81A. Specifically, application of the photoresist layers (21, 22, 23, 2i), especially for the photoresist layers that are formed closer toward the final patterning steps for formation of the contact via openings 81, causes a photoresist material to be sucked into the voids within the contact via openings 81. Local thickness reduction of the photoresist material occurs around deep contact via openings 81. Typically, more photoresist is sucked into the deeper openings than the shallow openings, which causes the top surface of the photoresist layer to become uneven. This degrades the quality of the exposure of the photoresist layer. According to an aspect of the present disclosure, the areal density of the contact via openings 81 can be reduced around a subset of the deeper contact via openings 81, such as the third contact via openings 81C, so that the effect of photoresist sucking into the deeper (i.e., higher volume) openings is reduced. In areas in which the areal density of the contact via openings 81 is low, such as the first region R1 including the shallower first contact via openings 81A, the areal density of the contact via openings 81 can be high so that the overall device density of a three-dimensional memory device to be subsequently formed can be increased.

In one embodiment, the first exemplary structures illustrated in FIGS. 9A-9C and 10A-10C, comprise a quasi-periodic two-dimensional array of support pillar structures 20 vertically extending through the alternating stack (32, 42). The support pillar structures 20 in the quasi-periodic two-dimensional array are located at a primary subset of lattice sites of a first periodic two-dimensional array having a first support-pillar periodicity spp1 along a first horizontal direction hd1 and having a second support-pillar periodicity spp2 along a second horizontal direction hd2 in a plan view. The contact via openings 81 are located at a complementary subset of the vacancy lattice sites of the first periodic two-dimensional array, and do not extend through the support pillar structures 20. In one embodiment, the second region R2 is laterally spaced from the first region R1 along the first horizontal direction hd1, and the third region R3 is laterally spaced from the second region R2 along the first horizontal direction hd1. In one embodiment, the first horizontal direction hd1 is parallel to the first horizontal periodicity direction, and the second horizontal direction hd2 is perpendicular to the first horizontal periodicity direction. In one embodiment, the first subset of the contact via openings 81 is formed at the vacancy lattice sites of a first subset of the complementary subset in the first region R1; and the second subset of the contact via openings 81 is formed at the vacancy lattice sites of a second subset of the complementary subset in the second region R2.

In an alternative embodiment, the support pillar structures 20 are arranged in a periodic two-dimensional array. In this alternative embodiment, some of the contact via openings 81 may extend through the support pillar structures 20 due to the different density of the contact via openings 81 which does not match the spacing of the periodic two-dimensional array of the support pillar structures 20.

In one embodiment, each of the contact via openings 81 contacts a respective one of the sacrificial material layers 42 and vertically extends through a respective subset of layers within the alternating stack (32, 42) that overlies the respective one of the sacrificial material layers 42. In one embodiment, the three-dimensional memory device comprises a first region R1 including a first two-dimensional array of a first subset of the contact via openings 81 that has a first average height and a first periodic pitch p1 along a first horizontal periodicity direction, and further comprises a second region R2 including a second two-dimensional array of a second subset of the contact via openings 81 having a second average height and a second periodic pitch p2 along the first horizontal periodicity direction. The second average height is greater than the first average height, and the second periodic pitch p2 is greater than the first periodic pitch p1.

In one embodiment, a ratio of the second average height to the first average height is in a range from 1.5 to 3; and a ratio of the second periodic pitch p2 to the first periodic pitch p1 is in a range from 1.2 to 2. In one embodiment, the first horizontal periodicity direction is the first horizontal direction hd1, as illustrated in FIGS. 9A-9C. In another embodiment, the first horizontal periodicity direction is the second horizontal direction hd2, as illustrated in FIGS. 10A-10C. In one embodiment, the first horizontal direction hd1 is parallel to the first horizontal periodicity direction; and the second horizontal direction hd2 is perpendicular to the first horizontal periodicity direction, as illustrated in FIGS. 9A-9C. In this embodiment, the first periodic pitch p1 is a first multiple, such as a first integer multiple of the first support-pillar periodicity spp1; and the second periodic pitch p2 is a second multiple, such as a second integer multiple of the first support-pillar periodicity spp1 as illustrated in FIGS. 10A-10C.

In one embodiment, the first two-dimensional array comprises a first two-dimensional periodic array of the first subset of the contact via openings 81 having a uniform pitch pu along a second horizontal periodicity direction that is different from the first horizontal periodicity direction; and the second two-dimensional array of the second subset of the contact via openings 81 comprises a second two-dimensional periodic array having the uniform pitch pu along the second horizontal periodicity direction.

In one embodiment, the first periodic pitch p1 is a first integer multiple of the second support-pillar periodicity spp2; and the second periodic pitch p2 is a second integer multiple of the second support-pillar periodicity spp2. In one embodiment, the first subset of the contact via openings 81 is located at lattice sites of a first subset of the complementary subset in the first region R1; and the second subset of the contact via openings 81 is located at lattice sites of a second subset of the complementary subset in the second region R2. In one embodiment, the first subset of the complementary subset has a uniform pitch pu along a second horizontal periodicity direction that is different from the first horizontal periodicity direction; and the second subset of the complementary subset has the uniform pitch pu along the second horizontal periodicity direction.

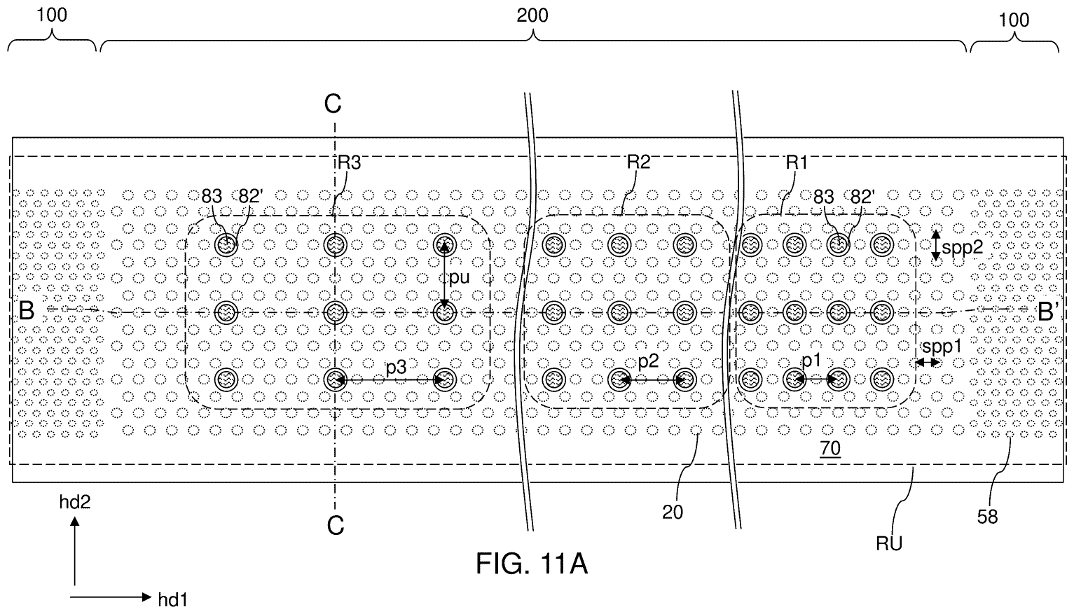

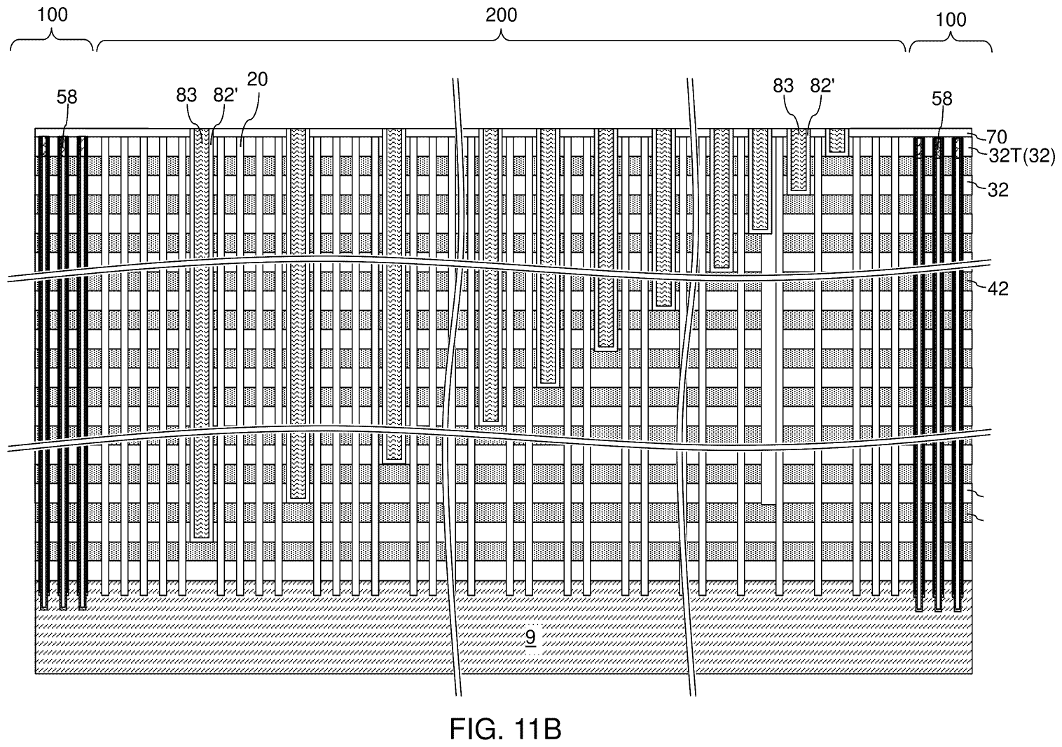

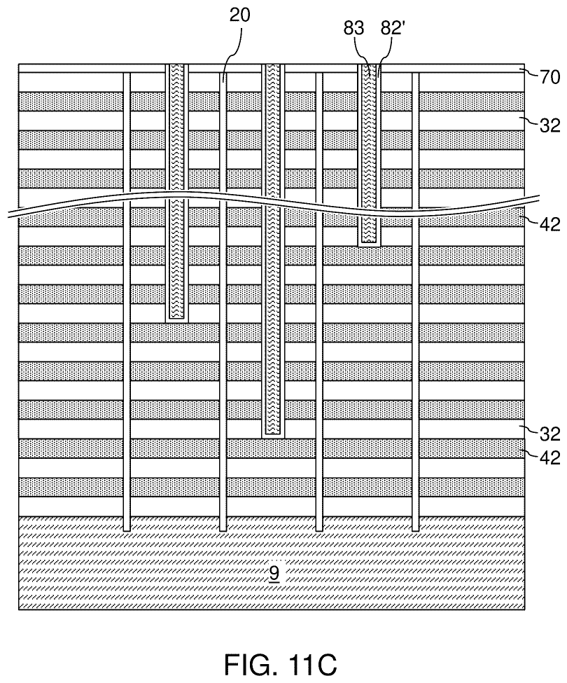

Referring to FIGS. 11A-11C, an insulating material, such as silicon oxide, can be conformally deposited in the contact via openings 89 and over the insulating cap layer 70 to form a conformal insulating material layer. An anisotropic etch process can be performed to remove horizontally-extending portions of the conformal insulating material layer. Each remaining portion of the conformal insulating material layer constitutes an insulating spacer 82′. Each insulating spacer 82′ is a dielectric via liner that contacts a sidewall of a respective one of the contact via openings 81. The insulating spacer 82′ can be formed at a peripheral portion of each contact via opening 81. A contact via opening can be present within each unfilled volume of the contact via openings 81.

A sacrificial via fill material can be deposited in the contact via openings, i.e., in the volumes of the contact via openings 81 that are not filled with the insulating spacer 82′. The sacrificial via fill material may comprise a semiconductor material (such as amorphous silicon, polysilicon, or silicon-germanium), a carbon-based material (such as amorphous carbon or diamond-like carbon), an organosilicate glass, or a polymer material. Excess portions of the sacrificial via fill material can be removed from above the horizontal plane including the top surface of the insulating cap layer 70. Each remaining portion of the sacrificial via fill material filling a respective contact via opening constitutes a sacrificial via opening fill structure 83. Top surface of the sacrificial via opening fill structures 83 may be coplanar with the top surface of the insulating cap layer 70.

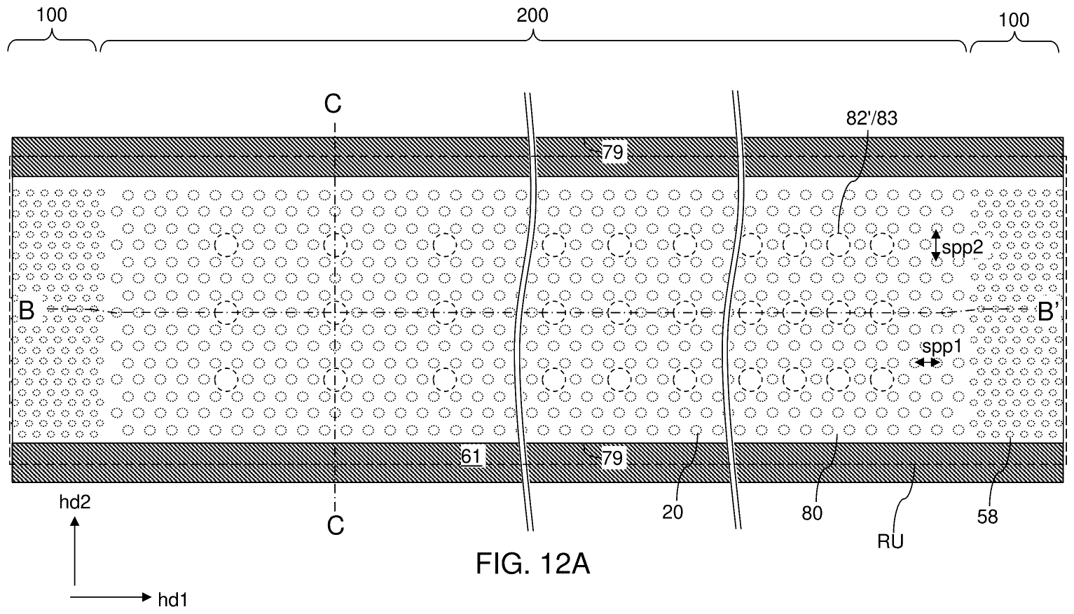

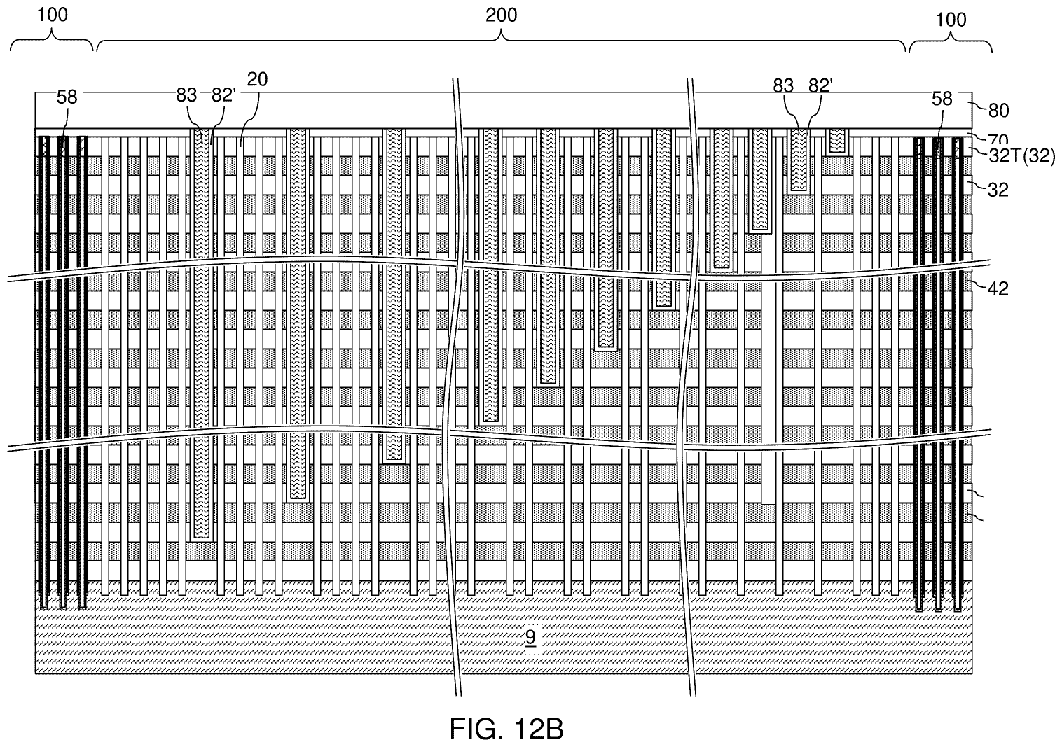

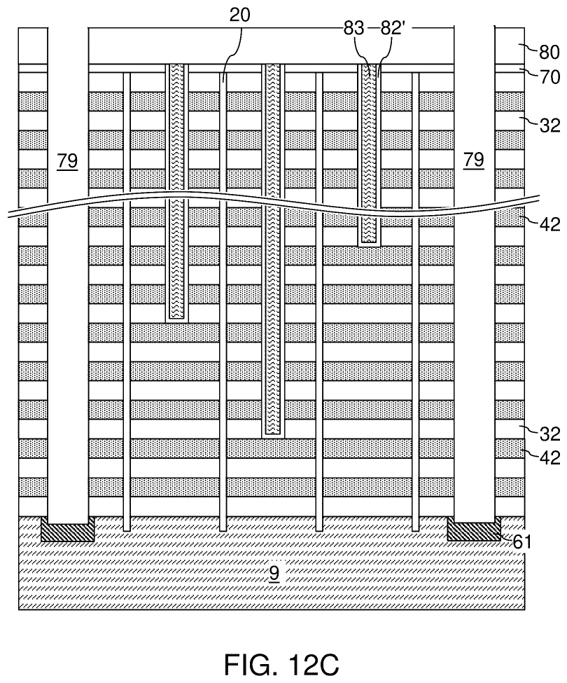

Referring to FIGS. 12A-12C, a dielectric material, such as silicon oxide, can be deposited over the insulating cap layer 70 to form a contact-level dielectric layer 80. A photoresist layer can be applied over the contact-level dielectric layer 80, and can be lithographically patterned to form various elongated openings therethrough. The elongated openings in the photoresist layer may comprise slit-shaped openings that are formed at or around the boundaries between neighboring pairs of repetition units (e.g., memory blocks) RU at which the memory opening fill structures 58 and the support pillar structures 20 are not present. An anisotropic etch process can be performed to transfer the pattern of the elongated openings in the photoresist layer through the contact-level dielectric layer 80 and the alternating stack of insulating layers 32 and sacrificial material layers 42 and optionally into an upper portion of the semiconductor material layer 9. Lateral isolation trenches 79 are formed underneath the slit-shaped openings in the photoresist layer. The lateral isolation trenches 79 are formed between a respective cluster of memory openings 49 to separate laterally adjacent memory blocks. The lateral isolation trenches 79 laterally extend along the first horizontal direction hd1. Generally, a pair of lateral isolation trenches 79 can laterally extend along a first horizontal direction hd1 through the alternating stacks (32, 42) such that each neighboring pair of alternating stacks (32, 42) are laterally spaced from each other along the second horizontal direction hd2. Source regions 61 may optionally be formed by implanting dopants of the second conductivity type into surface portions of the semiconductor material layer 9 that underlies the lateral isolation trenches 79.

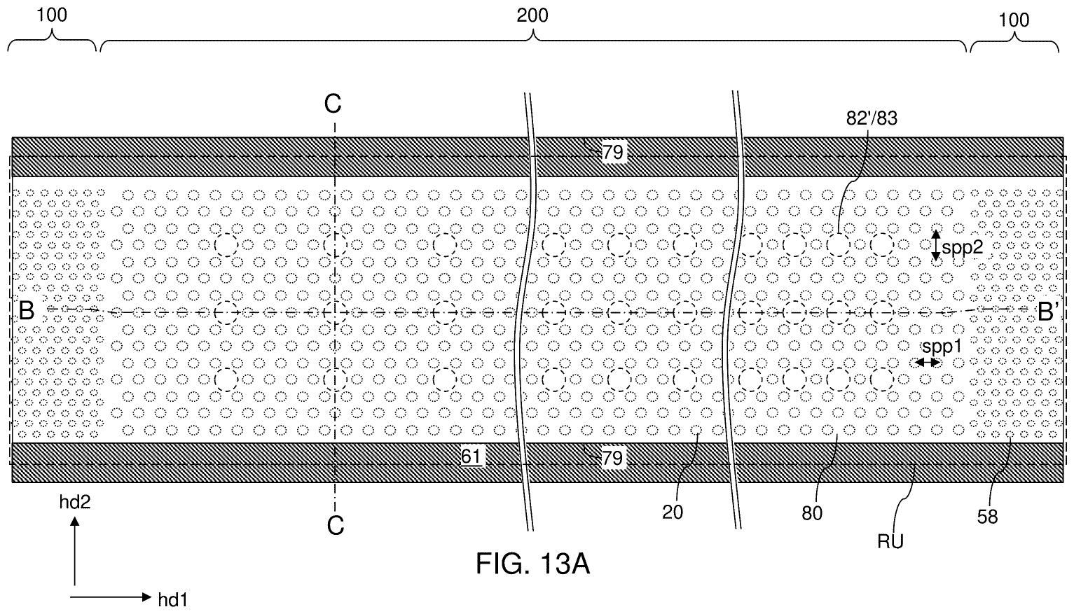

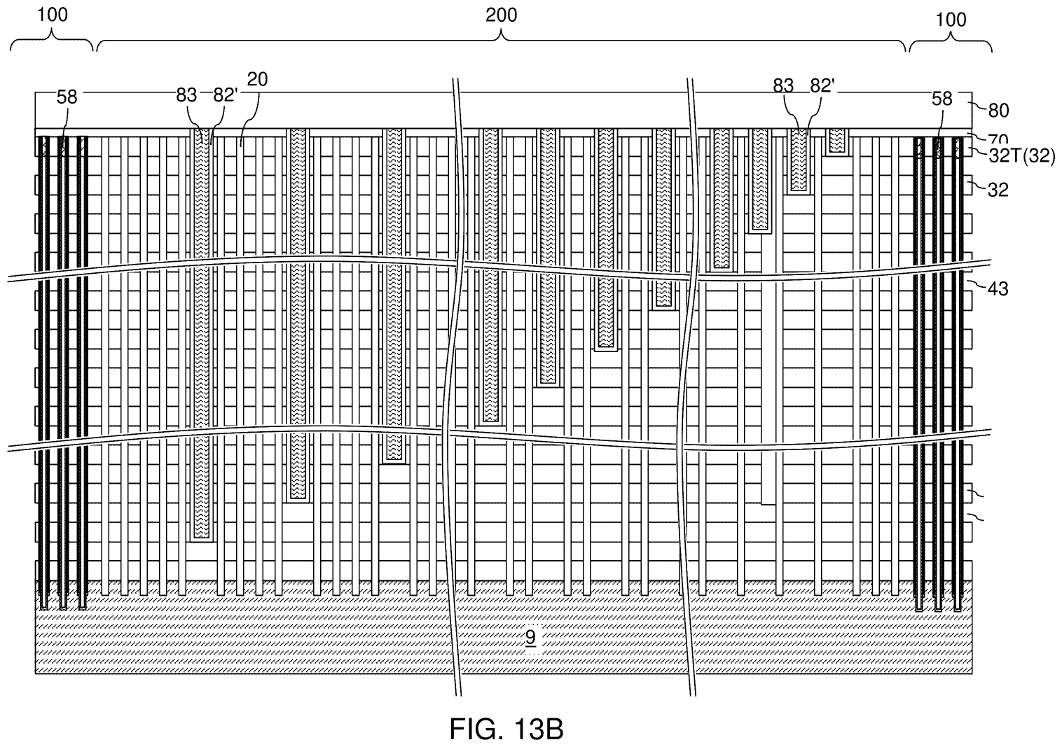

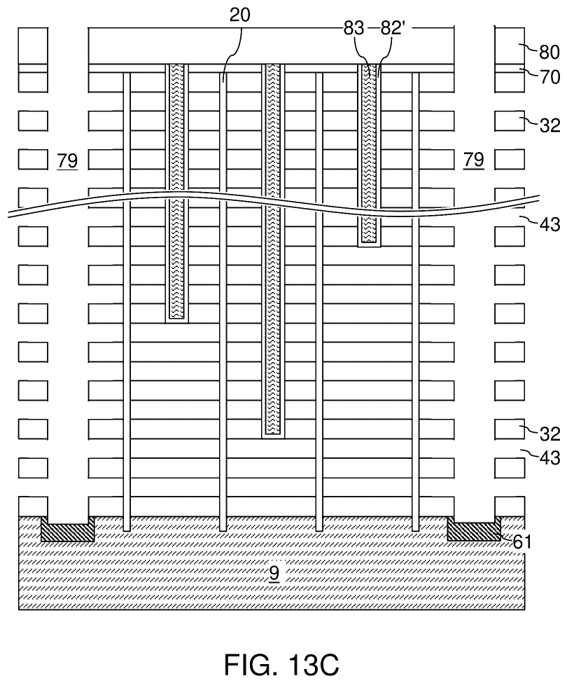

Referring to FIGS. 13A-13C, an isotropic etch process can be performed to etch the material of the sacrificial material layers 42 selective to materials of the insulating layers 32, the insulating spacers 82′, the insulating cap layer 70, the contact-level dielectric layer 80, the outermost layer of each memory film 50 (such as a blocking dielectric layer 52), and the semiconductor material layer 9. For example, if the sacrificial material layers 42 comprise silicon nitride, a wet etch process employing hot phosphoric acid may be performed to remove the sacrificial material layers 42. A laterally-extending cavity 43 can be formed within each void that is formed by removal of a portion of a sacrificial material layer 42. The laterally-extending cavities 43 can be formed around each contiguous combination of a sacrificial via opening fill structure 83 and an insulating spacer 82′.

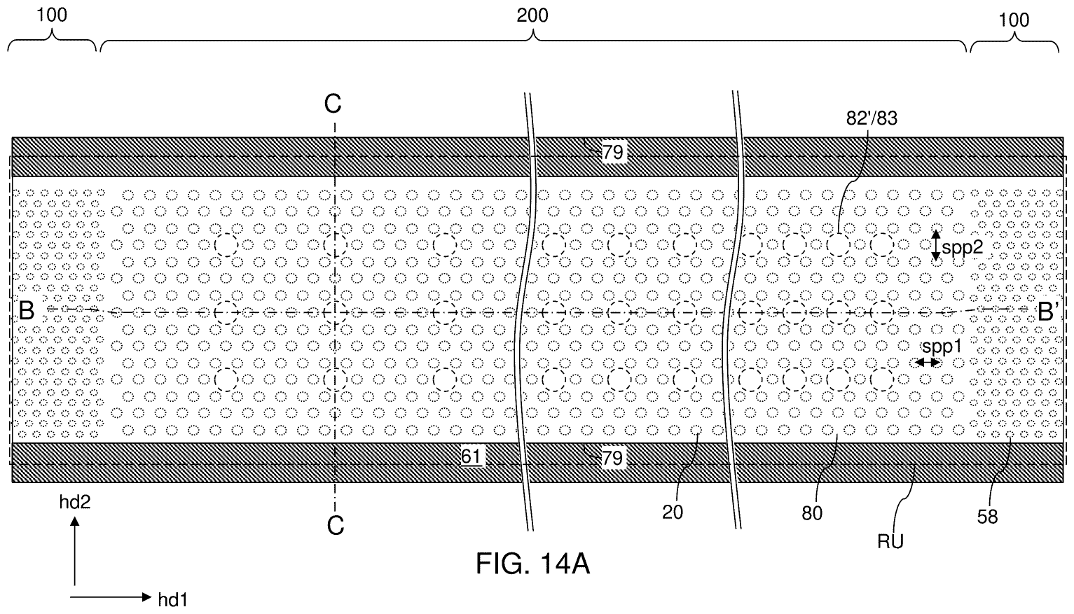

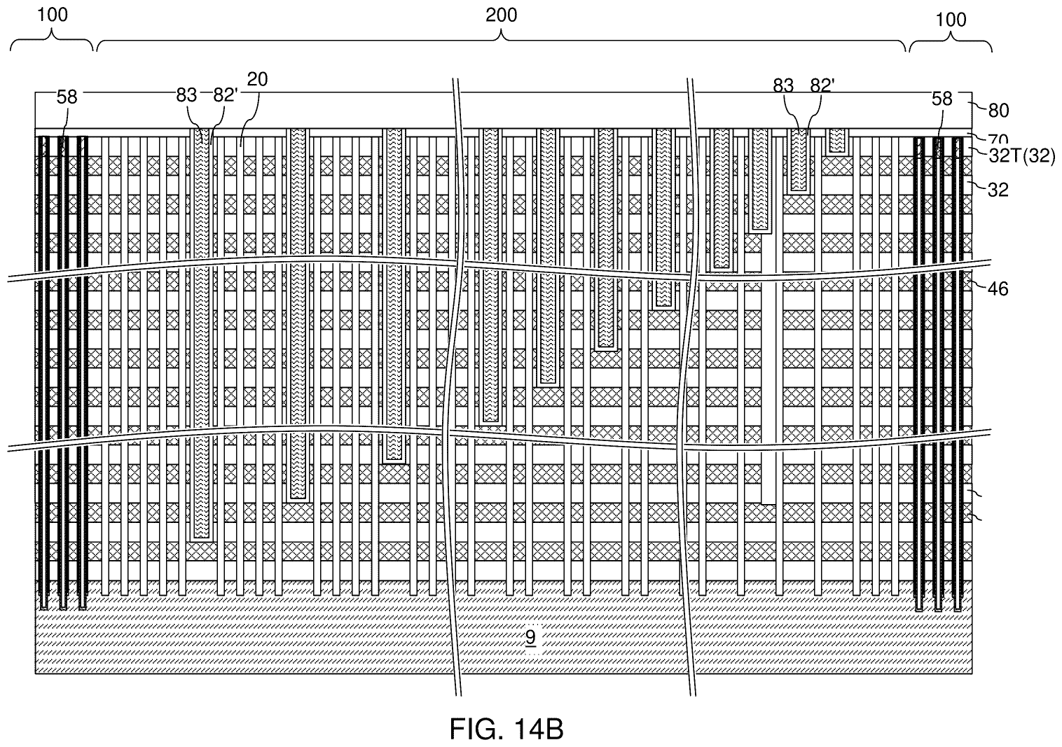

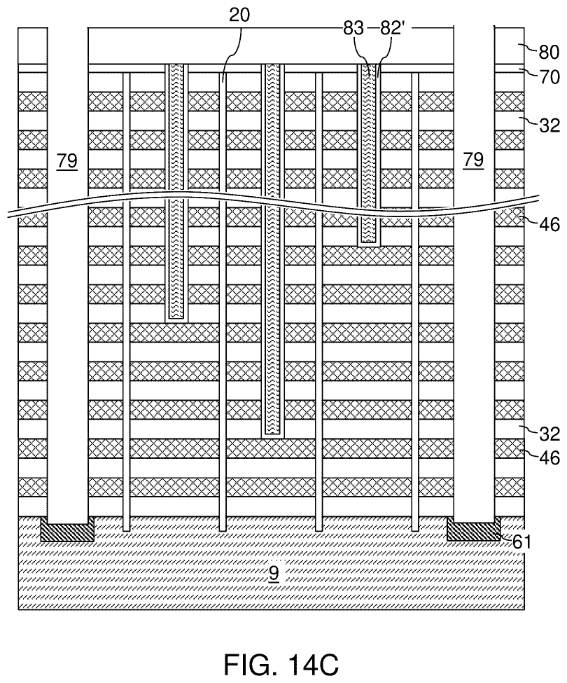

Referring to FIGS. 14A-14C, at least one conductive material, such as a combination of a metallic barrier liner material and a metal fill material, may be conformally deposited in the laterally-extending cavities 43, in peripheral regions of the lateral isolation trenches 79, and above the contact-level dielectric layer 80. The metallic barrier liner material may comprise a conductive metallic compound material such as TiN, TaN, WN, MON, TiC, TaC, WC, alloys thereof, or a combination thereof. The metal fill material may comprise W, Ti, Ta, Mo, Co, Ru, Cu, alloys thereof, or combinations thereof. The total thickness of the at least one conductive material is greater than one half of the height of each laterally-extending cavity 43.

A recess etch process can be performed to remove portions of the at least one conductive material that are present within the volumes of the lateral isolation trenches 79 or above the contact-level dielectric layer 80. The recess etch process may comprise an anisotropic etch process. Each remaining portion of the at least one conductive material filling a respective laterally-extending cavity 43 constitutes an electrically conductive layer 46. In one embodiment, sidewalls of the electrically conductive layers 46 in an alternating stack (32, 46) may be vertically coincident with (i.e., located within same vertical planes as) sidewalls of a pair of lateral isolation trenches 79.

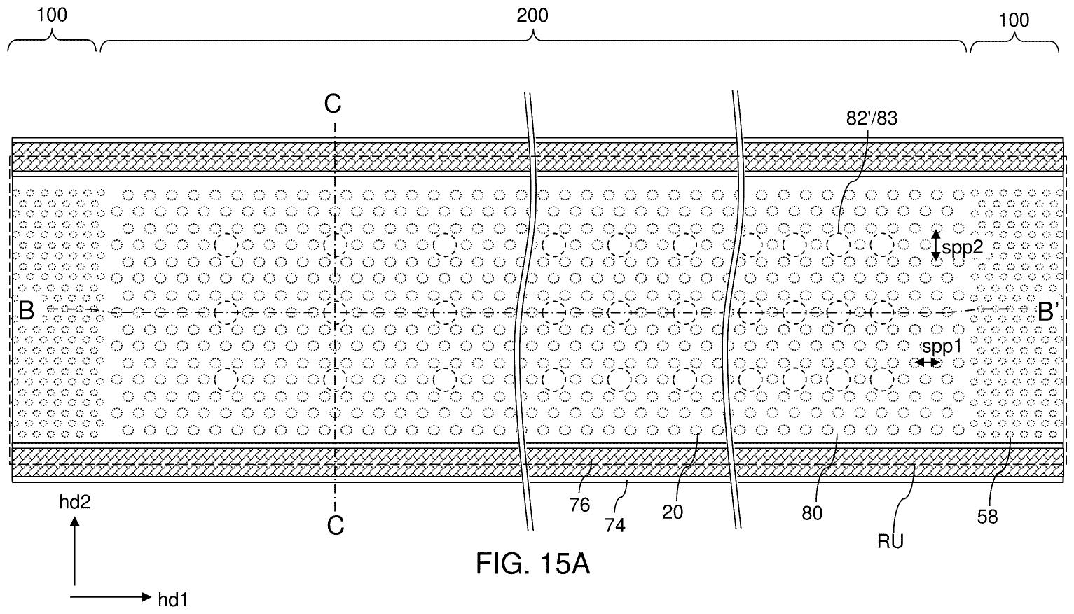

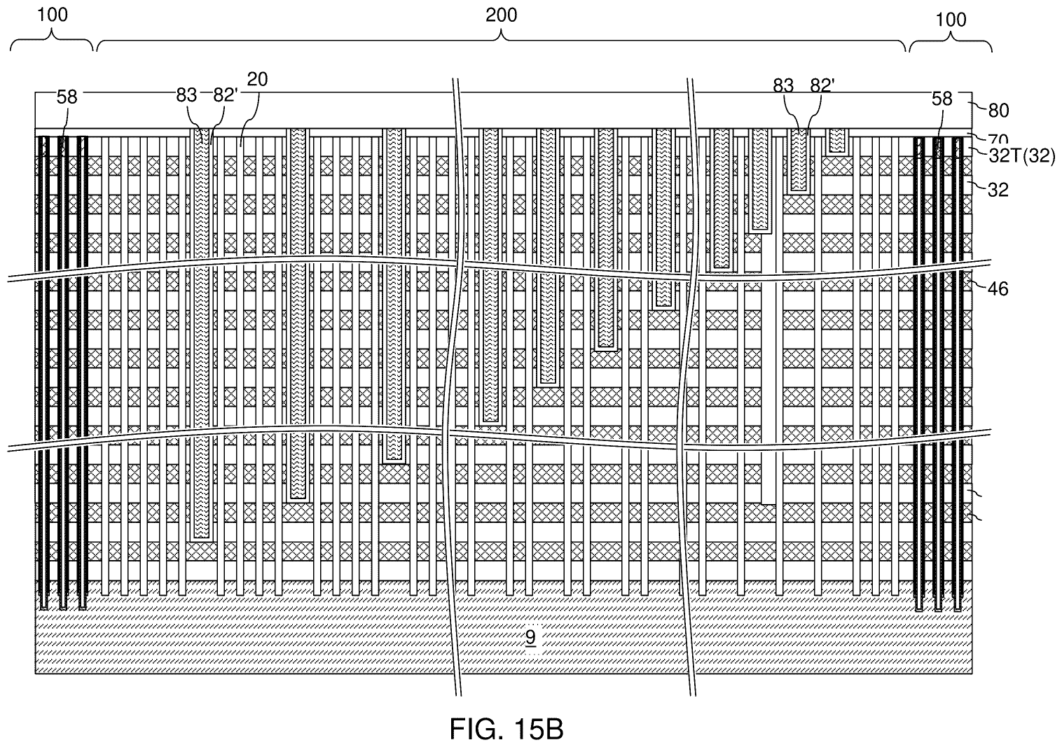

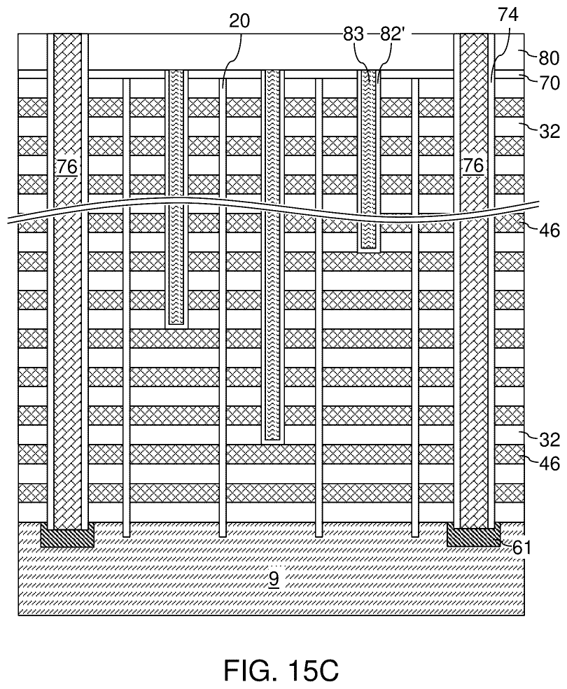

Referring to FIGS. 15A-15C, an insulating material layer can be formed in the lateral isolation trenches 79 and over the contact-level dielectric layer 80 by a conformal deposition process. An optional anisotropic etch can be performed to remove horizontal portions of the insulating material layer from above the contact-level dielectric layer 80 and at the bottom of each lateral isolation trench 79. Each remaining portion of the insulating material layer constitutes an insulating spacer 74. A lateral isolation cavity can be present within a volume surrounded by each insulating spacer 74. A top surface of the semiconductor material layer 9 can be physically exposed at the bottom of each lateral isolation trench 79.

An optional conductive trench fill structure 76 can be formed within each lateral isolation cavity. The conductive trench fill structures 76 can be formed by depositing at least one conductive material in the backside cavities. For example, the at least one conductive material can include a conductive liner and a conductive fill material portion. The conductive liner can include a conductive metallic liner such as TiN, TaN, WN, TiC, TaC, WC, an alloy thereof, or a stack thereof. The thickness of the conductive liner can be in a range from 3 nm to 30 nm, although lesser and greater thicknesses can also be employed. The conductive fill material portion can include a metal or a metallic alloy. For example, the conductive fill material portion can include W, Cu, Al, Co, Ru, Ni, an alloy thereof, or a stack thereof. Excess portions of the at least one conductive material can be removed from above the horizontal plane including the top surface of the contact-level dielectric layer 80 by a planarization process. The planarization process may comprise a recess etch process and/or a chemical mechanical polishing process. Each remaining portion of the at least one conductive material constitutes a conductive trench fill structure 76. A pair of lateral isolation trench fill structures (74, 76) can laterally contact each alternating stack (32, 46) of insulating layers 32 and electrically conductive layers 46. The pair of lateral isolation trench fill structures (74, 76) can be laterally spaced apart from each other by the alternating stack (32, 46). Each of pair of lateral isolation trench fill structures (74, 76) comprises a respective insulating sidewall that laterally extends along the first horizontal direction hd1 and contacting a respective set of sidewalls of the alternating stack (32, 46).

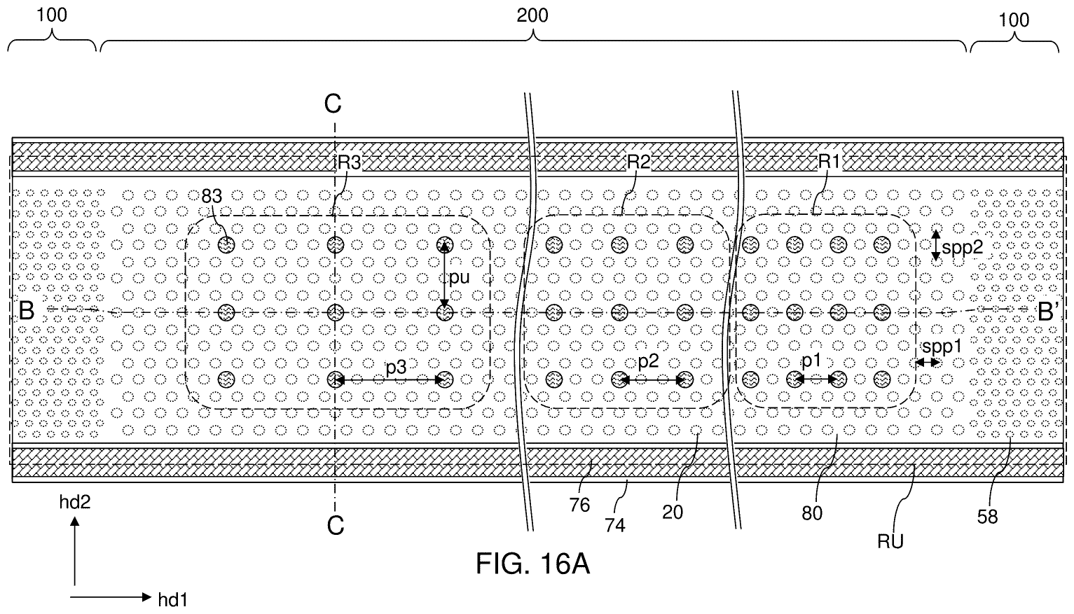

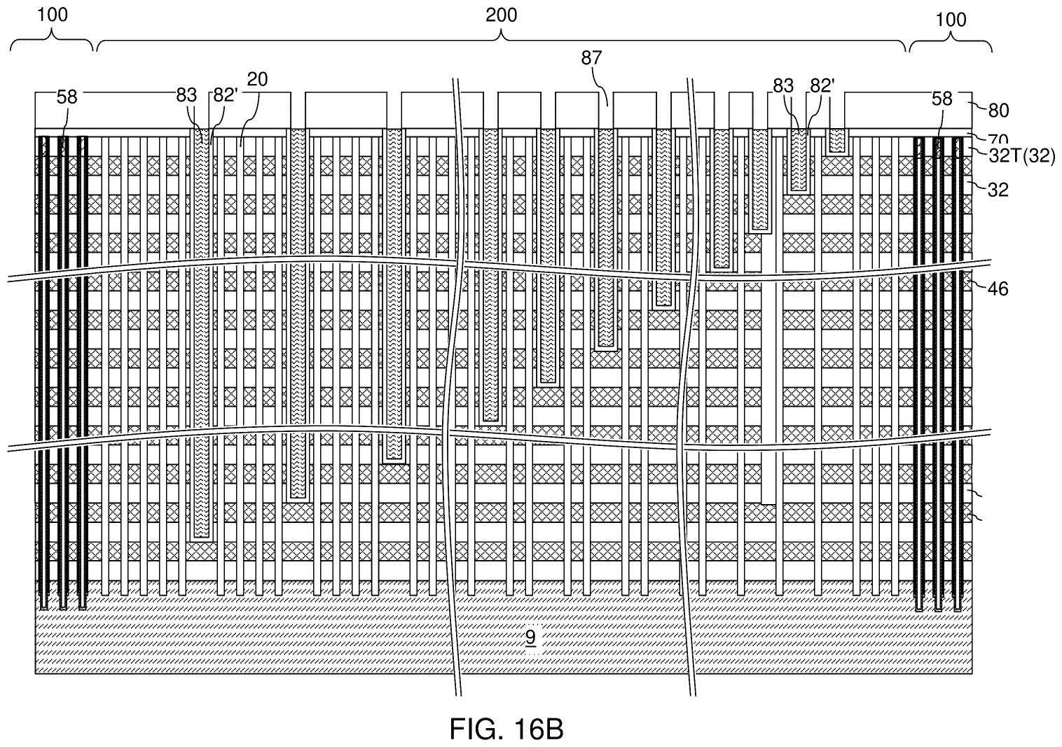

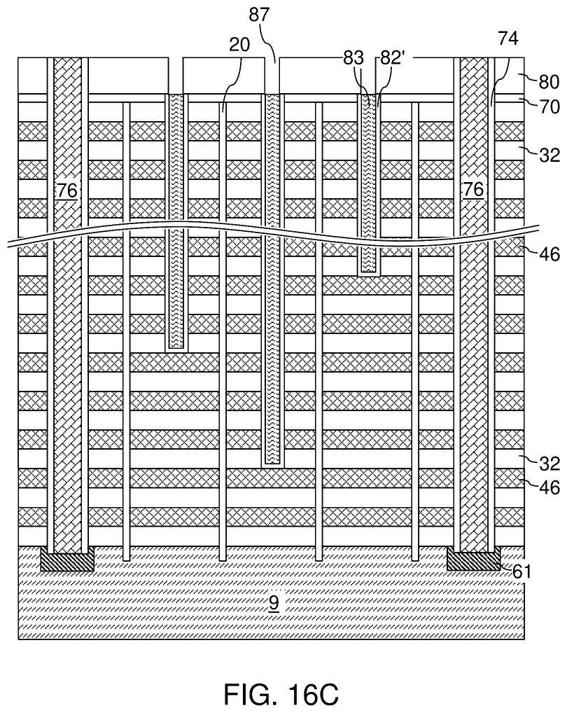

Referring to FIGS. 16A-16C, a photoresist layer (not shown) can be applied over the contact-level dielectric layer 80, and can be lithographically patterned to form openings within the areas of the sacrificial via opening fill structures 83 in a plan view. An anisotropic etch process can be performed to transfer the pattern of the openings in the photoresist layer through the contact-level dielectric layer 80. Connection via openings 87 can be formed through the contact-level dielectric layer 80. A top surface of a sacrificial via opening fill structure 83 can be physically exposed underneath each connection via opening 87. Additional openings can also be formed over the drain regions 63 of the memory opening fill structures 58. The photoresist layer can be subsequently removed, for example, by ashing.

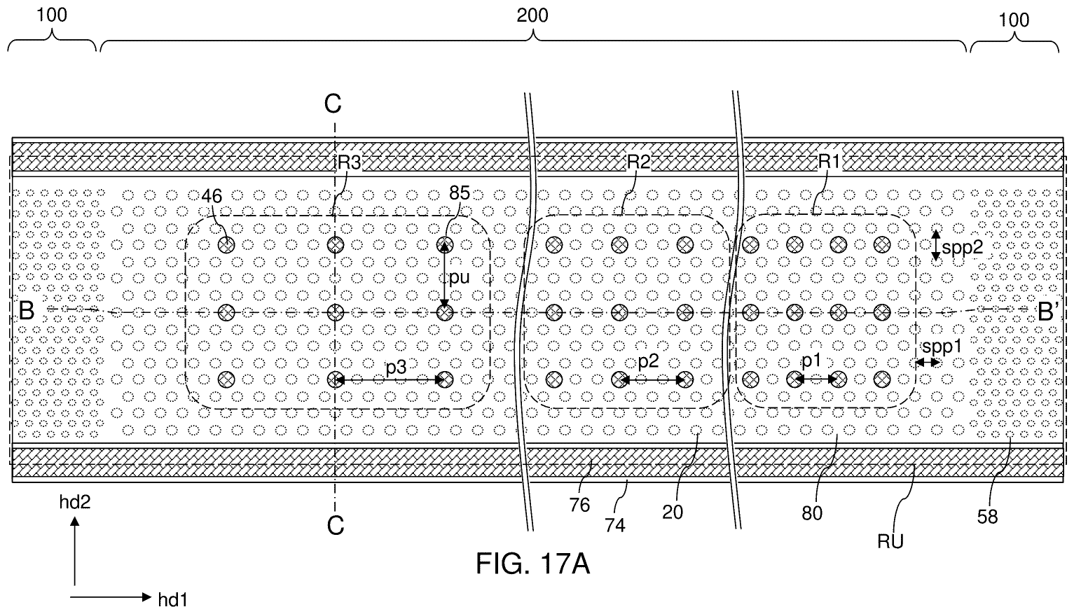

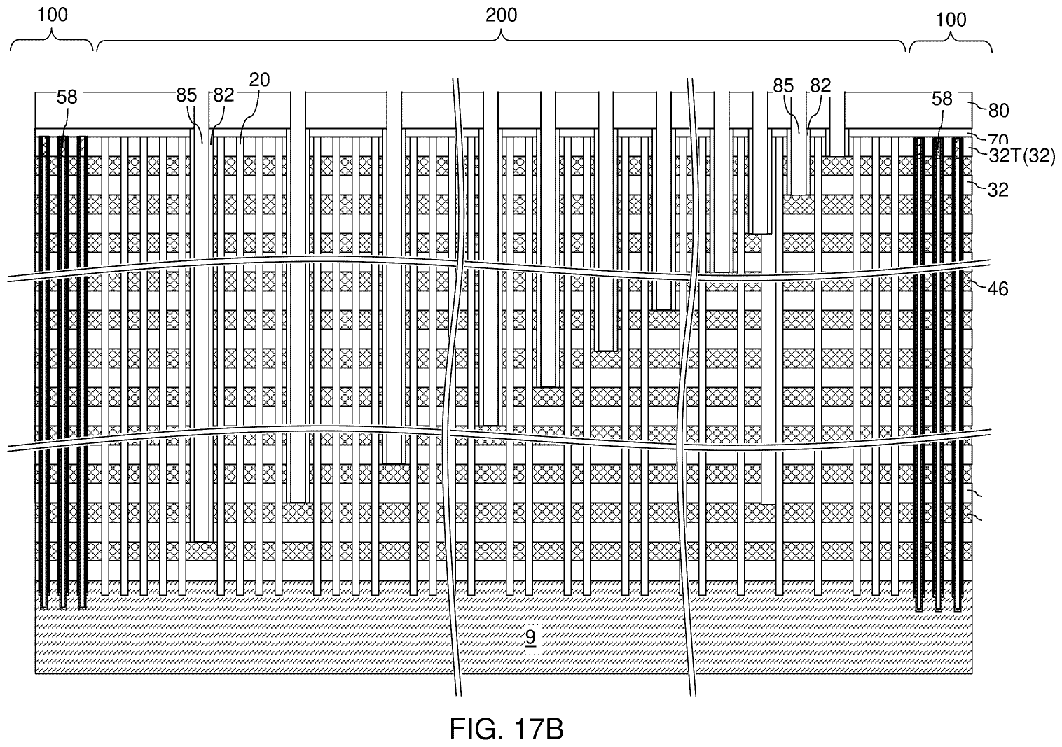

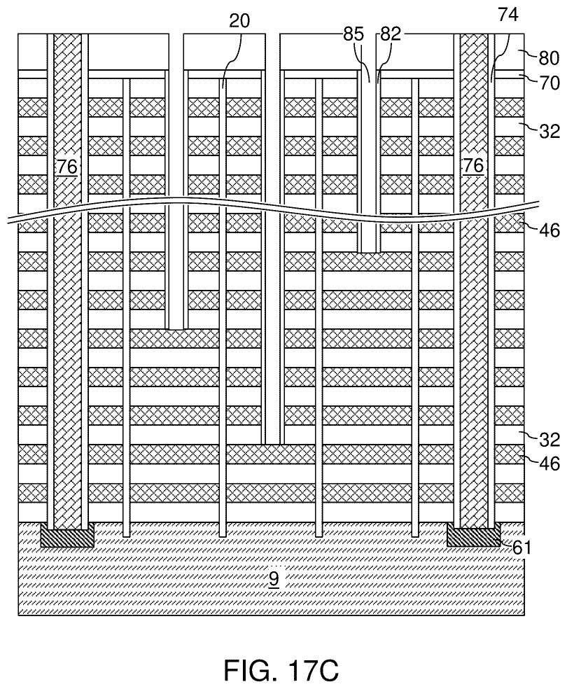

Referring to FIGS. 17A-17C, a selective removal process can be performed to remove the sacrificial via opening fill structures 83 selective to the materials of the insulating spacers 82′ and the contact-level dielectric layer 80. In one embodiment, the selective removal process may comprise a selective etch process or an ashing process. For example, if the sacrificial via opening fill structures 83 comprise a semiconductor material, a wet etch process that etches the semiconductor material selective to the dielectric materials of the insulating spacers 82′ and the contact-level dielectric layer 80 can be performed to remove the sacrificial via opening fill structures 83. Alternatively, if the sacrificial via opening fill structures 83 comprise a carbon-based material, an ashing process may be performed to remove the sacrificial via opening fill structures 83. Subsequently, an anisotropic etch process can be performed to remove bottom portions of the insulating spacers 82′.

The remaining portion of each insulating spacer 82′ has a tubular configuration, and is herein referred to as a tubular insulating spacer 82. Each volume of a void that is laterally surrounded by an insulating spacer 82′ constitutes a via cavity, which is herein referred to as a contact via opening 85. A top surface segment of an electrically conductive layer 46 can be physically exposed underneath each contact via opening 85.

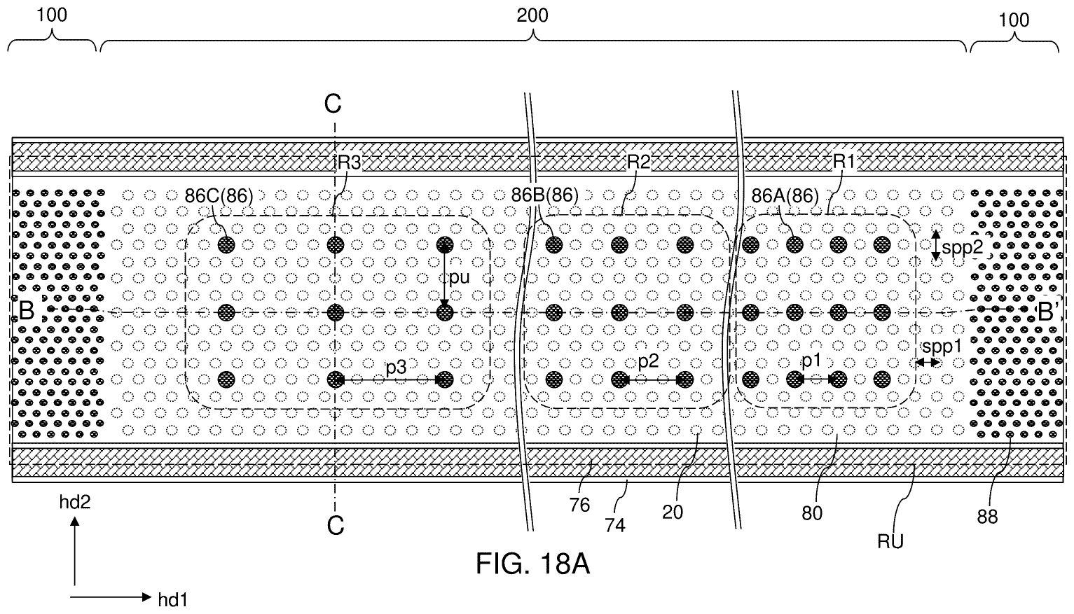

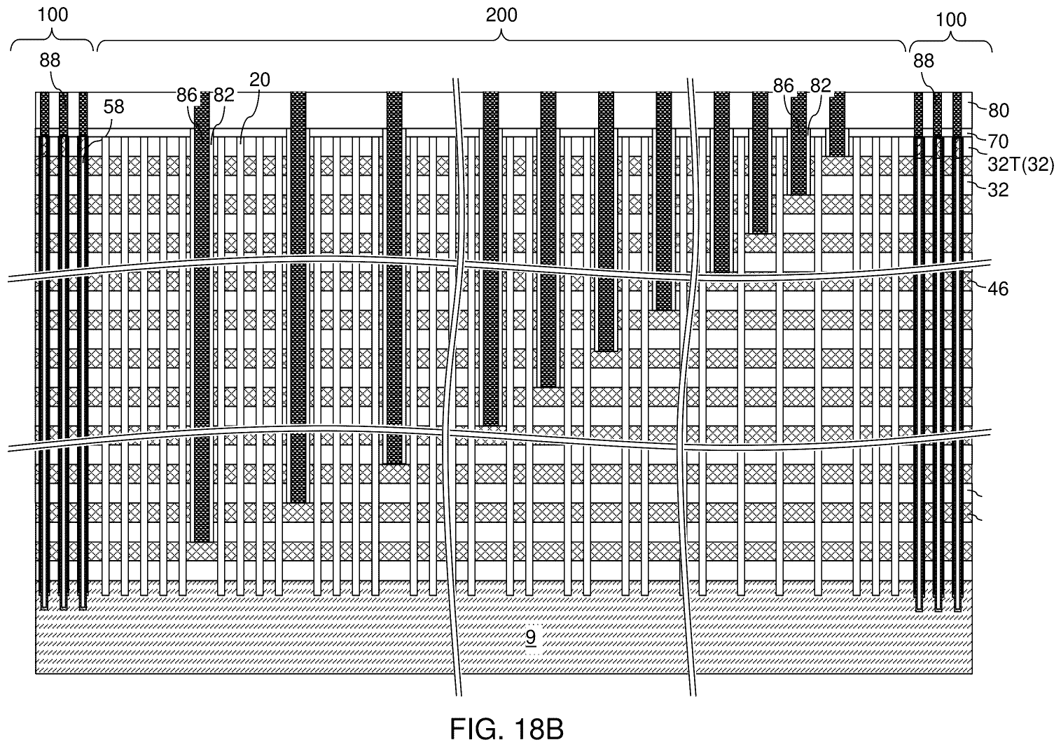

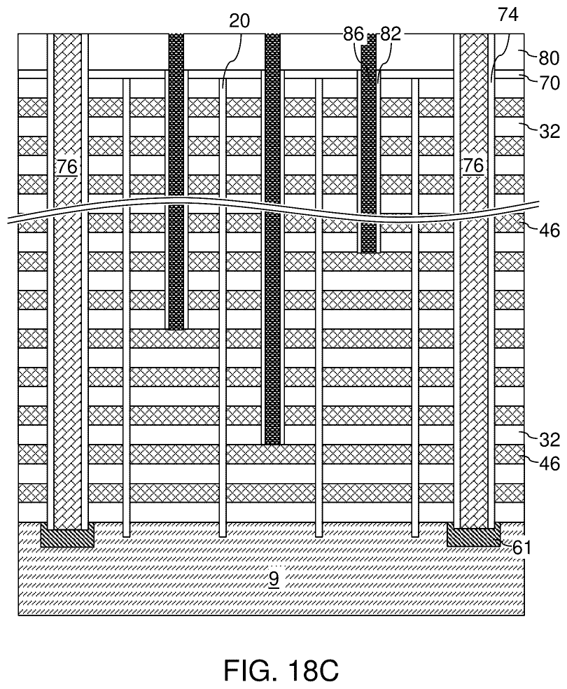

Referring to FIGS. 18A-18C, at least one conductive material can be deposited in the contact via openings 85 and into openings that overly the drain regions 63. The at least one conductive material may comprise a combination of a metallic barrier material (such as TiN, TaN, WN, MON, etc.) and a metallic fill material (such as W, Cu, Mo, Ru, etc.). Excess portions of the at least one conductive material may be removed from above the horizontal plane including the top surface of the contact-level dielectric layer 80. Each contact via opening 85 can be filled with a remaining portion of the at least one conductive material, which constitutes a layer contact via structure 86. The layer contact via structures 86 comprise first layer contact via structures 86A that are formed in the first region R1, second layer contact via structures 86B that are formed in the second region R2, and third layer contact via structures 86C that are formed in the third region R3. Drain contact via structures 88 are formed in contact with the drain regions 63. Subsequently, bit lines (not shown) are formed in electrical contact with the drain contact via structures 88.

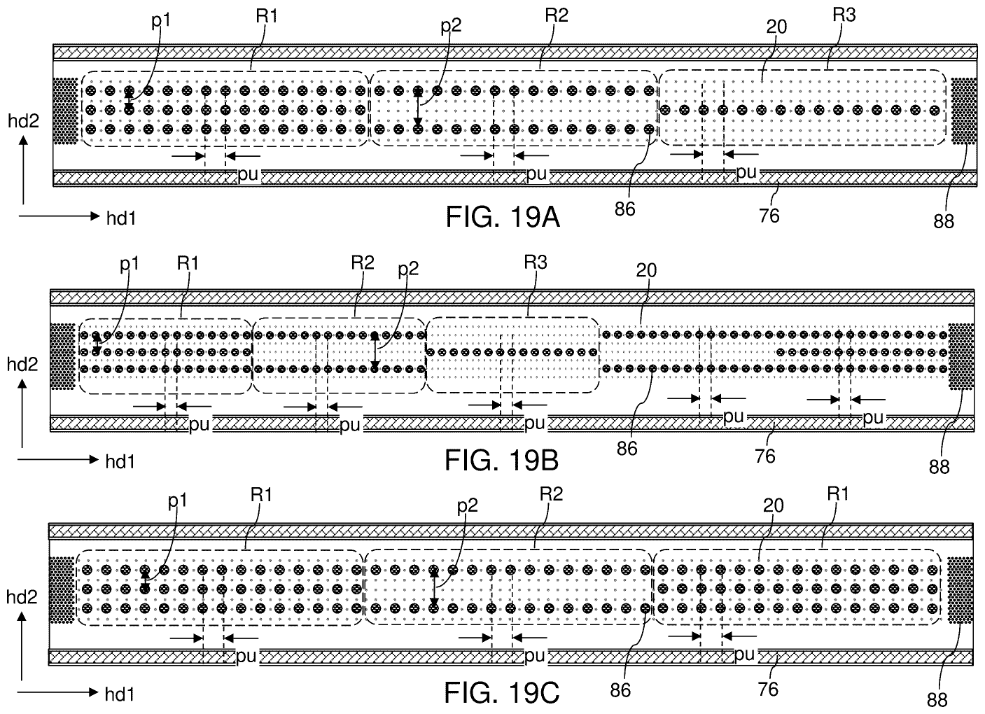

FIGS. 19A-19C are top-down views of alternative configuration of the first exemplary structure after the processing steps of FIGS. 18A-18C according to the alternative embodiment of the present disclosure. The alternative configurations of the first exemplary structure can be derived from the first exemplary structure illustrated in FIGS. 18A-18C by employing the configurations described with reference to FIGS. 10A-10C in lieu of the configuration illustrated in FIGS. 18A-18C.

Referring collectively to FIGS. 18A-18C and 19A-19C, each of the layer contact via structures 86 is formed on a respective one of the electrically conductive layers 46 and vertically extends through a respective subset of layers within the alternating stack (32, 46) that overlies the respective one of the electrically conductive layers 46. In one embodiment, the three-dimensional memory device comprises: an alternating stack (32, 46) of insulating layers 32 and electrically conductive layers 46; memory openings 49 vertically extending through the alternating stack (32, 46); memory opening fill structures 58 located in the memory openings 49, wherein each of the memory opening fill structures 58 comprises a respective vertical stack of memory elements (e.g., portions of the memory film 50) and a vertical semiconductor channel 60; and an array of layer contact via structures 86. Each of the layer contact via structures 86 contacts a respective one of the electrically conductive layers 46 and vertically extends through a respective subset of layers within the alternating stack (32, 46) that overlies the respective one of the electrically conductive layers 46. A shallower first subset 86A of the layer contact via structures 86 has a higher density per unit area than a deeper second subset 86B of the layer contact via structures 86.

In one embodiment, the three-dimensional memory device contains a first region R1 including a first two-dimensional array of the first subset 86A of the layer contact via structures 86 that has a first average height and a first periodic pitch p1 along a first horizontal periodicity direction, and also contains a second region R2 including a second two-dimensional array of the second subset 86B of the layer contact via structures 86 having a second average height and a second periodic pitch p2 along the first horizontal periodicity direction. The three-dimensional memory device may also comprise a third region R3 including a third two-dimensional array of a third subset 86C of the layer contact via structures 86 having a third average height and a third periodic pitch p3 along the first horizontal periodicity direction. The second average height is greater than the first average height. The third average height is greater than the second average height. In one embodiment, the maximum height of the first subset 86A of the layer contact via structures 86 is less than the minimum height of the second subset 86B of the layer contact via structures 86. In one embodiment, the maximum height of the second subset 86B of the layer contact via structures 86 is less than the minimum height of the third subset 86C of the layer contact via structures 86. In one embodiment, the second periodic pitch p2 is greater than the first periodic pitch p1. In one embodiment, the third periodic pitch p3 is greater than the second periodic pitch p2.

In one embodiment, a ratio of the second average height to the first average height is in a range from 1.5 to 3; and a ratio of the second periodic pitch p2 to the first periodic pitch p1 is in a range from 1.2 to 2. In one embodiment, a ratio of the third average height to the second average height is in a range from 1.5 to 3; and a ratio of the third periodic pitch p3 to the second periodic pitch p2 is in a range from 1.2 to 2.

In one embodiment, the three-dimensional memory device comprises a pair of lateral isolation trench fill structures (74, 76) laterally extending along a first horizontal direction hd1, laterally spaced apart from each other along a second horizontal direction hd2 that is perpendicular to the first horizontal direction hd1, and comprising a respective insulating sidewall that laterally extends along the first horizontal direction hd1 and contacting a respective set of sidewalls of the alternating stack (32, 46), wherein one of the first horizontal direction hd1 and the second horizontal direction hd2 is the first horizontal periodicity direction. In one embodiment of FIGS. 18A-18C, the first horizontal periodicity direction is the first horizontal direction hd1. In another embodiment of FIGS. 19A-19C, the first horizontal periodicity direction is the second horizontal direction hd2.

In one embodiment, the first two-dimensional array comprises a first two-dimensional periodic array having a uniform pitch pu along a second horizontal periodicity direction that is different from the first horizontal periodicity direction; and the second two-dimensional array comprises a second two-dimensional periodic array having the uniform pitch pu along the second horizontal periodicity direction. In one embodiment, the three-dimensional memory device comprises a quasi-periodic two-dimensional array of support pillar structures 20 vertically extending through the alternating stack (32, 46). The support pillar structures 20 in the quasi-periodic two-dimensional array are located at a primary subset of lattice sites of a first periodic two-dimensional array having a first support-pillar periodicity spp1 along a first horizontal direction hd1 and having a second support-pillar periodicity spp2 along a second horizontal direction hd2 in a plan view; and the layer contact via structures 86 are located at a complementary subset of the vacancy lattice sites of the first periodic two-dimensional array.

In one embodiment, the second region R2 is laterally spaced from the first region R1 along the first horizontal direction hd1. In one embodiment, the first horizontal direction hd1 is parallel to the first horizontal periodicity direction; and the second horizontal direction hd2 is perpendicular to the first horizontal periodicity direction. In one embodiment, the first periodic pitch p1 is a first integer multiple of the first support-pillar periodicity spp1; and the second periodic pitch p2 is a second integer multiple of the first support-pillar periodicity spp1. In one embodiment, the first periodic pitch p1 is a first integer multiple of the second support-pillar periodicity spp2; and the second periodic pitch p2 is a second integer multiple of the second support-pillar periodicity spp2 different from the first integer multiple.

In one embodiment, the first subset of the layer contact via structures 86 is located at lattice sites of a first subset of the complementary subset in the first region R1; and the second subset of the layer contact via structures 86 is located at lattice sites of a second subset of the complementary subset in the second region R2. In one embodiment, the first subset of the complementary subset has a uniform pitch pu along a second horizontal periodicity direction that is different from the first horizontal periodicity direction; and the second subset of the complementary subset has the uniform pitch pu along the second horizontal periodicity direction. In one embodiment, each of the layer contact via structures 86 is laterally surrounded by a respective tubular insulating spacer 82 that vertically extends between the respective one of the electrically conductive layers 46 to a horizontal plane located at or above a topmost surface of the alternating stack (32, 46).

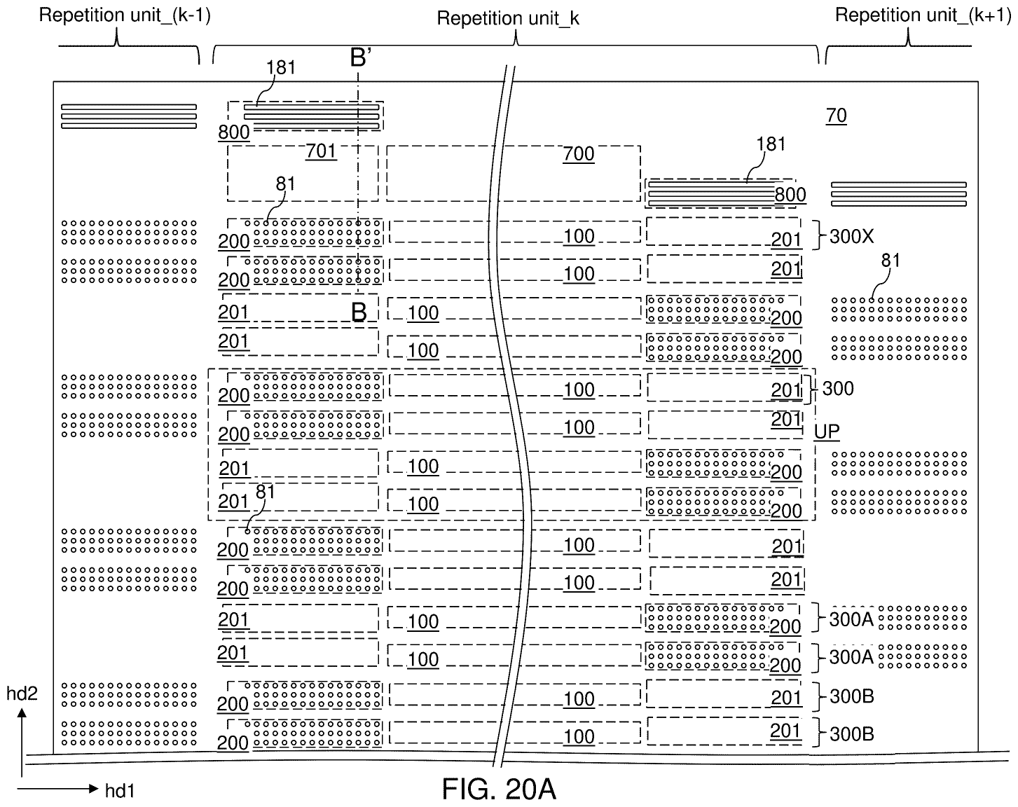

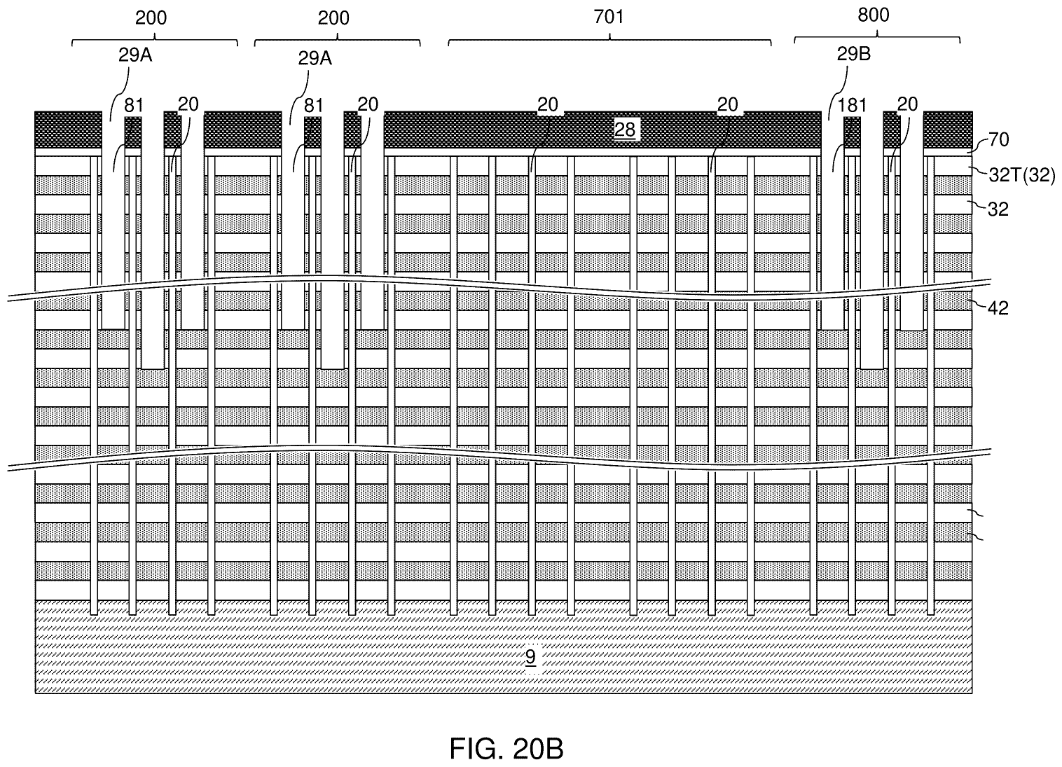

Referring to FIGS. 20A and 20B, a second exemplary structure according to a second embodiment of the present disclosure can be derived from the first exemplary structure illustrated in FIGS. 7A and 7B by modifying the layout of the first exemplary structure and by forming dummy cavities 181 in addition to the contact via openings 81. Generally, a vertically alternating sequence (32, 42) of continuous insulating layers 32 and continuous spacer material layers 42 can be formed over a substrate. Memory openings 49 can be formed through the vertically alternating sequence (32, 42), and memory opening fill structures 58 can be formed in the memory openings 49. Each of the memory opening fill structures 58 comprises a respective vertical stack of memory elements (e.g., portions of the memory film 50) and a vertical semiconductor channel 60. A patterned hardmask layer 28 can be formed over the vertically alternating sequence (32, 42) and the memory opening fill structures 58. In one embodiment, the patterned hardmask layer 28 comprises arrays of first-type openings in a center region of the vertically alternating sequence (32, 42) and arrays of second-type openings in a peripheral region of the vertically alternating sequence (32, 42).

According to an aspect of the present disclosure, each contact region 200 can be aligned to a respective set of at least one memory array region 100 along a first horizontal direction (e.g., word line direction hd1) to form a memory block 300 including at least one memory array region 100 and a contact region 200. Blocks 300 of at least one memory array region 100 and a contact region 200 can be arranged along a second horizontal direction (e.g., bit line direction) hd2 that is perpendicular to the first horizontal direction hd1. Each block of at least one memory array region 100 and a contact region 200 can have a limited lateral extent along the second horizontal direction hd2 which is less than the pitch of lateral isolation trenches 79 (described above and to be subsequently formed) along the second horizontal direction hd2.

The blocks 300 of at least one memory array region 100 and a contact region 200 can comprise first blocks 300A of at least one memory array region 100 and a contact region 200, and second blocks 300B of at least one memory array region 100 and a contact region 200. Contact regions 200 within the first blocks 300A can be aligned among one another along the first horizontal direction hd1, and contact regions 200 within the second blocks 300B can be aligned among one another along the first horizontal direction hd1 with a lateral offset relative to the contact regions 200 within the first blocks 300A. In one embodiment, lateral extents of the contact regions 200 along the first horizontal direction hd1 in the first blocks 300A may not have an overlap with lateral extents of the contact regions 200 along the first horizontal direction hd1 in the second blocks 300B. In one embodiment, a unit pattern UP including a sequence of at least one first block 300A (e.g., two blocks 300A) and at least one second block 300B (e.g., two blocks 300B) may be repeated along the second horizontal direction hd2.

Further, a dummy memory array region 700 may be formed at a periphery of an outermost block 300 (e.g., a block 300X located at the edge of a memory plane or of a memory die) of at least one memory array region 100 and a contact region 200. The dummy memory array region 700 may comprise an array of dummy memory opening fill structures 58 arranged the same as in a memory array region 100. However, the dummy memory opening fill structures 58 in the dummy memory array region 700 may be dummy structures that are not electrically connected to any bit line, and thus, are electrically floating and inactive. The dummy memory array region 700 may be laterally offset from the outermost block 300X of the at least one memory array region 100 and the contact region 200 along the second horizontal direction hd2. According to an aspect of the present disclosure, dummy structure regions 800 can be formed on an outer side of the combination of the dummy memory array region 700, the memory array regions 100, and the contact regions 200, adjacent to an edge of a memory plane or of a memory die).

Generally, the pattern of the contact regions 200 and the memory array regions 100 can be replicated along the first horizontal direction hd1 such that multiple repetition units are arranged along the first horizontal direction hd1. The multiple repetition units may be sequentially numbered along the first horizontal direction hd1 with positive integers beginning with 1 and incrementing by 1 along the first horizontal direction hd1. In some embodiments, the pattern of the even-numbered repetition units may be a mirror image pattern of the odd-numbered repetition units. The illustrated portion of the second exemplary structure includes the k-th repetition unit (i.e., repetition unit_k), and a portion of the (k−1)-th repetition unit and a portion of the (k+1)-th repetition unit. The memory array regions 100 in each repetition unit can be arranged along the second horizontal direction hd2 to form a row of memory array regions 100, and a dummy memory array region 700 can be located at the outermost end of the row of memory array regions 100.

Each memory array region 100 can be adjoined to a respective contact region 200 at one end, and can be adjoined to a respective first dummy contact region 201 at a second end. One of the respective contact regions 200 and one of the respective first dummy contact regions 201 can be laterally offset from the memory array region 100 along the first horizontal direction hd1, and another one of the respective contact regions 200 and another one of the respective first dummy contact regions 201 can be laterally offset from the memory array region 100 along the opposite direction of the first horizontal direction hd1. The first dummy contact regions 201 are regions in which contact via cavities are not formed to avoid photoresist thinning. The first dummy contact regions 201 lower the overall pattern density of contact via cavities to be subsequently formed.

A second dummy contact region 701 may be formed between each dummy structure region 800 and an outermost contact region 200 that is most proximal to the dummy structure region 800. The second dummy contact region 701 can be employed to provide a consistent pattern repetition for the outermost contact region 200 and adjacent memory array regions 100. The second dummy contact region 701 is a region in which contact via cavities are not formed.

The patterned hardmask layer 28 comprises first-type openings 29A and second-type openings 29B. The first-type openings 29A are formed in the contact regions 200, which are provided in the center region of the vertically alternating sequence (32, 42). The second-type openings 29B are formed within the dummy structure regions 800, which are provided in a peripheral region of the vertically alternating sequence (32, 42). In one embodiment, the first-type openings 29A in the contact region 200 may have horizontal cross-sectional shapes of circles or ovals. In one embodiment, the second-type openings 29B in the dummy structure regions 800 may have horizontal cross-sectional shapes of elongated rectangles or rounded elongated rectangles (i.e., slits or slit shaped trenches). The first dummy contact regions 201 and the second dummy contact regions 701 may be free of any openings in the patterned hardmask layer 28.

In one embodiment, each region including the first-type openings 29A in the patterned hardmask layer 28 in the contact regions 200 has a first areal density of the first-type openings 81 in a plan view. In an illustrative example, the first areal density may be in a range from 0.05 to 0.4, although lesser and greater first areal densities may also be employed. As used herein, an “areal density” refers to the ratio of the total area of elements to the total area of a region containing the area of the elements. In one embodiment, each region including the second-type openings 29B in the patterned hardmask layer 28 in the dummy structure region 800 has a second areal density of the second-type openings in the plan view. In one embodiment, the second areal density may be in a range from 0.15 to 0.8, such as from 0.25 to 0.50, although lesser and greater second areal densities may also be employed. In one embodiment, the second areal density may be in a range from 110% to 2,000% of the first areal density.

In one embodiment, each of the first-type openings 29A in the patterned hardmask layer 28 in the contact regions 200 has a first horizontal cross-sectional area. In one embodiment, each of the second-type openings 29B in the patterned hardmask layer 28 has a second horizontal cross-sectional area in a range from 200% to 10,000%, such as 300% to 1,000%, of the first-type openings.

After formation of the patterned hardmask layer 28, arrays of contact via openings 81 can be formed underneath the first-type openings 29A in the patterned hardmask layer 28 by vertically recessing first portions of the vertically alternating sequence (32, 42) that underlie the first-type openings. Further, arrays of dummy cavities 181 can be formed underneath the second-type openings 29B in the patterned hardmask layer 28 by vertically recessing second portions of the vertically alternating sequence (32, 42) that underlie the second-type openings.

In one embodiment, the arrays of contact via openings 81 and the array of dummy cavities 181 are formed by sequentially performing multiple iterations of a selective via extension process. Each iteration of the selective via extension process comprises a respective photoresist masking step in which a respective photoresist material layer covers a respective first subset of the first-type openings 29A while not covering a respective second subset of the first-type openings 29A and not covering a respective subset of the second-type openings 29B, and further comprises a respective anisotropic etch step that vertically extends a respective subset of the contact via openings that underlies the respective second subset of the first-type openings 29A and a respective subset of the dummy cavities 181 that underlies the respective subset of the second-type openings 29B. The second exemplary structure illustrated in FIGS. 20A and 20B can be provided by performing a first subset of the iterations of the selective via extension process. In an illustrative example, the sequence of processing steps described with reference to FIGS. 8B-8F can be performed during the iterations of the selective via extension process.

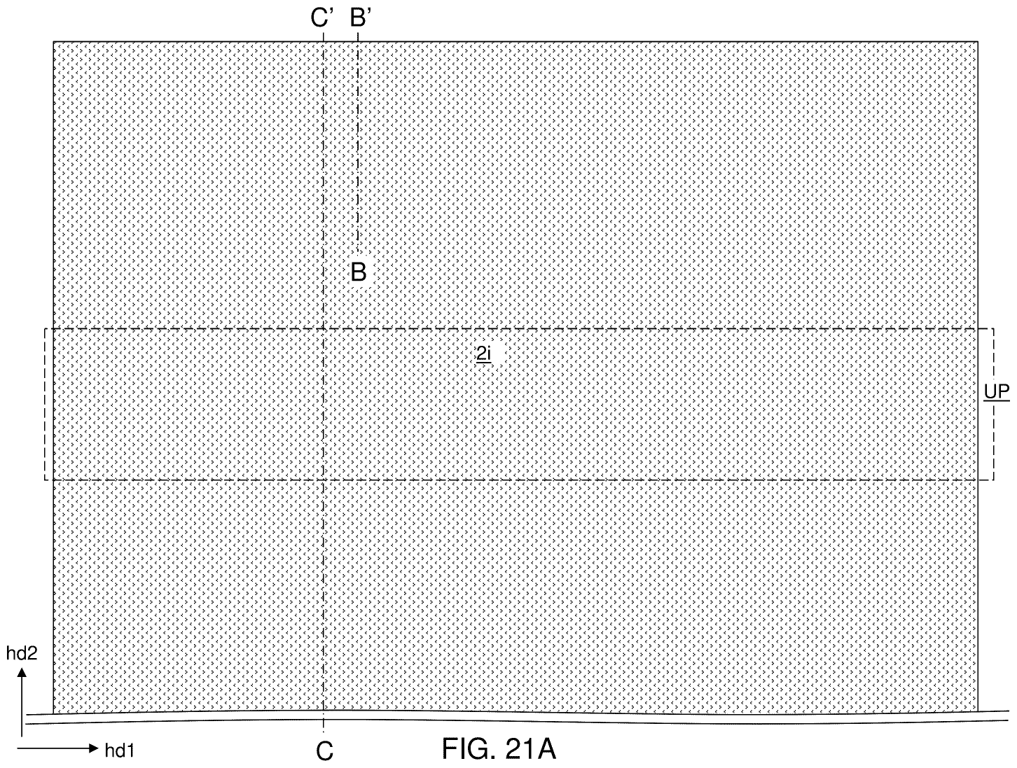

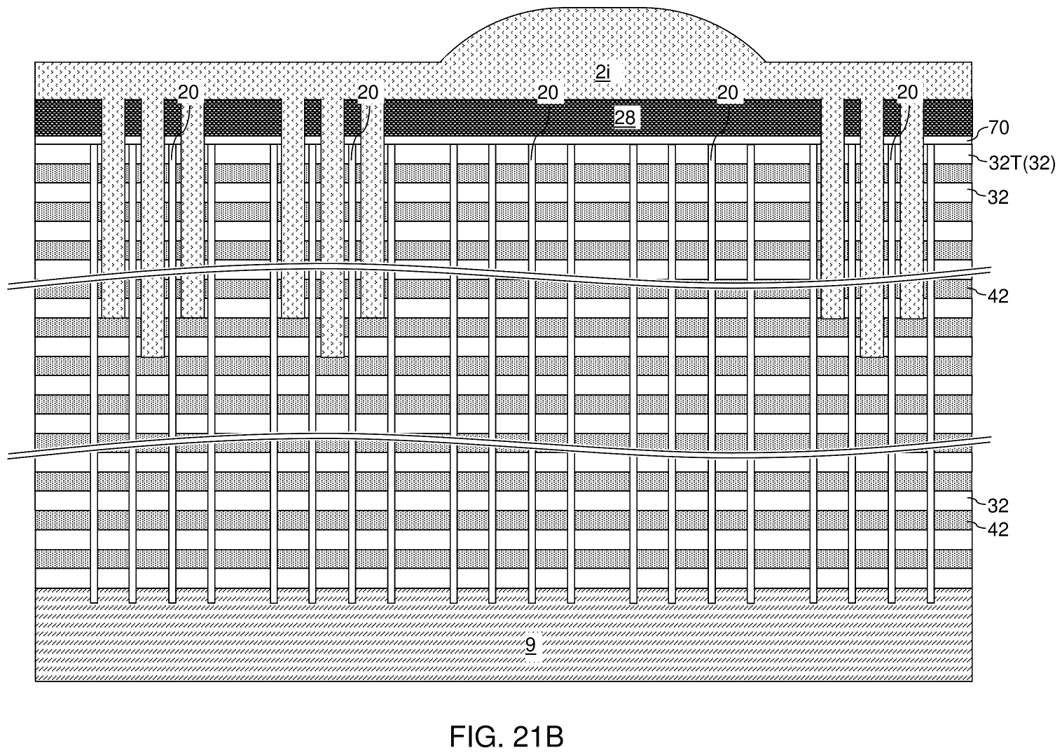

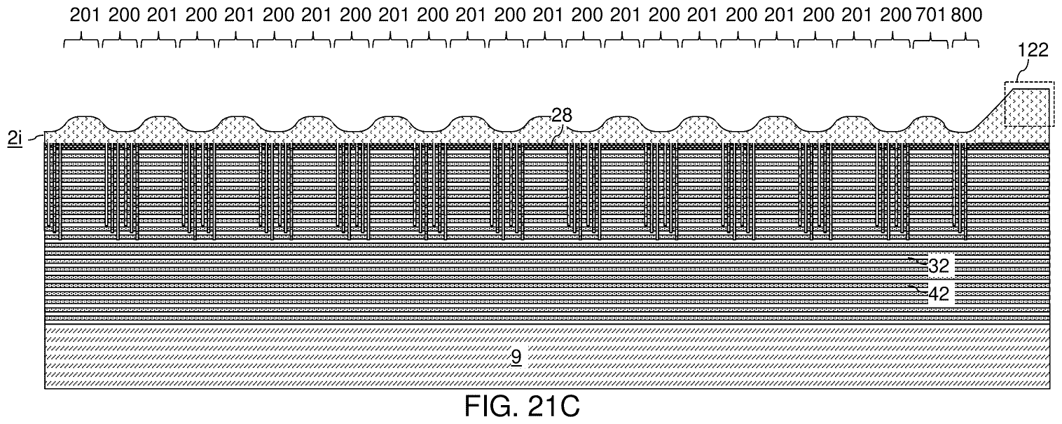

Referring to FIGS. 21A-21C, the second exemplary structure is illustrated during an i-th iteration of the selective via extension process after the i-th photoresist masking step in which an i-th photoresist material layer 2i covers a respective first subset of the first-type openings 29A in the patterned hardmask layer 28 while not covering a respective second subset of the first-type openings 29A in the patterned hardmask layer 28 and not covering a respective subset of the second-type openings 29B in the patterned hardmask layer 28. The total number N of iterations of the selective via extension process may be in a range from 3 to 12, such as from 4to 8, although lesser and greater numbers may also be employed. The integer i may be any number in the range from 1 to N.

In one embodiment, a fraction of a total number of first-type openings within the respective first subset to a total number of the first-type openings 29A through the patterned hardmask layer 28 is in a range from 0.33 to 0.67 (which is herein referred to as a first fraction); and a fraction of a total number of second-type openings 29B within the respective subset to a total number of the second-type openings through the patterned hardmask layer 28 is in a range from 0.50 to 1.00 (which is herein referred to as a second fraction). The ratio of the second fraction to the first fraction may be in a range from 1.0 to 3.0, such as from 1.25 to 2.0, although lesser and greater ratios may also be employed.

Generally, the voids of the contact via openings 81 and the dummy cavities 181 function as sinks for the i-th photoresist material layer 2i. Further, as the total volume of the contact via openings 81 and the dummy cavities 181 increases during progression of the iterations of the selective via extension process, the total volume of the photoresist material that fills the contact via openings 81 and the dummy cavities 181 increases such that at least 5%, such as at least 10%, of the total volume of the photoresist material is located within the contact via openings 81 and the dummy cavities 181. Thus, during the i-th iteration of the selective via extension process, the i-th photoresist material layer may have a contoured top surface having a surface height undulation. The surface height modulation in the contoured top surface of the i-th photoresist material layer generally increases with the increase in the total volume of the contact via openings 81 and the dummy cavities 181, i.e., with the progression of the iterations of the selective via extension process.

In one embodiment, first surface segments of the contoured top surface of the i-th photoresist material layer are located in first regions in which the first-type openings and the second-type openings are absent, i.e., in regions in which the contact via openings 81 and the dummy cavities 181 do not function as sinks for the photoresist material of the i-th photoresist material layer. Second surface segments of the contoured top surface of the i-th photoresist material layer are located in second regions containing the first-type openings or the second-type openings, i.e., in regions in which the contact via openings 81 and the dummy cavities 181 function as sinks for the photoresist material, and are vertically recessed relative to the first surface segments.

Generally, during one or more iterations of the selective via extension process, an average volume of a respective photoresist material layer filling the array of dummy cavities 181 per unit area is greater than an average volume of the respective photoresist material layer filling the arrays of contact via openings 81 per unit area at least by a factor of 2. In other words, the volume of the dummy cavities 181 per unit area may be greater than the volume of the contact via openings 81 per unit area at least by a factor of 2. Thus, the dummy cavities 181 may function as a more effective sink for the photoresist material than the arrays of contact via openings 81. The more effective sinking of the photoresist material portions into the dummy cavities 181 than the contact via openings 81 has a beneficial effect of providing a more aggressive sinking of the photoresist material at a peripheral region (i.e., in the dummy structure region 800 adjacent to the plane or die edge) than around the blocks 300 of at least one memory array region 100 and a contact region 200, i.e., a device region including functional devices. The peripheral area (e.g., plane or die edge) outside of the memory array regions 100, the contact regions 200, the dummy memory region 700, and the dummy structure region 800 typically does not include many via cavities, and thus, does not function as a sink area for the photoresist material layers. Thus, a peripheral segment 122 of the photoresist material layer 2i located in a peripheral region (e.g., at the plane or die edge) outside the memory array regions 100, the contact regions 200, the dummy memory region 700, and the dummy structure region 800 may have a top surface that protrudes above the top surface of the remaining segments of the photoresist material layer 2i located in the memory array regions 100, the contact regions 200, the dummy memory region 700, and the dummy structure region 800 as illustrated in FIG. 21C. By aggressively sinking the photoresist material into the larger dummy cavities 181 in the dummy structure region 800, the surface height differences of the top surface of the photoresist material layer 2i across the memory array regions 100, the contact regions 200, the dummy memory region 700, and the dummy structure region 800 can be reduced. In other words, by forming larger slit shaped dummy cavities 181 in the dummy structure region 800, the height of the peripheral segment 122 may be reduced. By reducing the height of the peripheral segment 122, the step height between the peripheral segment 122 and the remaining segments of the photoresist material layer 2i is reduced, which reduces potential photolithography errors caused by a step in the top surface (i.e., an uneven top surface) of the photoresist layer 2i.

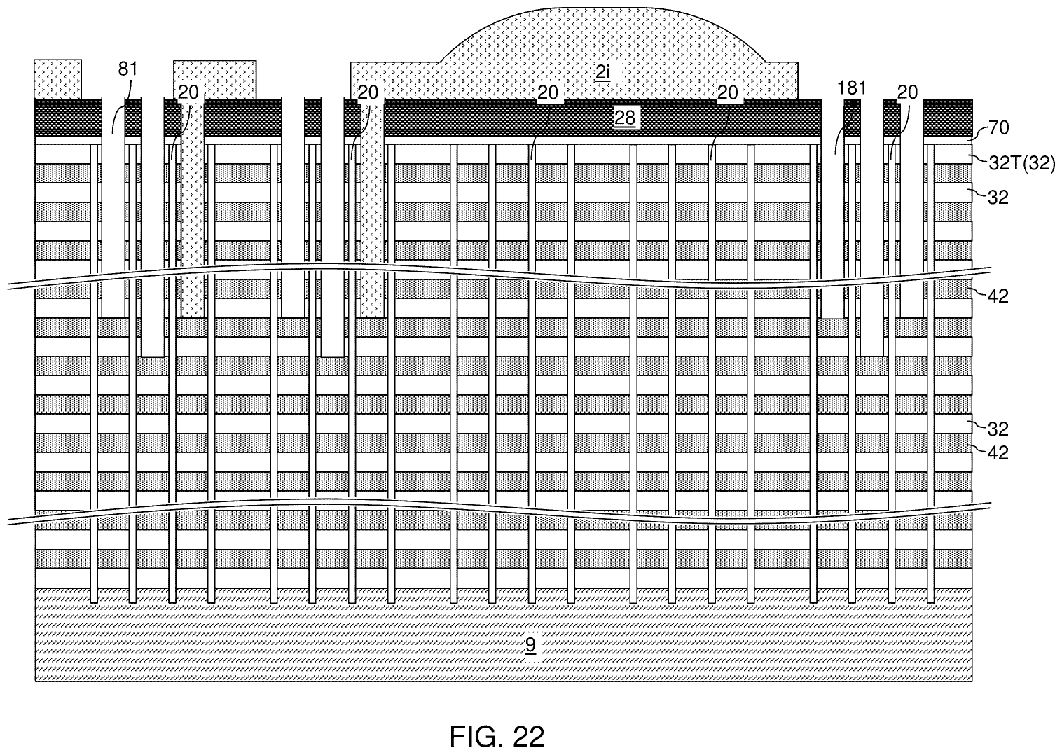

Referring to FIG. 22, the i-th photoresist material layer 2i can be lithographically patterned such that the i-th photoresist material layer is removed a first subset of contact via openings 81 and from above a subset of the dummy cavities 181. The patterned i-th photoresist material layer 2i covers a second subset of the contact via openings 81, which is a complementary set of the first subset of the contact via openings 81. The patterned i-th photoresist material layer 2i may optionally cover another subset of the dummy cavities 181. In other words, all of the dummy cavities 181 may not be covered by the patterned i-th photoresist material layers 2i, or some of the dummy cavities 181 may be covered by the patterned i-th photoresist material layer 2i.

Subsequently, the anisotropic etch step of the i-th iteration of the selective via extension process can be performed to vertically extend the second subset of the contact via openings 81 (which is not covered by the patterned i-th photoresist material layer) and to vertically extend the subset of the dummy cavities 181 (which is not covered by the patterned i-th photoresist material layer). As described with reference to FIGS. 8B-8F, the recess depth of the anisotropic etch step may differ among the various iterations of the selective via extension process.

The processing steps described with reference to FIGS. 21A-21C and 22 can be performed for each integer i from 1 to N with different masking patterns for the patterned photoresist material layer. Generally, the fraction of the dummy cavities 181 that are not masked by a patterned photoresist material layer may be the same as or greater than the fraction of the contact via openings 81 that are not masked by the same patterned photoresist material layer in each iteration of the selective via extension process. Thus, the dummy cavities 181 provide enhanced sinking of the material of the photoresist material per area than the contact via openings 81 as the iterations of the selective via extension process.

In one embodiment, each array among the arrays of contact via openings 81 has a first total cavity volume per unit area, and the array of dummy cavities 181 has a second total cavity volume per unit area which is greater than the first total cavity volume per unit area during at least one of the iterations of the selective via extension process. In one embodiment, the second total cavity volume is in a range from 110% to 2,000% of the first total cavity volume. In one embodiment, each array of the arrays of contact via openings 81 has a first total cavity volume per unit area, and the array of dummy cavities 181 has a second total cavity volume per unit area which is greater than the first total cavity volume per unit area during each iteration of the selective via extension process.

In one embodiment, during at least one iteration of the selective via extension process, the respective photoresist material layer has a contoured top surface having a surface height undulation; first surface segments of the contoured top surface of the respective photoresist material layer are located in first regions in which the first-type openings and the second-type openings are absent; and second surface segments of the contoured top surface of the respective photoresist material layer are located in second regions containing the first-type openings or the second-type openings and are vertically recessed relative to the first surface segments.

In one embodiment, during at least one iteration of the selective via extension process, an average volume of the respective photoresist material layer filling the array of dummy cavities 181 per unit area is greater than an average volume of the respective photoresist material layer filling the arrays of contact via openings 81 per unit area at least by a factor of 2, such as 2 to 20.

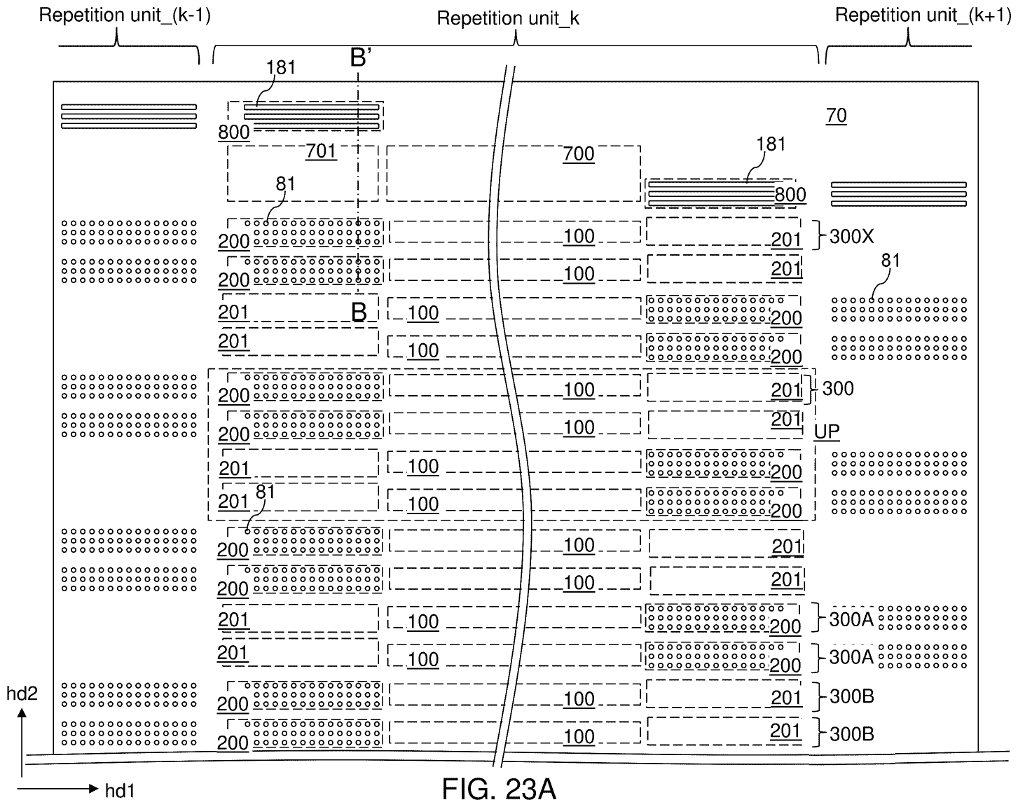

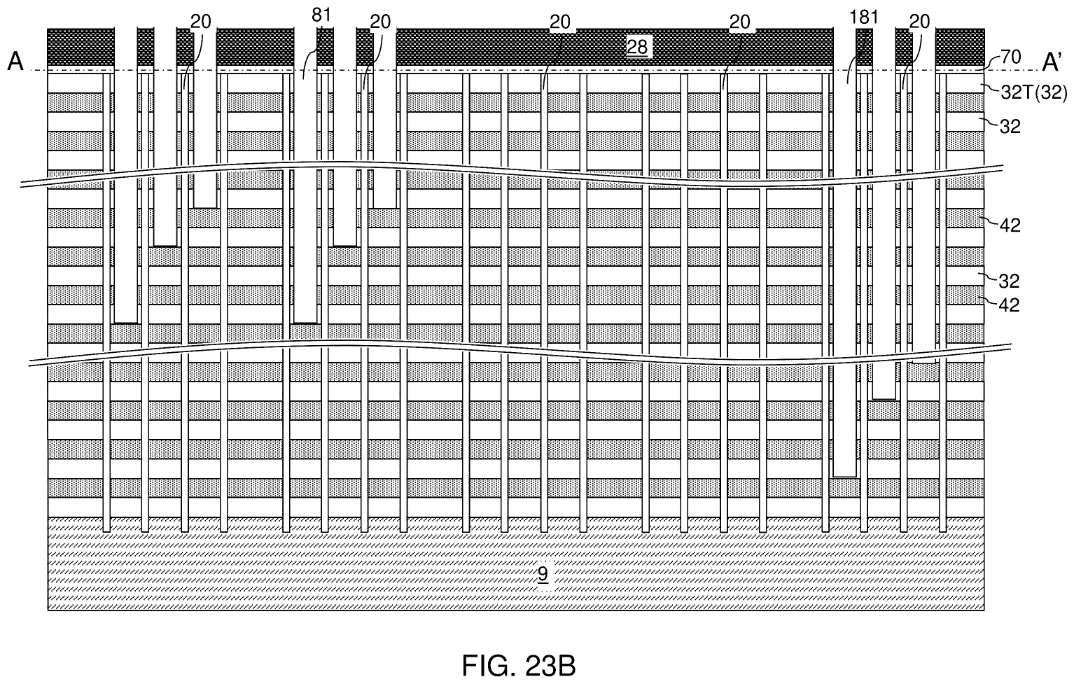

Referring to FIGS. 23A and 23B, the second exemplary structure is illustrated after a last iteration (i.e., the N-th iteration) of the selective via extension process and removal of the last patterned photoresist material layer (i.e., the N-th patterned photoresist material layer).

Generally, during the last iteration of the selective via extension process, an average volume of the photoresist material layer filling the array of dummy cavities 181 per unit area is greater than an average volume of the respective photoresist material layer filling the arrays of contact via openings 81 per unit area at least by a factor of 2. In one embodiment, during the last iteration of the selective via extension process, the respective photoresist material layer has a contoured top surface having a surface height undulation; first surface segments of the contoured top surface of the respective photoresist material layer are located in first regions in which the first-type openings and the second-type openings are absent; and second surface segments of the contoured top surface of the respective photoresist material layer are located in second regions containing the first-type openings or the second-type openings and are vertically recessed relative to the first surface segments.

In one embodiment, each dummy structure region 800 may have the same area as each contact region 200. In one embodiment, each contact region 200 may contain a respective set of contact via openings 81 such that a total volume of the respective set of contact via openings 81 in the respective contact region 200 has a first total volume value. In one embodiment, each dummy structure region 800 may contain dummy cavities 181 such that a total volume of the dummy cavities 181 has a second total volume value that is in a range from 110% to 2,000% of the first total volume value. In one embodiment, the second total volume value may be at least 200% of the first total volume value.

In one embodiment, at least one of the contact via openings 81 may have a first maximum lateral extent (such as a diameter or a major axis of an ellipse) along the first horizontal direction hd1, and at least one of the dummy cavities 181 may have a second maximum lateral extent (such as a lengthwise dimension of a rectangle) along the first horizontal direction hd1 that is in a range from 200% to 10,000% of the first maximum lateral extent. In other words, the contact via openings 81 may have a circular or oval horizontal cross-sectional shape, while the dummy cavities 181 may have an elongated slit (e.g., trench) shape.

In one embodiment, at least one of the contact via openings 81 may have a first lateral dimension ratio which is a ratio of a maximum lateral dimension of a contact via opening 81 along the first horizontal direction hd1 to a maximum lateral dimension of the contact via opening 81 along the second horizontal direction hd2. The first lateral dimension ratio may be in a range from 0.5 to 2, such as from 0.75 to 1.5, for example about 1 (e.g., a circular horizontal cross-sectional shape) although lesser and greater ratios may also be employed. In one embodiment, at least one of the dummy cavities 181 has a second lateral dimension ratio which is a ratio of a maximum lateral dimension of a dummy cavity 181 along the first horizontal direction hd1 to a maximum lateral dimension of the dummy cavity 181 along the second horizontal direction hd2. The second lateral dimension ratio may be in a range from 3 to 100, such as from 5 to 20, although lesser and greater ratios may also be employed. The second lateral dimension ratio is greater than the first lateral dimension ratio.

In one embodiment, an average height of the contact via openings 81 in each contact region 200 may have a first average height value, and an average height of the dummy cavities 181 may have a second average height value that is greater than the first average height value.

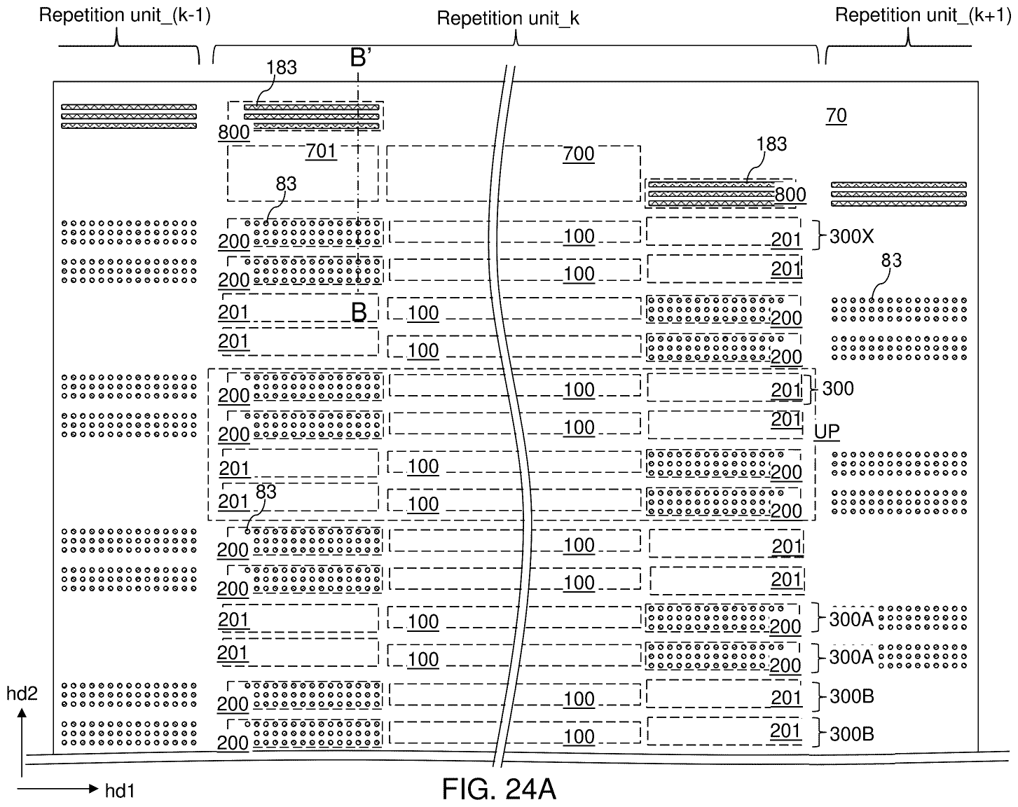

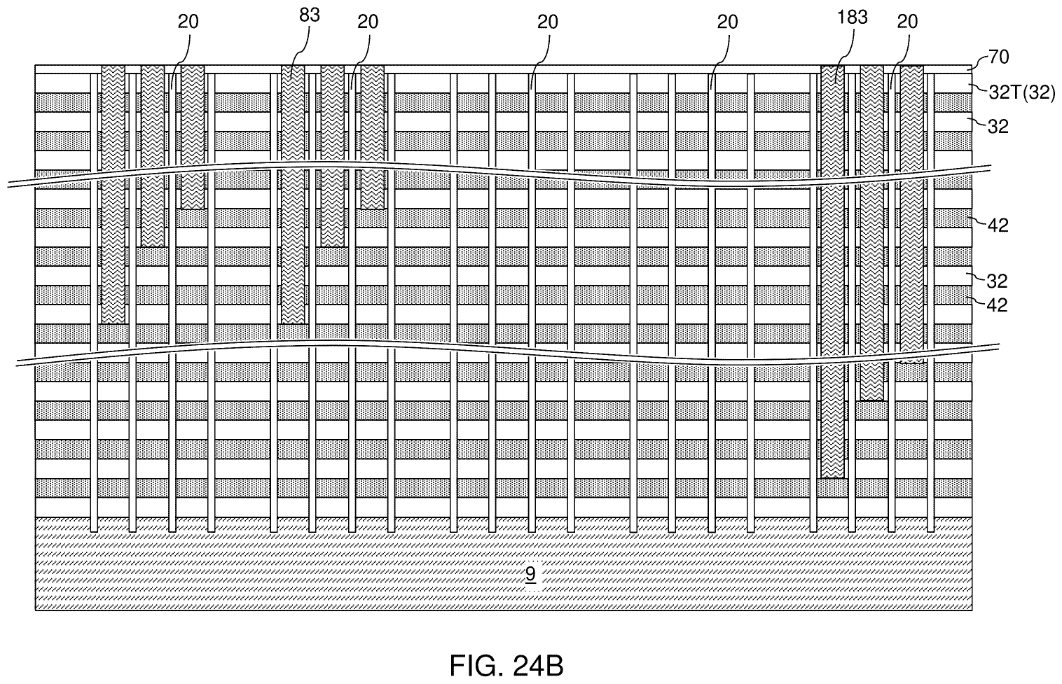

Referring to FIGS. 24A and 24B, the processing steps described with FIGS. 11A-11C can be performed to form sacrificial via opening fill structures (83, 183) in the contact via openings 81 and in the dummy cavities 181. First-type sacrificial via opening fill structures 83 are formed in the contact via openings 81, and second-type sacrificial via opening fill structures 183 are formed in the dummy cavities 181.

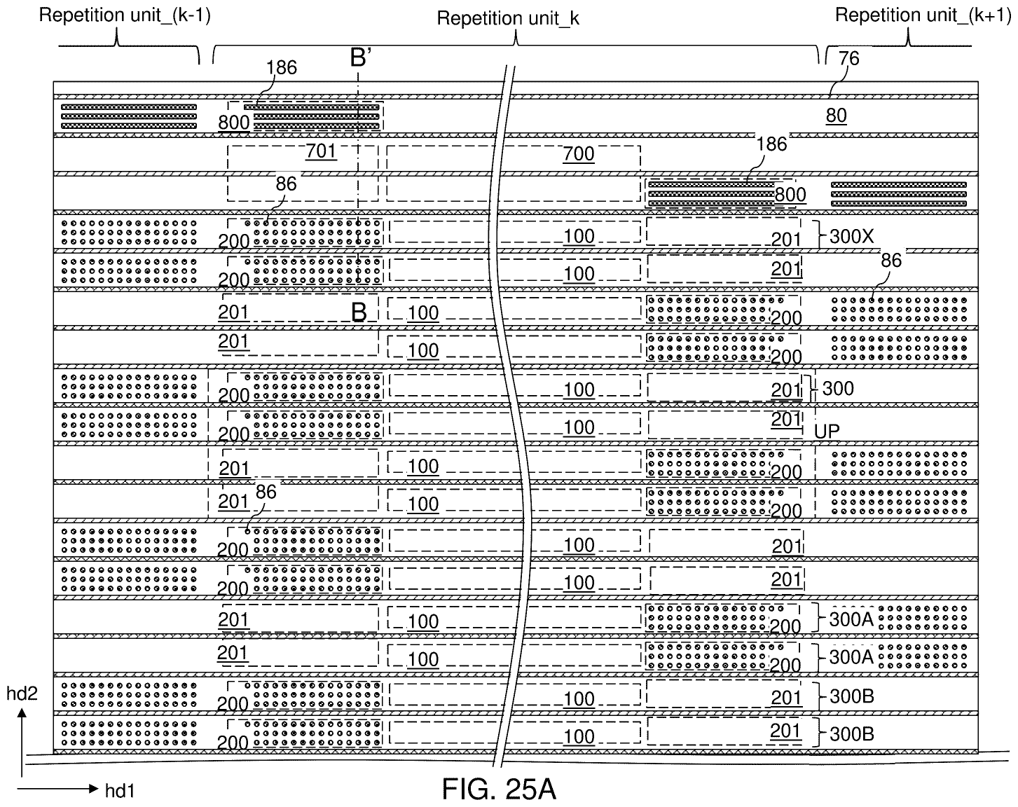

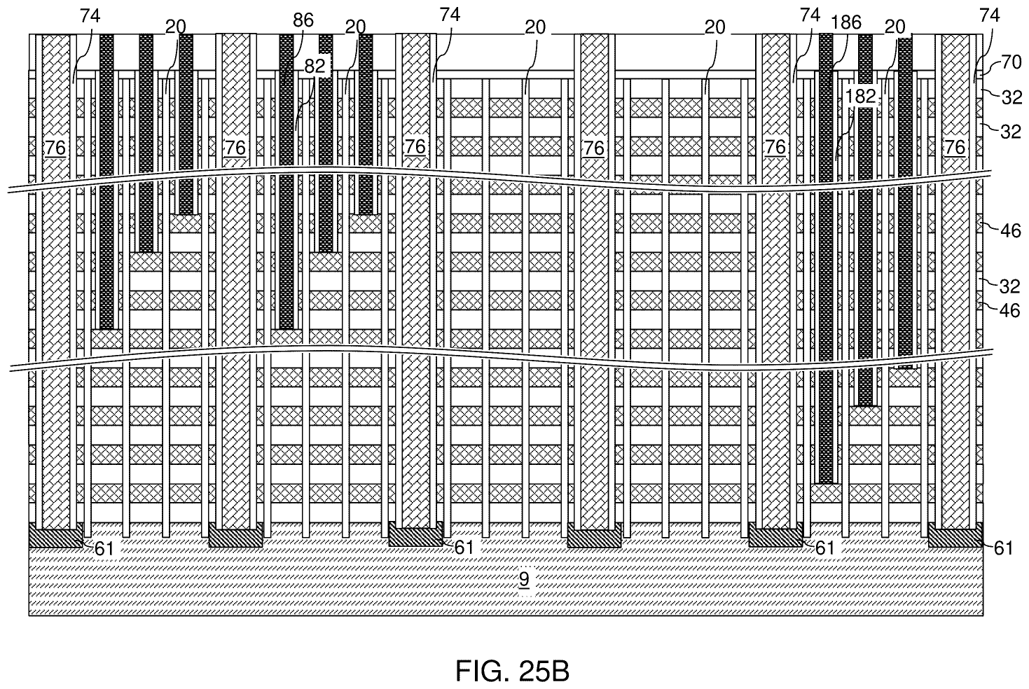

Referring to FIGS. 25A and 25B, the processing steps described with reference to FIGS. 12A-12C can be performed to form lateral isolation trenches 79; the processing steps described with reference to FIGS. 13A-13C can be performed to form laterally-extending cavities 43 by removing the sacrificial material layers 42; the processing steps described with reference to FIGS. 14A-14C can be performed to form electrically conductive layers 46 in the laterally-extending cavities 43; and the processing steps described with reference to FIGS. 15A-18C can be performed to replace the first-type sacrificial via opening fill structures 83 with contact via structures 86, and to replace the second-type sacrificial via opening fill structures 183 with dummy via fill structures 186.

The second exemplary structure comprises a three-dimensional memory device. The three-dimensional memory device comprises active and peripheral alternating stacks (32, 46) of insulating layers 32 and electrically conductive layers 46 laterally extending along a first horizontal direction hd1 with a respective width along a second horizontal direction hd2 that is perpendicular to the first horizontal direction hd1. In one embodiment, the width may be a uniform width. The active alternating stacks (32, 46) are located in the respective active blocks 300, while the peripheral alternating stacks (32, 46) are located in the respective dummy blocks 300D.

Lateral isolation trenches 79 laterally extend along the first horizontal direction, wherein the alternating stacks (32, 46) are laterally spaced apart from each other along the second horizontal direction hd2 by the lateral isolation trenches 79. Memory opening fill structures 58, each containing a respective vertical stack of memory elements (e.g., portions of the memory film 50) and a vertical semiconductor channel 60, vertically extend through the active alternating stacks (32, 46).

The memory device also includes a set of layer contact via structures 86 and a set of dummy via fill structures 186. Each of the layer contact via structures 86 in the set contacts a respective electrically conductive layer 46 in a respective contact region 200 in a respective one of the active alternating stacks (32, 46). Each of the dummy via fill structures 186 contacts a respective electrically conductive layer 46 in a respective dummy structure region 800 in a respective one of the peripheral alternating stacks (32, 46). A second total volume of the respective set of the dummy via fill structures 186 contacting the electrically conductive layers 46 within the respective one of the peripheral alternating stacks in a respective dummy block 300D is greater than a first total volume of the respective set of the layer contact via structures contacting the electrically conductive layers 46 within the respective one of the active alternating stacks in a respective active block 300.

The active alternating stacks (32, 46) in the active memory blocks comprise a predominant subset (i.e., more than half) of the alternating stacks. In one embodiment, the second total volume value is in a range from 110% to 2,000% of the first total volume value. In one embodiment, the second total volume value is at least 200% of the first total volume value of the layer contact via structures 86 in the respective contact region 200 of a respective active memory block 300.

In one embodiment, one of the layer contact via structures 86 has a first maximum lateral extent along the first horizontal direction hd1; and one of the dummy via fill structures 186 has a second maximum lateral extent along the first horizontal direction hd1 that is in a range from 200% to 10,000% of the first maximum lateral extent.

In one embodiment, each of the layer contact via structures 86 has a horizontal cross-sectional shape of a circle or an oval; and each of the dummy fill structures 186 has a horizontal cross-sectional shape of an elongated slit.

In one embodiment, the one of the layer contact via structures 86 has a first lateral dimension ratio which is a ratio of a maximum lateral dimension of the one of the layer contact via structures 86 along the first horizontal direction hd1 to a maximum lateral dimension of the one of the layer contact via structures 86 along the second horizontal direction hd2; the one of the dummy via fill structures 186 has a second lateral dimension ratio which is a ratio of a maximum lateral dimension of the one of the dummy via fill structures 186 along the first horizontal direction hd1 to a maximum lateral dimension of the one of the dummy via fill structures 186 along the second horizontal direction hd2; and the second lateral dimension ratio is greater than the first lateral dimension ratio.

In one embodiment, an average height of the layer contact via structures 86 in the respective contact region has a first average height value for each alternating stack (32, 46); and an average height of the dummy via fill structures 186 in the dummy structure region has a second average height value that is greater than the first average height value.

In one embodiment, each of the dummy via fill structures 186 comprises a respective metallic material portion having a same material composition as the layer contact via structures 86. In one embodiment, each of the layer contact via structures 86 is laterally surrounded by a respective first insulating spacer 82 having an outer sidewall contacting each electrically conductive layer 46 that overlies the respective electrically conductive layer 46; and each of the dummy via fill structures 186 is laterally surrounded by a respective second insulating spacer 182 having a same material composition and a same lateral thickness as the first insulating spacers 82.

In one embodiment, each electrically conductive layer 46 within the active alternating stacks (32, 46) is contacted by a respective layer contact via structure 86; a first subset of the electrically conductive layer 46 within at least a first one of the peripheral alternating stacks (32, 46) is contacted by a respective dummy via fill structure 186; and a second subset of the electrically conductive layers 46 within at least a second one the peripheral alternating stacks (32, 46) is not contacted by any overlying conductive structure. In other words, the electrically conductive layers 46 are not contacted by either the layer contact via structures 86 or the dummy via fill structures 186 in a peripheral alternating stack (32, 46) in at least one of the dummy memory blocks 300D which lacks the dummy structures 800. In one embodiment, the peripheral alternating stacks comprise three peripheral alternating stacks located in respective three dummy blocks 300D, and the active alternating stacks comprise more than three (e.g., more than 10) active alternating stacks located in respective active blocks 300.

In one embodiment, the second subset of the electrically conductive layers 46 overlies the first subset of the electrically conductive layers 46 in the peripheral alternating stack (32, 46). In one embodiment, the second subset of the electrically conductive layers 46 within the peripheral alternating stack (32, 46) may be electrically floating.

In one embodiment, the active alternating stacks (32, 46) comprises first-type alternating stacks (32, 46) and second-type alternating stacks (32, 46); contact regions 200 of the second-type alternating stacks (32, 46) are laterally offset along the first horizontal direction hd1 relative to contact regions 200 of the first-type alternating stacks (32, 46); and the first-type alternating stacks (32, 46) and the second-type alternating stacks (32, 46) are interlaced along the second horizontal direction hd2 such that a unit pattern UP including a sequence of at least one first-type alternating stack (32, 46) and at least one second-type alternating stack (32, 46) is repeated along the second horizontal direction hd2.

In one embodiment, the memory opening fill structures 58 located in the active blocks 300 comprise active memory opening fill structures that are in electrical contact with a respective one of a plurality of bit lines. The dummy memory opening fill structures are located in the dummy blocks 300D comprise the same structure as the active memory opening fill structures 58. However, the dummy memory opening fill structures are not electrically connected to any of the plurality of bit lines. In one embodiment, each of the active alternating stacks has a same width along the second horizontal direction as each of the peripheral alternating stacks (i.e., the dummy and active blocks have the same width for improved lithography processing).

By forming slit shaped dummy via fill structures 186 in slit shaped dummy cavities 181, the number of dummy blocks 300D may be reduced compared to forming cylindrical dummy via fill structures 186 in cylindrical dummy cavities 181. For example, only three dummy blocks 300D containing slit shaped dummy cavities 181 may absorb the same amount of photoresist material overflow as four dummy blocks containing cylindrical dummy cavities due to the greater volume of slit shaped than cylindrical dummy cavities. Thus, the size of the dummy peripheral area may be reduced, which leaves more space for the active area.

Although the foregoing refers to particular preferred embodiments, it will be understood that the claims are not so limited. It will occur to those of ordinary skill in the art that various modifications may be made to the disclosed embodiments and that such modifications are intended to be within the scope of the claims. Compatibility is presumed among all embodiments that are not alternatives of one another. The word “comprise” or “include” contemplates all embodiments in which the word “consist essentially of”' or the word “consists of” replaces the word “comprise” or “include,” unless explicitly stated otherwise. Where an embodiment using a particular structure and/or configuration is illustrated in the present disclosure, it is understood that the claims may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

1. A three-dimensional memory device, comprising:
active and peripheral alternating stacks of insulating layers and electrically conductive layers laterally extending along a first horizontal direction with a respective width along a second horizontal direction that is perpendicular to the first horizontal direction;
lateral isolation trenches laterally extending along the first horizontal direction, wherein the alternating stacks are laterally spaced apart from each other along the second horizontal direction by the lateral isolation trenches;
memory opening fill structures each containing a respective vertical stack of memory elements and a vertical semiconductor channel vertically extending through the active alternating stacks;
a set of layer contact via structures, each of the layer contact via structures contacting a respective electrically conductive layer in a respective contact region in a respective one of the active alternating stacks;
a set of dummy via fill structures, each of the dummy via fill structures contacting a respective electrically conductive layer in a respective dummy structure region in a respective one of the peripheral alternating stacks,
wherein a second total volume of the respective set of the dummy via fill structures contacting the electrically conductive layers within the respective one of the peripheral alternating stacks is greater than a first total volume of the respective set of the layer contact via structures contacting the electrically conductive layers within the respective one of the active alternating stacks.

2. The three-dimensional memory device of claim 1, wherein:
the active alternating stacks comprise a predominant subset of the alternating stacks; and
the second total volume value is in a range from 110% to 2,000% of the first total volume value.

3. The three-dimensional memory device of claim 1, wherein:
one of the layer contact via structures has a first maximum lateral extent along the first horizontal direction; and
one of the dummy via fill structures has a second maximum lateral extent along the first horizontal direction that is in a range from 200% to 10,000% of the first maximum lateral extent.

4. The three-dimensional memory device of claim 3, wherein:
each of the layer contact via structures has a horizontal cross-sectional shape of a circle or an oval; and
each of the dummy fill structures has a horizontal cross-sectional shape of an elongated slit.

5. The three-dimensional memory device of claim 3, wherein:
said one of the layer contact via structures has a first lateral dimension ratio which is a ratio of a maximum lateral dimension of said one of the layer contact via structures along the first horizontal direction to a maximum lateral dimension of said one of the layer contact via structures along the second horizontal direction;
said one of the dummy via fill structures has a second lateral dimension ratio which is a ratio of a maximum lateral dimension of said one of the dummy via fill structures along the first horizontal direction to a maximum lateral dimension of said one of the dummy via fill structures along the second horizontal direction; and
the second lateral dimension ratio is greater than the first lateral dimension ratio.

6. The three-dimensional memory device of claim 1, wherein:
an average height of the layer contact via structures in the respective contact region has a first average height value for each alternating stack; and
an average height of the dummy via fill structures in the dummy structure region has a second average height value that is greater than the first average height value.

7. The three-dimensional memory device of claim 1, wherein:
each of the dummy via fill structures comprises a respective metallic material portion having a same material composition as the layer contact via structures;
each of the layer contact via structures is laterally surrounded by a respective first insulating spacer having an outer sidewall contacting each electrically conductive layer that overlies the respective electrically conductive layer; and
each of the dummy via fill structures is laterally surrounded by a respective second insulating spacer having a same material composition and a same lateral thickness as the first insulating spacers.

8. The three-dimensional memory device of claim 1, wherein:
each electrically conductive layer within the active alternating stacks is contacted by a respective one of the layer contact via structures;
a first subset of the electrically conductive layers within at least a first one of the peripheral alternating stacks is contacted by a respective one of the dummy via fill structures; and
a second subset of the electrically conductive layers within at least a second one of the peripheral alternating stacks is not contacted by any overlying conductive structure.

9. The three-dimensional memory device of claim 8, wherein the peripheral alternating stacks comprise three peripheral alternating stacks located in respective dummy blocks, and the active alternating stacks comprise more than three active alternating stacks located in respective active blocks.

10. The three-dimensional memory device of claim 1, wherein:
the active alternating stacks comprise first-type alternating stacks and second-type alternating stacks;
contact regions of the second-type alternating stacks are laterally offset along the first horizontal direction relative to contact regions of the first-type alternating stacks; and
the first-type alternating stacks and the second-type alternating stacks are interlaced along the second horizontal direction such that a unit pattern including a sequence of at least one first-type alternating stack and at least one second-type alternating stack is repeated along the second horizontal direction.

11. The three-dimensional memory device of claim 1, wherein:
the active alternating stacks are located in active blocks;
the memory opening fill structures located in the active blocks comprise active memory opening fill structures that are in electrical contact with a respective one of a plurality of bit lines;
the peripheral alternating stacks are located in dummy blocks;
dummy memory opening fill structures are located in the dummy blocks comprise the same structure as the active memory opening fill structures;
the dummy memory opening fill structures are not electrically connected to any of the plurality of bit lines; and
each of the active alternating stacks has a same width along the second horizontal direction as each of the peripheral alternating stacks.

12. A method of forming a device structure, comprising:
forming a vertically alternating sequence of continuous insulating layers and continuous spacer material layers over a substrate;
forming memory openings through the vertically alternating sequence;
forming memory opening fill structures in the memory openings, wherein each of the memory opening fill structures comprises a respective vertical stack of memory elements;
forming a patterned hardmask layer over the vertically alternating sequence and the memory opening fill structures, wherein the patterned hardmask layer comprises arrays of first-type openings in a center region of the vertically alternating sequence and an array of second-type openings in a peripheral region of the vertically alternating sequence; and
forming arrays of contact via openings by vertically recessing first portions of the vertically alternating sequence that underlie the first-type openings, and forming an array of dummy cavities by vertically recessing second portions of the vertically alternating sequence that underlie the second-type openings, wherein:
each of the arrays of contact via openings has a first total cavity volume per unit area; and
the array of dummy cavities has a second total cavity volume per unit area which is greater than the first total cavity volume per unit area.

13. The method of claim 12, wherein:
each region including the first-type openings in the patterned hardmask layer has a first areal density of the first-type openings in a plan view;
a region including the second-type openings in the patterned hardmask layer has a second areal density of the second-type openings in the plan view; and
the second areal density is in a range from 110% to 2,000% of the first areal density.

14. The method of claim 12, wherein:
each of the first-type openings in the patterned hardmask layer has a first horizontal cross-sectional area; and
each of the second-type openings in the patterned hardmask layer has a second horizontal cross-sectional area in a range from 200% to 10,000% of the first horizontal cross-sectional area.

15. The method of claim 12, wherein the second total cavity volume is in a range from 110% to 2,000% of the first total cavity volume.

16. The method of claim 12, wherein:
the arrays of contact via openings and the array of dummy cavities are formed by sequentially performing multiple iterations of a selective via extension process; and
each iteration of the selective via extension process comprises a respective photoresist masking step in which a respective photoresist material layer covers a respective first subset of the first-type openings while not covering a respective second subset of the first-type openings and not covering a respective subset of the second-type openings, and further comprises a respective anisotropic etch step that vertically extends a respective subset of the contact via openings that underlies the respective second subset of the first-type openings and a respective subset of the dummy cavities that underlies the respective subset of the second-type openings.

17. The method of claim 16, wherein, during one iteration of the selective via extension processes:
a fraction of a total number of first-type openings within the respective first subset to a total number of first-type openings through the patterned hardmask layer is in a range from 0.33 to 0.67; and
a fraction of a total number of second-type openings within the respective subset to a total number of second-type openings through the patterned hardmask layer is in a range from 0.5 to 1.

18. The method of claim 17, wherein:
during a last iteration of the selective via extension process, the respective photoresist material layer has a contoured top surface having a surface height undulation;
first surface segments of the contoured top surface of the respective photoresist material layer are located in first regions in which the first-type openings and the second-type openings are absent; and
second surface segments of the contoured top surface of the respective photoresist material layer are located in second regions containing the first-type openings or the second-type openings and are vertically recessed relative to the first surface segments.

19. The method of claim 18, wherein, during the last iteration of the selective via extension process, an average volume of the respective photoresist material layer filling the array of dummy cavities per unit area is greater than an average volume of the respective photoresist material layer filling the arrays of contact via openings per unit area at least by a factor of 2.

20. The method of claim 16, further comprising:
forming arrays of first-type sacrificial via opening fill structures in the arrays of contact via openings;
forming an array of second-type sacrificial via opening fill structures in the array of dummy cavities;
forming lateral isolation trenches that laterally extend along the first horizontal direction, wherein the vertically alternating sequence is divided into a plurality of alternating stacks, and wherein each alternating stack within the plurality of alternating stacks comprises a respective array of first-type sacrificial via opening fill structures or the array of second-type sacrificial via opening fill structures;
replacing the arrays of first-type sacrificial via opening fill structures with a respective array of layer contact via structures; and
replacing the array of second-type sacrificial via opening fill structures with an array of dummy via fill structures.
